(19) United States
(12) Patent Application Publication
(10) Pub. No.: US 2012/0235162 A1
(43) Pub. Date: Sep. 20, 2012

(54) POWER CONVERTER

(75) Inventors: Tasuku ISOBE, Fukuoka (JP); Yasuhiko Kawanami, Fukuoka (JP); Yukihisa Nakabayashi, Fukuoka (JP); Masato Higuchi, Fukuoka (JP); Koji Higashikawa, Fukuoka (JP); Katsushi Terazono, Fukuoka (JP); Akira Sasaki, Fukuoka (JP); Takayuki Morihara, Fukuoka (JP); Takashi Aoki, Fukuoka (JP); Tetsuya Ito, Fukuoka (JP); Kiyonori Koguma, Fukuoka (JP)

(73) Assignee: KABUSHIKI KAISHA YASKAWA DENKI, Kitakyushu-shi (JP)

(21) Appl. No.: 13/330,540

(22) Filed: Dec. 19, 2011

Related U.S. Application Data
(63) Continuation of application No. PCT/JP2010/060336, filed on Jun. 18, 2010.

(30) Foreign Application Priority Data
Jun. 19, 2009 (JP) 2009-146953

(51) Int. Cl. H01L 23/50; H01L 29/20; H01L 23/34; H01L 29/24

(52) U.S. Cl. 257/77; 257/737; 257/76; 257/E23.08; 257/E23.079; 257/E29.104; 257/E29.089

(57) ABSTRACT

This power converter includes a power-conversion semiconductor element, an electrode conductor having a substantially flat upper end surface, and a sealant. The sealant allows the substantially flat upper end surface of the electrode conductor to be exposed at an upper surface of the sealant, and provides electrical connection with an external device at the upper end surface of the exposed electrode conductor.

### CROSS-REFERENCE TO RELATED APPLICATIONS

The present application is a continuation application of PCT/JP2010/060336, filed Jun. 18, 2010, which claims priority to Japanese Patent Application No. 2009-146953, filed Jun. 19, 2009. The contents of these applications are incorporated herein by reference in their entirety.

### BACKGROUND OF THE INVENTION

1. Field of the Invention

The disclosed embodiment relates to a power converter.

2. Discussion of the Background

For example, a power converter is described in Japanese Unexamined Patent Application Publication No. 2008-103623. This semiconductor device (a power converter) includes an insulated-gate bipolar transistor (IGBT, power-conversion semiconductor element); a lead frame electrically connected with the IGBT; and mold resin having the IGBT and the lead frame arranged therein. This semiconductor device is formed such that the lead frame protrudes from a side surface of the mold resin to allow the semiconductor device to be electrically connected with an external device.

Since the lead frame protrudes from the side surface of the mold resin, the size of such a semiconductor device is increased by the amount of protrusion. Consequently, it is difficult to decrease the size of the semiconductor device.

### SUMMARY OF THE INVENTION

According to one aspect of the present invention, a power converter includes a power-converter body portion including a power-conversion semiconductor element having an electrode, an electrode conductor electrically connected with the electrode of the power-conversion semiconductor element, and having side surfaces and a flat upper end surface, and a sealant made of resin and covering the power-conversion semiconductor element and the side surfaces of the electrode conductor, the sealant allowing the flat upper end surface of the electrode conductor to be exposed at an upper surface of the sealant and the sealant providing electrical connection with an external device at the flat upper end surface of the exposed electrode conductor; and a wiring board electrically connected with the flat upper end surface of the electrode conductor exposed from the upper surface of the sealant.

According to another aspect of the present invention, a power converter includes a plurality of power-conversion semiconductor elements including a plurality of electrodes; a plurality of electrode conductors electrically connected with the plurality of electrodes of the plurality of power-conversion semiconductor elements, having columnar shapes extending upward, and having flat upper end surfaces; a radiator member arranged at back surfaces of the power-conversion semiconductor elements; and a sealant made of resin and covering the power-conversion semiconductor elements and side surfaces of the electrode conductors. The sealant allows the flat upper end surfaces of the plurality of electrode conductors having the columnar shapes to be exposed at an upper surface of the sealant and provides electrical connection with an external device at the upper end surfaces of the exposed electrode conductors. Heat generated by the power-conversion semiconductor elements can be radiated from both the flat upper end surfaces of the plurality of electrode conductors arranged at principal surfaces of the power-conversion semiconductor elements and the radiator member arranged at the back surfaces of the power-conversion semiconductor elements.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view of a power module according to a first embodiment;

FIG. 2 is a sectional view taken along line 1000-1000 in FIG. 1;

FIG. 3 is a sectional view taken along line 1100-1100 in FIG. 1;

FIG. 4 is a sectional view taken along line 1200-1200 in FIG. 1;

FIG. 5 is a perspective view from a front surface of the power module according to the first embodiment;

FIG. 6 is a perspective view from a back surface of the power module according to the first embodiment;

FIG. 7 is a perspective view of a drain terminal of the power module according to the first embodiment;

FIG. 8 is a circuit diagram of the power module according to the first embodiment;

FIG. 9 is a sectional view of a module indicative of a simulation module according to the first embodiment;

FIG. 10 is a sectional view of a module indicative of a simulation module according to a comparative example;

FIG. 11 is a plan view of a power module according to a second embodiment;

FIG. 12 is a sectional view taken along line 1300-1300 in FIG. 11;

FIG. 13 is a sectional view taken along line 1400-1400 in FIG. 11;

FIG. 14 is a sectional view of a power module according to a third embodiment;

FIG. 15 is a sectional view of a power module according to a fourth embodiment;

FIG. 16 is a sectional view of a power module according to a fifth embodiment;

FIG. 17 is a sectional view of a power module according to a sixth embodiment;

FIG. 18 is a sectional view of a power module according to a seventh embodiment;

FIG. 19 is a sectional view of a power module according to an eighth embodiment;

FIG. 20 is a sectional view of a power module according to a ninth embodiment;

FIG. 21 is a plan view of a power module according to a tenth embodiment;

FIG. 22 is a sectional view taken along line 1410-1410 in FIG. 21;

FIG. 23 is a sectional view taken along line 1420-1420 in FIG. 21;

FIG. 24 is a perspective view from a front surface of the power module according to the tenth embodiment;

FIG. 25 is a perspective view from a back surface of the power module according to the tenth embodiment;

FIG. 26 is a plan view of a power module according to an eleventh embodiment;

FIG. 27 is a sectional view taken along line 1430-1430 in FIG. 26;

FIG. 28 is a sectional view taken along line 1440-1440 in FIG. 26;

FIG. 29 is a perspective view from a front surface of the power module according to the eleventh embodiment;

FIG. 30 is a perspective view from a back surface of the power module according to the eleventh embodiment;

FIG. 31 is a sectional view of a power module according to a twelfth embodiment;

FIG. 32 is a perspective view from a front surface of the power module according to the twelfth embodiment;

FIG. 33 is a perspective view from a back surface of the power module according to the twelfth embodiment;

FIG. 34 is a plan view of a power module according to a thirteenth embodiment;

FIG. 35 is a sectional view taken along line 1500-1500 in FIG. 34;

FIG. 36 is a sectional view taken along line 1600-1600 in FIG. 34;

FIG. 37 is a sectional view taken along line 1700-1700 in FIG. 34;

FIG. 38 is a sectional view of a power module according to a fourteenth embodiment;

FIG. 39 is a perspective view from a front surface of the power module according to the fourteenth embodiment;

FIG. 40 is a perspective view from a back surface of the power module according to the fourteenth embodiment;

FIG. 41 is a sectional view of a power module according to a fifteenth embodiment;

FIG. 42 is a perspective view of the power module according to the fifteenth embodiment;

FIG. 43 is a perspective view from a front surface of a power module according to a sixteenth embodiment;

FIG. 44 is a perspective view from a back surface of the power module according to the sixteenth embodiment;

FIG. 45 is a perspective view from a front surface of a power module according to a seventeenth embodiment;

FIG. 46 is a perspective view from a back surface of the power module according to the seventeenth embodiment;

FIG. 47 is a plan view of a power module according to an eighteenth embodiment;

FIG. 48 is a sectional view taken along line 1710-1710 in FIG. 47;

FIG. 49 is a sectional view taken along line 1720-1720 in FIG. 47;

FIG. 50 is a plan view of a power module according to a nineteenth embodiment;

FIG. 51 is a sectional view taken along line 1730-1730 in FIG. 50;

FIG. 52 is a sectional view taken along line 1740-1740 in FIG. 50;

FIG. 53 is a perspective view from a front surface of the power module according to the nineteenth embodiment;

FIG. 54 is a perspective view from a back surface of the power module according to the nineteenth embodiment;

FIG. 55 is a sectional view of a power module according to a twentieth embodiment;

FIG. 56 is a plan view of a power module according to a twenty-first embodiment;

FIG. 57 is a sectional view taken along line 1750-1750 in FIG. 56;

FIG. 58 is a sectional view taken along line 1760-1760 in FIG. 56;

FIG. 59 is a perspective view of a wiring board of a power module according to a twenty-second embodiment;

FIG. 60 is a sectional view of the wiring board of the power module according to the twenty-second embodiment;

FIG. 61 is a perspective view of a wiring board of a power module according to a twenty-third embodiment;

FIG. 62 is a sectional view of the wiring board of the power module according to the twenty-third embodiment;

FIG. 63 is a perspective view of a wiring board of a power module according to a twenty-fourth embodiment;

FIG. 64 is a sectional view of the wiring board of the power module according to the twenty-fourth embodiment;

FIG. 65 is a perspective view of a wiring board of a power module according to a twenty-fifth embodiment;

FIG. 66 is a sectional view of the wiring board of the power module according to the twenty-fifth embodiment;

FIG. 67 is a perspective view of a wiring board of a power module according to a twenty-sixth embodiment;

FIG. 68 is a sectional view of the wiring board of the power module according to the twenty-sixth embodiment;

FIG. 69 is a perspective view of a wiring board of a power module according to a twenty-seventh embodiment;

FIG. 70 is a sectional view of the wiring board of the power module according to the twenty-seventh embodiment;

FIG. 71 is a circuit diagram of a power module according to a twenty-eighth embodiment;

FIG. 72 is a longitudinal sectional view of the power module according to the twenty-eighth embodiment;

FIG. 73 is a cross sectional view of the power module according to the twenty-eighth embodiment;

FIG. 74 is a top perspective view of the power module according to the twenty-eighth embodiment;

FIG. 75 is a sectional view of wiring of a power module according to a twenty-ninth embodiment;

FIG. 76 is a sectional view of wiring of a power module according to a thirtieth embodiment;

FIG. 77 is a sectional view of a wiring board of a power module according to a thirty-first embodiment;

FIG. 78 is a plan view of the wiring board of the power module according to the thirty-first embodiment;

FIG. 79 is a plan view of the wiring board of the power module according to the thirty-first embodiment;

FIG. 80 is a sectional view of a wiring board of a power module according to a thirty-second embodiment;

FIG. 81 is a sectional view of a wiring board of a power module according to a thirty-third embodiment;

FIG. 82 is a perspective view of a liquid cooler according to a thirty-fourth embodiment;

FIG. 83 is an exploded perspective view of the liquid cooler according to the thirty-fourth embodiment;

FIG. 84 is a perspective view of a liquid-cooling plate base of the liquid cooler according to the thirty-fourth embodiment;

FIG. 85 is a perspective view of a liquid cooler according to a thirty-fifth embodiment;

FIG. 86 is an exploded perspective view of the liquid cooler according to the thirty-fifth embodiment;

FIG. 87 is a perspective view of a liquid cooler according to a thirty-sixth embodiment;

FIG. 88 is an exploded perspective view of the liquid cooler according to the thirty-sixth embodiment;

FIG. 89 is a perspective view of a liquid cooler according to a thirty-seventh embodiment;

FIG. 90 is an exploded perspective view of the liquid cooler according to the thirty-seventh embodiment;

FIG. 91 is a sectional view of a liquid cooler according to a thirty-eighth embodiment;

FIG. 92 is a sectional view of a liquid cooler according to a thirty-ninth embodiment;

FIG. 93 is a sectional view of a joint material according to a fortieth embodiment;

FIG. 94 is a sectional view for explaining current that flows through a joint material according to the fortieth embodiment;

FIG. 95 is a sectional view of a joint material according to a forty-first embodiment;

FIG. 96 is a sectional view for explaining current that flows through the joint material according to the forty-first embodiment;

FIG. 97 is a perspective view of a high-current terminal block according to a forty-second embodiment;

FIG. 98 is a perspective view of a back surface of the high-current terminal block according to the forty-second embodiment;

FIG. 99 is a front view of a connecting terminal portion according to the forty-second embodiment;

FIG. 100 is a bottom view of the connecting terminal portion according to the forty-second embodiment;

FIG. 101 is a side view of the connecting terminal portion according to the forty-second embodiment;

FIG. 102 is a perspective view of the high-current terminal block connected with an inverter section and a converter section according to the forty-second embodiment;

FIG. 103 is a perspective view of the high-current terminal block before the high-current terminal block is connected with the inverter section and the converter section according to the forty-second embodiment;

FIG. 104 is a perspective view of a high-current terminal block according to a forty-third embodiment;

FIG. 105 is a perspective view of a back surface of the high-current terminal block according to the forty-third embodiment;

FIG. 106 is a perspective view of a connecting terminal portion of the high-current terminal block according to the forty-third embodiment;

FIG. 107 is a front view of the connecting terminal portion according to the forty-third embodiment;

FIG. 108 is a side view of the connecting terminal portion according to the forty-third embodiment;

FIG. 109 is a bottom view of the connecting terminal portion according to the forty-third embodiment;

FIG. 110 is a rear view of the connecting terminal portion according to the forty-third embodiment;

FIG. 111 is a perspective view of the high-current terminal block connected with an inverter section and a converter section according to the forty-third embodiment; and

FIG. 112 is a perspective view of the high-current terminal block before the high-current terminal block is connected with the inverter section and the converter section according to the forty-third embodiment.

### DESCRIPTION OF THE EMBODIMENTS

Embodiments will now be described with reference to the accompanying drawings, wherein like reference numerals designate corresponding or identical elements throughout the various drawings.

### First Embodiment

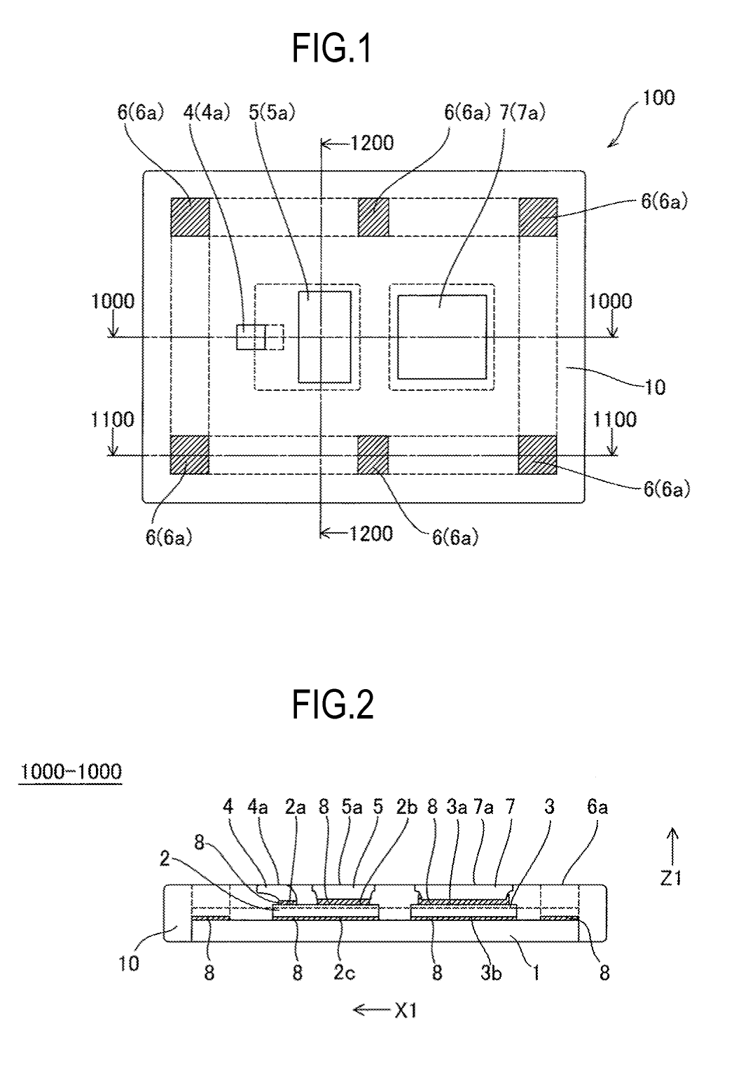

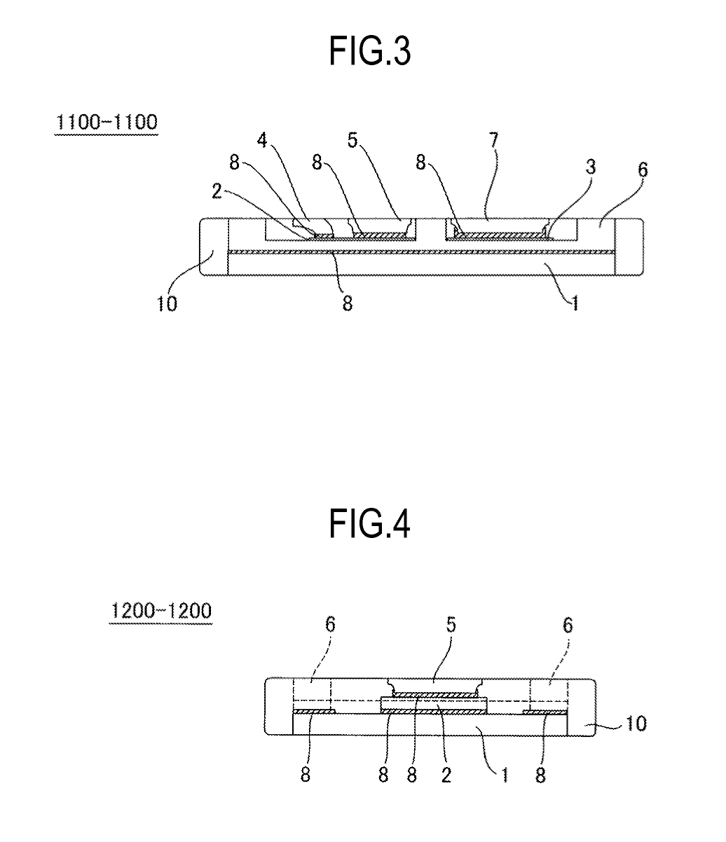

A configuration of a power module 100 according to a first embodiment is described with reference to FIGS. 1 to 8. The power module 100 is an example of a “power-converter body portion” that is disclosed.

Referring to FIGS. 1 to 4, the power module 100 includes a drain-electrode radiator plate 1, a semiconductor element 2, a semiconductor element 3, a gate terminal 4, a source terminal 5, a drain terminal 6, and an anode terminal 7. The drain-electrode radiator plate 1, the gate terminal 4, the source terminal 5, the drain terminal 6, and the anode terminal 7 each are formed of copper (Cu), copper molybdenum (CuMo), or the like, not containing an insulating substance. The drain-electrode radiator plate 1 is formed of a single metal plate. The semiconductor element 2 is formed on a silicon carbide (SiC) substrate having SiC as the main constituent, and is formed of a field effect transistor (FET) that can perform high-frequency switching. As shown in FIG. 2, the semiconductor element 2 includes a control electrode 2a and a source electrode 2b provided on a principal surface of the semiconductor element 2, and a drain electrode 2c provided on a back surface of the semiconductor element 2. The semiconductor element 2 is an example of a “power-conversion semiconductor element” and a “voltage-driven transistor element” that are disclosed. The control electrode 2a is an example of a “front-surface electrode” that is disclosed. The source electrode 2b is an example of a “first electrode” and a “front-surface electrode” that are disclosed. The drain electrode 2c is an example of a “second electrode” and a “back-surface electrode” that are disclosed. The drain-electrode radiator plate 1 is an example of a “radiator member” that is disclosed.

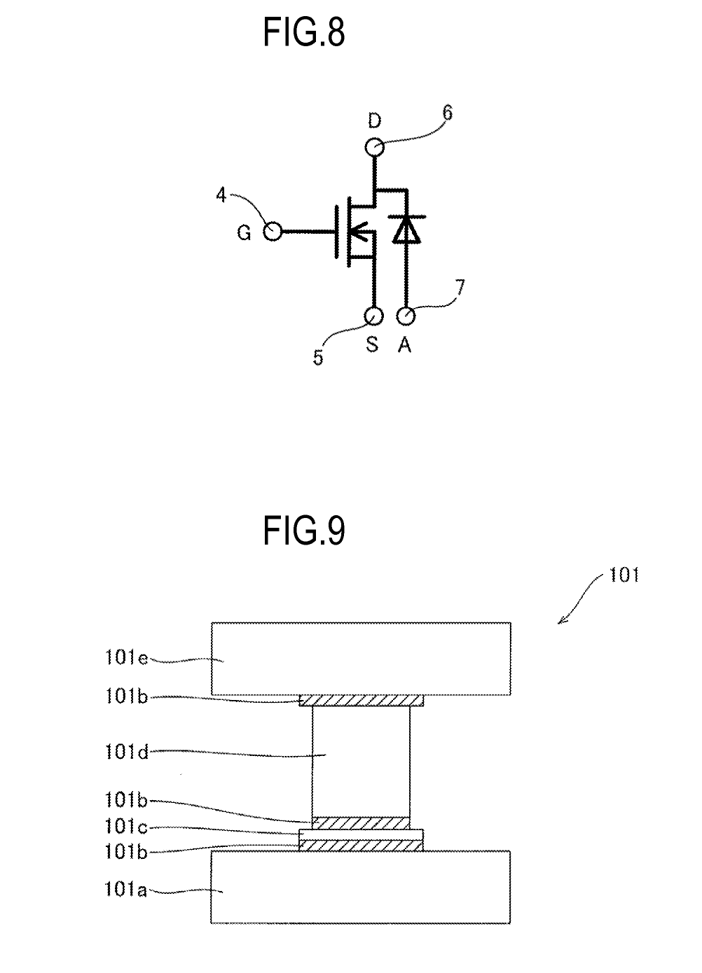

The semiconductor element 3 includes a fast recovery diode (FRD) having an anode electrode 3a and a cathode electrode 3b. The cathode electrode 3b of the semiconductor element 3 is electrically connected with the drain electrode 2c of the semiconductor element 2. The semiconductor element 3 has a function as a free wheel diode (see FIG. 8). The anode electrode 3a is an example of a “first diode electrode” that is disclosed. The cathode electrode 3b is an example of a “second diode electrode” that is disclosed. The semiconductor element 3 is an example of a “power-conversion semiconductor element” and a “free wheel diode element” that are disclosed.

Referring to FIG. 2, the semiconductor element 2 and the semiconductor element 3 are bonded to a surface of the drain-electrode radiator plate 1 respectively through joint materials 8. The drain electrode 2c of the semiconductor element 2 is electrically connected with the drain-electrode radiator plate 1. The cathode electrode 3b of the semiconductor element 3 is electrically connected with the drain-electrode radiator plate 1. If these types of semiconductor elements are used, the temperature at the joint portion increases to almost about 200° C. Hence, the joint material 8 uses solder, such as Au-20Sn, Zn-30Sn, or Pb-5Sn, with a high heat resistance. If the temperature at the joint portion increases to almost about 400° C., the joint material 8 uses Ag nanoparticle paste with a higher heat resistance.

The gate terminal 4 is joined to a surface of the semiconductor element 2 (onto the control electrode 2a) through a joint material 8. The gate terminal 4 has a substantially columnar shape and extends upward of the power module 100 from the surface of the semiconductor element 2 (in a direction indicated by an arrow Z1). The gate terminal 4 also extends outward of the power module 100 (in a direction indicated by an arrow X1). An upper end surface 4a of the gate terminal 4 is substantially flat and has a substantially rectangular shape in plan view (see FIG. 1). The gate terminal 4 has a function of radiating heat generated by the semiconductor element 2, from the upper end surface 4a. The gate terminal 4 is an example of an “electrode conductor,” a “first-electrode conductor,” a “first-transistor-electrode conductor,” and a “control-electrode conductor” that are disclosed.

The source terminal 5 is joined to the surface of the semiconductor element 2 (onto the source electrode 2b) through a joint material 8. The source terminal 5 has a substantially columnar shape and extends upward of the power module 100 from the surface of the semiconductor element 2 (in the direction indicated by the arrow Z1). The source terminal 5 has a substantially flat and substantially rectangular upper end surface 5a (see FIG. 1). The source terminal 5 has a function of radiating heat generated by the semiconductor element 2, from the upper end surface 5a. The source terminal 5 is an example of an “electrode conductor,” a “first-electrode conductor,” a “first-transistor-electrode conductor,” and a “source-electrode conductor” that are disclosed.

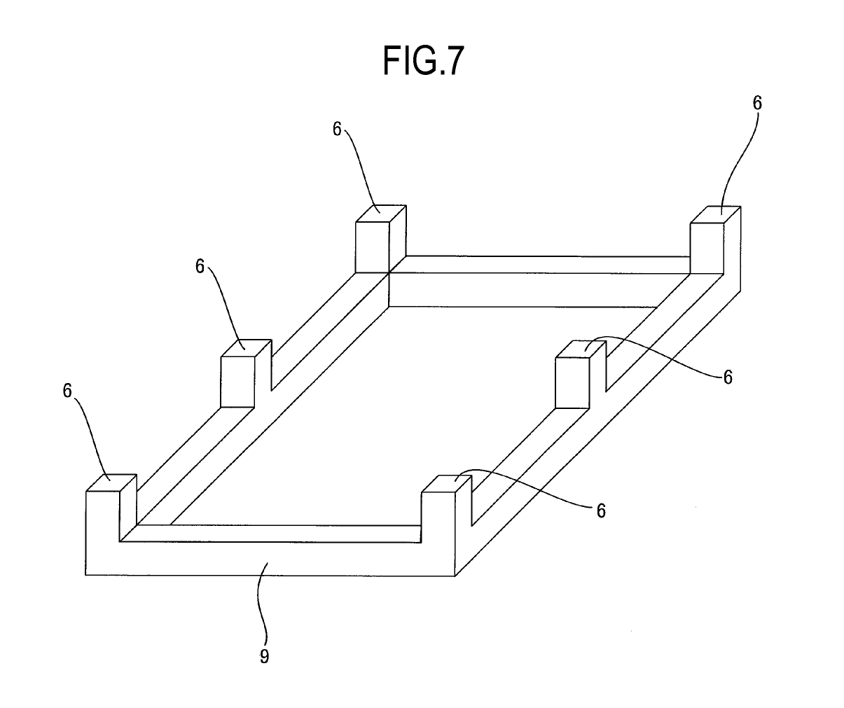

The drain terminal 6 (a drain-electrode frame 9, which will be described later) is joined to the surface of the drain-electrode radiator plate 1 through a joint material 8. Referring to FIG. 7, the drain terminal 6 has a substantially columnar shape. Six drain terminals 6 are integrally formed at the drain-electrode frame 9 formed in a substantially frame-like shape. Also, four of the drain terminals 6 are respectively provided at four corners of the drain-electrode frame 9 one by one. Also, two of the drain terminals 6 are respectively provided near center portions on two long sides of the drain-electrode frame 9 one by one. As described above, the drain terminals 6 are arranged at end portions of the power module 100 and separated from the semiconductor element 2 and the semiconductor element 3 (see FIG. 1).

The drain terminals 6 each have a substantially flat and substantially rectangular upper end surface 6a (see FIG. 1). The drain terminals 6 have a function of radiating heat generated by the semiconductor element 2, from the upper end surfaces 6a. The upper end surfaces 6a of the six drain terminals 6 have substantially equivalent heights from a surface of the drain-electrode frame 9. The drain terminals 6 each are an example of an “electrode conductor,” a “second-electrode conductor,” a “second-transistor-electrode conductor,” and a “drain-electrode conductor” that are disclosed. The wording “substantially” that is used in the above expressions “substantially flat” and “substantially equivalent heights” intends to include an allowable tolerance that may be generated by industrial manufacturing, in addition to a dimensional tolerance. This may be applied to the same wording hereinafter.

The drain terminals 6 each are electrically connected with the cathode electrode 3b of the semiconductor element 3, and each function as a cathode-electrode terminal of the semiconductor element 3. That is, the drain terminals 6 each are also an example of a “second-diode-electrode conductor” that is disclosed.

The anode terminal 7 is joined to a surface of the semiconductor element 3 (onto the anode electrode 3a) through a joint material 8. The anode terminal 7 has a substantially columnar shape and extends upward of the power module 100 from the surface of the semiconductor element 3 (in the direction indicated by the arrow Z1). The anode terminal 7 has a substantially flat and substantially rectangular upper end surface 7a (see FIG. 1). The anode terminal 7 has a function of radiating heat generated by the semiconductor element 3, from the upper end surface 7a. The anode terminal 7 is an example of an “electrode conductor,” a “first-electrode conductor,” and a “first-diode-electrode conductor” that are disclosed.

The upper end surface 4a of the gate terminal 4, the upper end surface 5a of the source terminal 5, the upper end surfaces 6a of the drain terminals 6, and the upper end surface 7a of the anode terminal 7 have substantially equivalent heights.

In a typical power module, a semiconductor element is joined to an electrode by wiring such as wire bonding. However, if wiring such as wire bonding is used, a wiring inductance becomes relatively large. It is difficult to perform high-frequency switching in the power module. In contrast, in the power module 100 according to this embodiment, the gate terminal 4, the source terminal 5, and the drain terminals 6 (the anode terminal 7) are directly joined to the semiconductor element 2 (the semiconductor element 3) respectively through the joint materials 8. Hence, in the power module 100 according to this embodiment, the wiring inductance becomes smaller than that of the typical power module using wire bonding. Thus, high-frequency switching can be performed.

Referring to FIGS. 1 to 4, an insulating resin material 10 uses silicon gel or the like, and covers the semiconductor element 2 and the semiconductor element 3, and side surfaces of the gate terminal 4, the source terminal 5, the drain terminals 6, the anode terminal 7, and the drain-electrode radiator plate 1. The resin material 10 also forms an outer surface of the power module 100. The resin material 10 has a function as an insulator for insulation among the semiconductor element 2, the semiconductor element 3, the gate terminal 4, the source terminal 5, the drain terminals 6, and the anode terminal 7; and a function as a sealant that inhibits water or the like from entering the semiconductor element 2 and the semiconductor element 3. The resin material 10 is an example of a “sealant” that is disclosed.

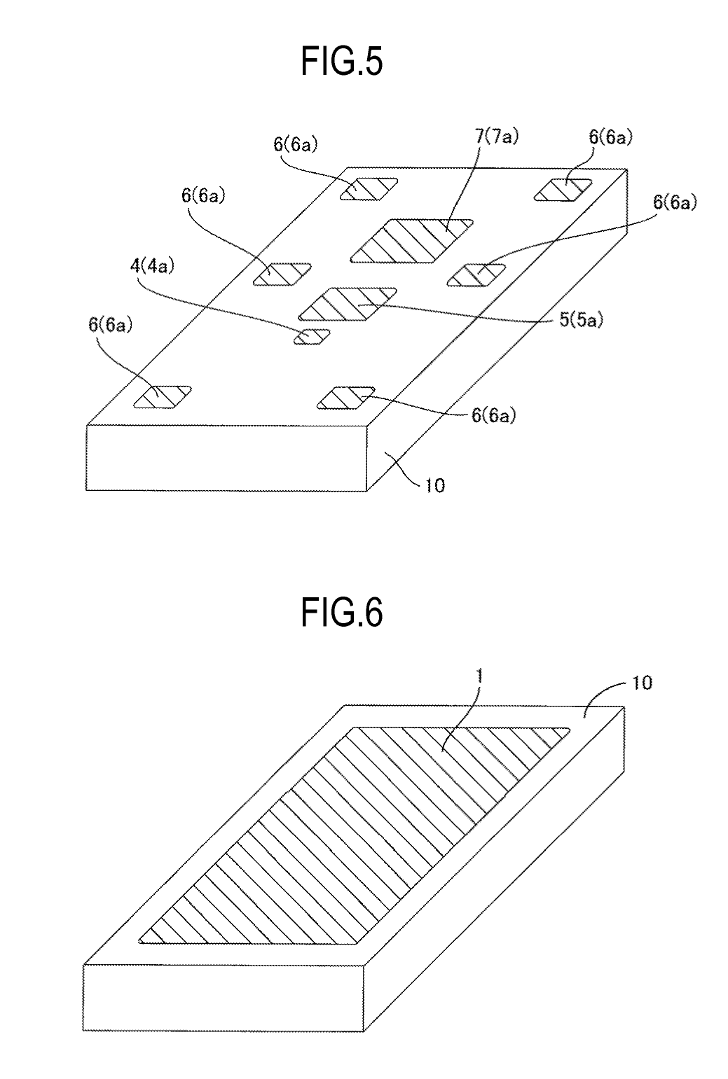

Referring to FIG. 5, the resin material 10 is provided such that the upper end surface 4a of the gate terminal 4, the upper end surface 5a of the source terminal 5, the upper end surfaces 6a of the drain terminals 6, and the upper end surface 7a of the anode terminal 7 are exposed from an upper surface of the resin material 10. The upper surface of the resin material 10 has a height substantially equivalent to the heights of the upper end surface 4a of the gate terminal 4, the upper end surface 5a of the source terminal 5, the upper end surfaces 6a of the drain terminals 6, and the upper end surface 7a of the anode terminal 7. The upper end surface 4a of the gate terminal 4, the upper end surface 5a of the source terminal 5, the upper end surfaces 6a of the drain terminals 6, and the upper end surface 7a of the anode terminal 7 exposed from the resin material 10 can be electrically connected with an external device. Referring to FIG. 6, the drain-electrode radiator plate 1 is exposed from a back surface of the resin material 10.

At the upper surface of the resin material 10, the substantially flat upper end surface 4a (the upper end surface 5a, the upper end surfaces 6a, the upper end surface 7a) of the gate terminal 4 (the source terminal 5, the drain terminals 6, the anode terminal 7) is exposed. With the substantially flat upper end surface 4a (the upper end surface 5a, the upper end surfaces 6a, the upper end surface 7a) of the exposed gate terminal 4 (the source terminal 5, the drain terminals 6, the anode terminal 7), heat radiation performance when heat generated from the semiconductor elements 2 and 3 is radiated upward is increased. The upper end surface 4a (the upper end surface 5a, the upper end surfaces 6a, the upper end surface 7a) of the gate terminal (the source terminal 5, the drain terminals 6, the anode terminal 7) exposed from the upper surface of the resin material 10 can be electrically connected with an external device. With this structure, the device can be further downsized as compared with the power module of related art in which the electrode protrudes from the side surface of the resin material 10.

In this embodiment, the upper end surface 4a of the gate terminal 4, the upper end surface 5a of the source terminal 5, the upper end surfaces 6a of the drain terminals 6, and the upper end surface 7a of the anode terminal 7 exposed from the upper surface of the resin material 10 have the substantially equivalent heights. Accordingly, when the upper surfaces of the gate terminal 4, the source terminal 5, the drain terminals 6, and the anode terminal 7 are electrically connected with an external device, a wiring board and an electrode can be easily arranged and the upper surfaces can be easily electrically connected with the external device.

The gate terminal 4, the source terminal 5, the drain terminals 6, and the anode terminal 7 each have a substantially columnar shape extending upward. The upper end surface 4a of the gate terminal 4, the upper end surface 5a of the source terminal 5, the upper end surfaces 6a of the drain terminals 6, and the upper end surface 7a of the anode terminal 7 are substantially flat. Since the terminals with such substantially columnar shapes are formed, the wiring inductance is markedly decreased as compared with a terminal of related art having a substantially thin wire-like shape. Since the wiring inductance is decreased, high-frequency switching can be performed. In addition, heat radiation performance is markedly increased.

The upper end surface 4a of the gate terminal 4, the upper end surface 5a of the source terminal 5, the upper end surfaces 6a of the drain terminals 6, and the upper end surface 7a of the anode terminal 7 exposed from the upper surface of the resin material 10 have the heights substantially equivalent to the upper surface of the resin material 10. The upper end surfaces 4a, 5a, 6a, and 7a are flush with the upper surface of the resin material 10. Accordingly, electrical connection can be easily provided by mounting a wiring board or the like on the upper end surfaces 4a, 5a, 6a, and 7a and the resin material 10.

The gate terminal 4 is connected with the control electrode 2a at the principal surface of the semiconductor element 2 through the joint material 8, and extends upward. The gate terminal 4 has the substantially flat upper end surface 4a exposed from the upper surface of the resin material 10. The source terminal 5 is connected with the source electrode 2b at the principal surface of the semiconductor element 2 through the joint material 8, and extends upward. The source terminal 5 has the substantially flat upper end surface 5a exposed from the upper surface of the resin material 10. The drain terminals 6 are electrically connected with the drain electrode 2c at the back surface of the semiconductor element 2, and extend upward from positions separated from the semiconductor element 2. The drain terminals 6 have the substantially flat upper end surfaces 6a exposed from the upper surface of the resin material 10. The anode terminal 7 is connected with the anode electrode 3a at the principal surface of the semiconductor element 3 through the joint material 8, and extends upward. The anode terminal 7 has the substantially flat upper end surface 7a exposed from the upper surface of the resin material 10. The drain terminals 6 are electrically connected with the cathode electrode 3b at the back surface of the semiconductor element 3, and extend upward from positions separated from the semiconductor element 3. The drain terminals 6 have the substantially flat upper end surfaces 6a exposed from the upper surface of the resin material 10. The upper end surface 4a of the gate terminal 4, the upper end surface 5a of the source terminal 5, the upper end surfaces 6a of the drain terminals 6, and the upper end surface 7a of the anode terminal 7 are arranged in an upper section of the power module 100. With this configuration, electrical connection with an external device can be easily provided.

The drain terminals 6 are electrically connected with the drain electrode 2c at the back surface of the semiconductor element 2, and extend upward from the positions separated from the semiconductor element 2. Since the drain terminals 6 are located at the positions separated from the semiconductor element 2, a short circuit does not occur between side surfaces of the drain terminals 6 and the semiconductor element 2.

In this embodiment, the drain terminals 6 are arranged near end portions of the power module 100, and the gate terminal 4 and the source terminal 5 are arranged near a center portion of the power module 100. With this arrangement, a sufficient insulation distance can be provided between the drain terminals 6, and the gate terminal 4 and the source terminal 5. A short circuit does not occur between the drain terminals 6, and the gate terminal 4 and the source terminal 5.

Side surfaces of the semiconductor element 3 and the anode terminal 7 are covered with the resin material 10, and the substantially flat upper end surface 7a of the anode terminal 7 is exposed from the upper surface of the resin material 10. Accordingly, heat generated by the semiconductor element 3 can be radiated upward from the substantially flat upper end surface 7a of the anode terminal 7. Heat radiation performance is increased. Also, since the substantially flat upper end surface 7a of the anode terminal 7 is exposed from the upper surface of the resin material 10, the free wheel diode can be easily electrically connected with the external device at the upper surface of the resin material 10.

With this embodiment, the resin material 10 forms the outer surface of the power module 100. The semiconductor element 2, the semiconductor element 3, the gate terminal 4, the source terminal 5, the drain terminals 6, and the anode terminal 7 are covered with the resin material 10. With this structure, the resin material 10 absorbs a shock from the outside. The semiconductor elements 2 and 3 can be protected from the shock, and reliability is increased. Also, since the resin material 10 provides the sufficient insulation distance, a short circuit does not occur among the gate terminal 4, the source terminal 5, the drain terminals 6, and the anode terminal 7.

With this embodiment, heat generated by the semiconductor elements 2 and 3 is radiated upward from the upper end surface 4a of the gate terminal 4, the upper end surface 5a of the source terminal 5, the upper end surfaces 6a of the drain terminals 6, and the upper end surface 7a of the anode terminal 7, these upper end surfaces being exposed from the resin material 10. Further, heat is radiated downward from the drain-electrode radiator plate 1 arranged at the back surfaces of the semiconductor elements 2 and 3. Thus, the heat radiation performance of the power module 100 is markedly increased.

The drain-electrode radiator plate 1 can be easily joined to the back surfaces of the semiconductor elements 2 and 3 respectively through the joint materials 8.

Since the drain-electrode radiator plate 1 is formed of a metal plate, heat radiation performance from the drain-electrode radiator plate 1 can be increased. The surface of the drain-electrode radiator plate 1 is exposed from the resin material 10. Hence, as compared with a case in which the surface of the drain-electrode radiator plate 1 is covered with the resin material 10, the heat radiation performance is obviously increased.

Also, in this embodiment, since the semiconductor elements 2 and 3 use SiC, as compared with a case in which the semiconductor elements 2 and 3 use Si, a switching operation at a higher speed can be performed under high-temperature environment.

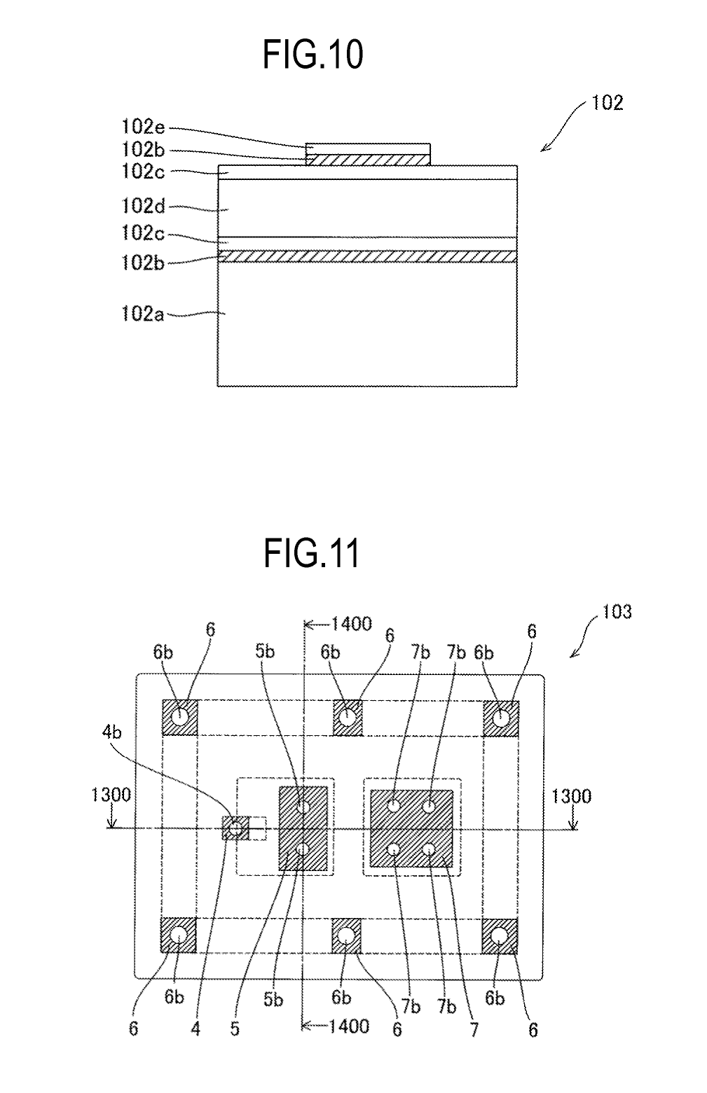

An advantage of the first embodiment is described on the basis of a simulation result of a thermal resistance. The simulation result was obtained through a simulation using a module 101 (see FIG. 9) according to Example 1 of the first embodiment and a module 102 (see FIG. 10) according to Comparative Example 1 as models.

Referring to FIG. 9, in the module 101 according to Example 1 of the first embodiment, a semiconductor element 101c made of SiC is joined to a surface of a lower-surface case 101a (corresponding to the drain-electrode radiator plate 1) made of copper molybdenum through solder (a joint material) 101b made of Pb-5Sn. It is to be noted that the semiconductor element 101c contain a field effect transistor (FET) (corresponding to the semiconductor element 2) and a Schottky barrier diode (corresponding to the semiconductor element 3). A terminal 101d (corresponding to the gate terminal 4, the source terminal 5, the drain terminals 6, and the anode terminal 7) made of copper molybdenum is joined to a surface of the semiconductor element 101c through solder (a joint material) 101b made of Pb-10Sn. An upper-surface case 101e made of copper molybdenum is joined to a surface of the terminal 101d through solder (a joint material) 101b made of Sn—Sb.

Referring to FIG. 10, in the module 102 according to Comparative Example 1, a copper wire 102c is joined to a surface of a lower-surface case 102a made of copper through solder 102b made of Pb-5Sn. A SiN substrate 102d is arranged on a surface of the copper wire 102c. A copper wire 102c is provided on a surface of the SiN substrate 102d. A semiconductor element 102e made of SiC is joined to a surface of the copper wire 102c through solder (a joint material) 102b made of Pb-5Sn.

The module 101 (Example 1) has a thermal resistance that is the sum of a thermal resistance from the semiconductor element 101c to the lower-surface case 101a and a thermal resistance from the semiconductor element 101c to the upper-surface case 101e. The total thermal resistance of the module 101 (Example 1) was 0.206 (K/W). The thermal resistance in a case in which the solder 101b is not provided between the terminal 101d and the upper-surface case 101e was 0.204 (K/W). In contrast, the module 102 (Comparative Example 1) had a thermal resistance from the semiconductor element 102e to the lower-surface case 102a of 0.422 (K/W). Thus, it was determined that the heat radiation performance of the module 101 (Example 1) is better than the heat radiation performance of the module 102 (Comparative Example 1).

An advantage of the first embodiment is described on the basis of simulation results of an inductance and a resistance value.

It was assumed that a module according to Example 2 of the first embodiment includes a field effect transistor (FET) (corresponding to the semiconductor element 2) formed on a SiC substrate having silicon carbide (SiC) as the main constituent, and a Schottky barrier diode (corresponding to the semiconductor element 3). In contrast, it was assumed that a module according to Comparative Example 2 includes an insulated-gate bipolar transistor (IGBT) formed on a Si substrate having silicon (Si) as the main constituent.

Using the module according to Example 2, a simulation was held for an average inductance value and an average resistance value between a source (corresponding to the source terminal 5) and a drain (corresponding to the drain terminal 6). Also, using the module according to Comparative Example 2, a simulation was held for an average inductance value and an average resistance value between an emitter and a collector. As the result of the simulation, the average inductance value of the module according to Example 2 was about 55% of the average inductance value of the module according to Comparative Example 2. Also, the average resistance value of the module according to Example 2 was about 7% of the average resistance value of the module according to Comparative Example 2. Thus, it was determined that the average inductance value and the average resistance value of the module having SiC as the main constituent according to Example 2 is smaller than those of the module having Si as the main constituent according to Comparative Example 2.

### Second Embodiment

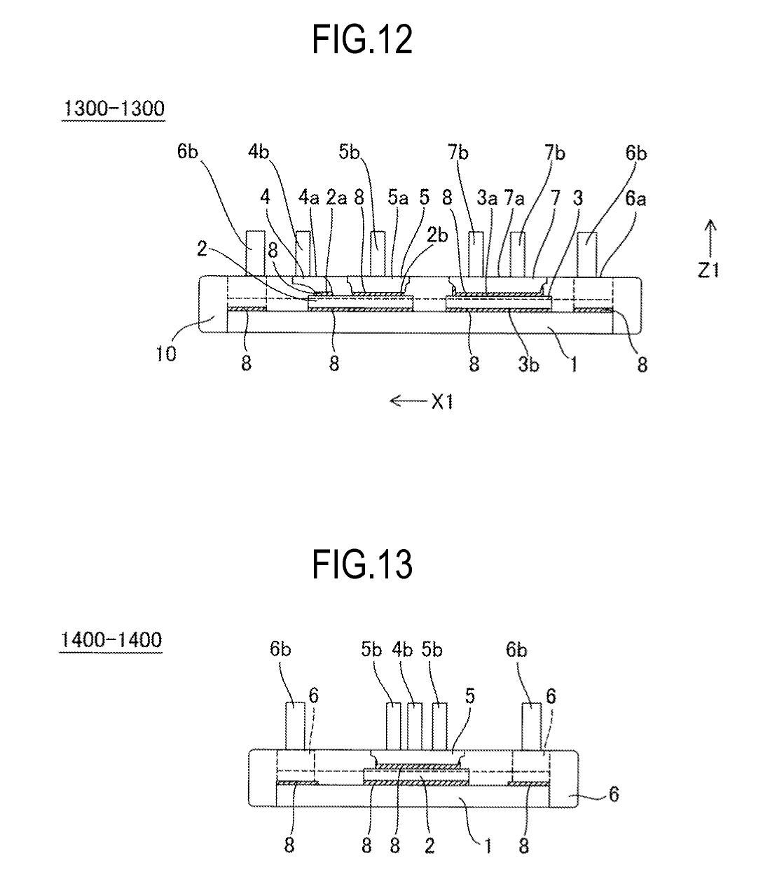

A second embodiment is described. Referring to FIGS. 11 to 13, a power module 103 includes a gate metal terminal 4b, source metal terminals 5b, drain metal terminals 6b, and anode metal terminals 7b that are respectively connected with the upper end surface 4a of the gate terminal 4, the upper end surface 5a of the source terminal 5, the upper end surfaces 6a of the drain terminals 6, and the upper end surface 7a of the anode terminal 7, for connection with, for example, a wiring board (not shown). The gate metal terminal 4b, the source metal terminals 5b, the drain metal terminals 6b, and the anode metal terminals 7b each have a substantially columnar shape (a substantially pin-like shape) and are connected with the upper end surface 4a, the upper end surface 5a, the upper end surfaces 6a, and the upper end surface 7a respectively through joint materials. The gate metal terminal 4b, the source metal terminals 5b, the drain metal terminals 6b, and the anode metal terminals 7b may be respectively integrally formed with the gate terminal 4, the source terminal 5, the drain terminals 6, and the anode terminal 7. In this case, since joint materials are not provided, a thermal resistance is decreased and hence heat radiation performance is increased. The other configuration and advantage of the second embodiment are similar to those of the first embodiment.

### Third Embodiment

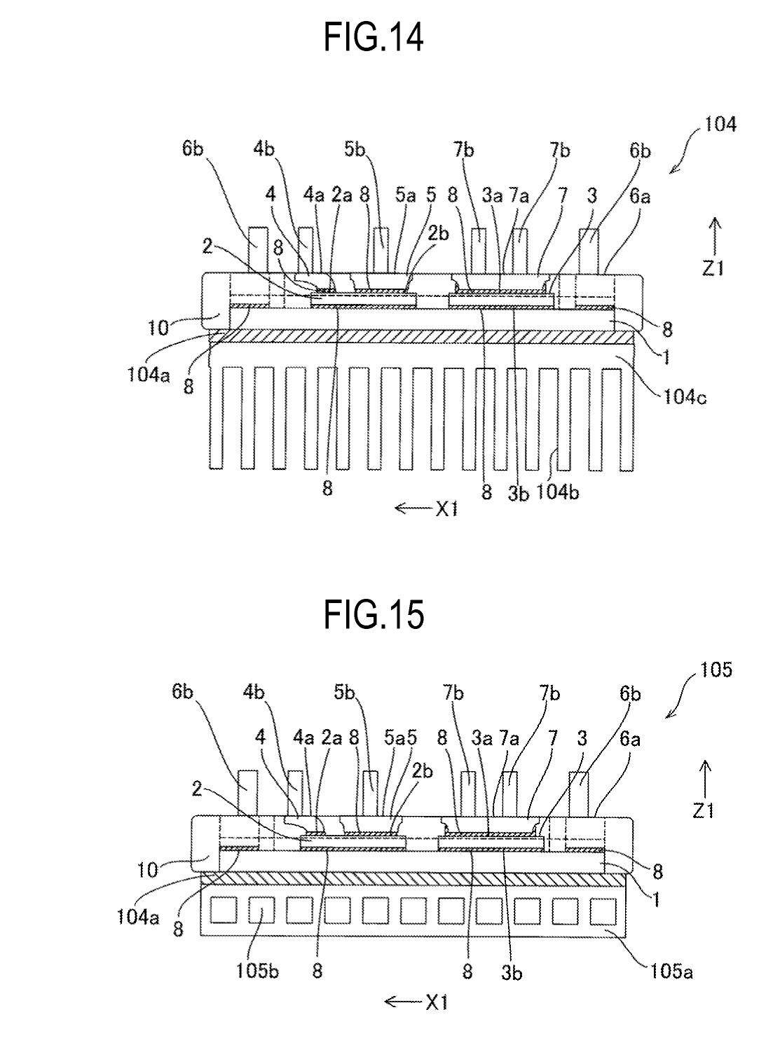

A third embodiment is described. Referring to FIG. 14, a power module 104 includes a heat sink 104c having a plurality of fins 104b. The heat sink 104c is provided at the lower surface of the drain-electrode radiator plate 1 through an insulating material 104a, such as a thermal-conductive sheet and grease. The insulating material 104a may be any material as long as the material has an insulating function and a high thermal conductivity. The heat sink 104c is an example of a “cooling structure” that is disclosed. The other configuration of the third embodiment is similar to that of the first embodiment.

With this embodiment, since the heat sink 104c is provided at the lower surface of the drain-electrode radiator plate 1 and hence heat that is transferred to the drain-electrode radiator plate 1 is radiated from the heat sink 104c, the heat radiation performance can be further increased.

Also, since the insulating material 104a is arranged between the heat sink 104c and the drain-electrode radiator plate 1, electric power does not leak from the drain-electrode radiator plate 1 to the heat sink 104c. The other advantage is similar to that of the first embodiment.

### Fourth Embodiment

A fourth embodiment is described. Referring to FIG. 15, a power module 105 includes a liquid-cooling jacket 105a provided at the lower surface of the drain-electrode radiator plate 1 through the insulating material 104a, such as the thermal-conductive sheet and grease. A solvent path 105b, through which a cooling solvent flows, is provided in the liquid-cooling jacket 105a. Heat generated by the semiconductor elements 2 and 3 is radiated through the cooling solvent that circulates through the solvent path 105b. The liquid-cooling jacket 105a is an example of a “cooling structure” that is disclosed. The other configuration of the fourth embodiment is similar to that of the first embodiment. Also, with the fourth embodiment, the advantage of increasing the heat radiation performance can be obtained like the third embodiment.

### Fifth Embodiment

A fifth embodiment is described. In this embodiment, the power module 100 in the first embodiment (power module body portions 100a and 100b) is attached to a wiring board 21.

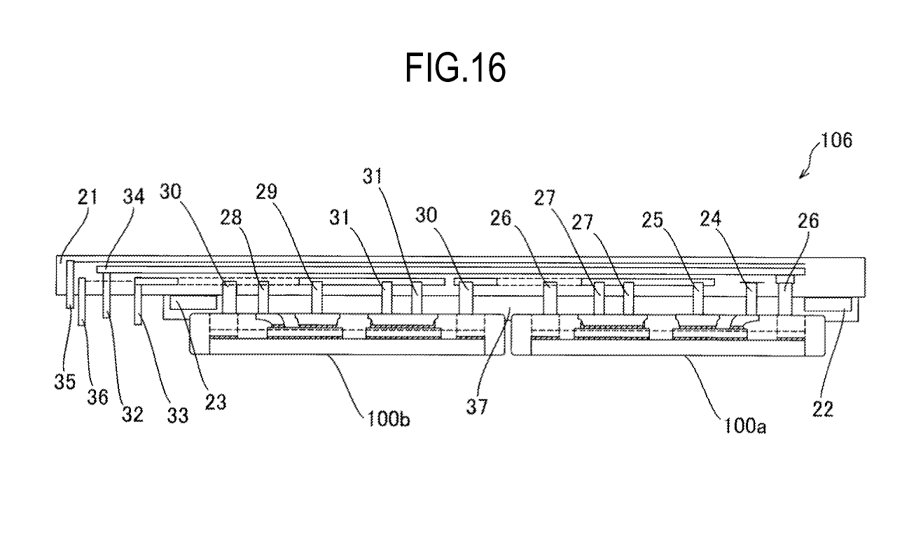

Referring to FIG. 16, in a power module 106, the power module body portions 100a and 100b are attached to the wiring board 21 formed of glass epoxy, ceramic, or polyimide. Also, a P gate driver IC 22 and an N gate driver IC 23 are mounted on a lower surface of the wiring board 21. The power module 106 includes a three-phase inverter circuit. The power module body portion 100a has a function as an upper arm of the three-phase inverter circuit, and the power module body portion 100b has a function as a lower arm of the three-phase inverter circuit.

The power module body portion 100a is attached to the wiring board 21 through a P gate metal terminal 24, a P source metal terminal 25, P drain metal terminals 26, and P anode metal terminals 27. The P gate metal terminal 24, the P source metal terminal 25, the P drain metal terminals 26, and the P anode metal terminals 27 are formed in substantially pin-like shapes (substantially columnar shapes). In particular, in this embodiment, the substantially flat upper end surface 4a (the upper end surface 5a, the upper end surfaces 6a, the upper end surface 7a) (see FIG. 1) of the gate terminal 4 (the source terminal 5, the drain terminals 6, the anode terminal 7) exposed from the surface of the resin material 10 is electrically connected with the wiring board 21 through the P gate metal terminal 24 (the P source metal terminal 25, the P drain metal terminals 26, the P anode metal terminals 27). Also, the power module body portion 100b is attached to the wiring board 21 through an N gate metal terminal 28, an N source metal terminal 29, N drain metal terminals 30, and N anode metal terminals 31. The N gate metal terminal 28, the N source metal terminal 29, the N drain metal terminals 30, and the N anode metal terminals 31 are formed in substantially pin-like shapes (substantially columnar shapes). In particular, in this embodiment, the substantially flat upper end surface 4a (the upper end surface 5a, the upper end surfaces 6a, the upper end surface 7a) (see FIG. 1) of the gate terminal 4 (the source terminal 5, the drain terminals 6, the anode terminal 7) exposed from the surface of the resin material 10 is electrically connected with the wiring board 21 through the N gate metal terminal 28 (the N source metal terminal 29, the N drain metal terminals 30, the N anode metal terminals 31).

A P metal terminal 32 and an N metal terminal 33 are provided at one end of the wiring board 21. The P metal terminal 32 is connected with the P drain metal terminal 26 of the power module body portion 100a through busbar-like wiring 34 made of a conductive metal plate provided in the wiring board 21. The P source metal terminal 25 and the P anode metal terminals 27 of the power module body portion 100a are connected with the N drain metal terminal 30 of the power module body portion 100b through wiring 34 provided in the wiring board 21. The N source metal terminal 29 and the N anode metal terminals 31 of the power module body portion 100b are connected with the N metal terminal 33 provided at the one end of the wiring board 21 through wiring 34 provided in the wiring board 21.

The P gate driver IC 22 is arranged near the P gate metal terminal 24 of the power module body portion 100a, and between the wiring board 21 and the power module body portion 100a. That is, the gap between the wiring board 21 and the power module body portion 100a is larger than the thickness of the P gate driver IC 22. Also, the P gate driver IC 22 is connected with a P control signal terminal 35 provided at the one end of the wiring board 21.

The N gate driver IC 23 is arranged near the N gate metal terminal 28 of the power module body portion 100b, and between the wiring board 21 and the power module body portion 100b. That is, the gap between the wiring board 21 and the power module body portion 100b is larger than the thickness of the N gate driver IC 23. Also, the N gate driver IC 23 is connected with an N control signal terminal 36 provided at the one end of the wiring board 21.

Since the P gate driver IC 22 and the N gate driver IC 23 are respectively arranged near the metal terminals of the power module body portions 100a and 100b, a wiring inductance can be decreased. Hence, high-frequency switching can be performed for the semiconductor elements 2 and 3.

The wiring board 21 and the power module body portions 100a and 100b are arranged with a predetermined distance (space) interposed therebetween. The space between the wiring board 21 and the power module body portions 100a and 100b is filled with an insulating resin material 37 having a sealing function. Accordingly, the wiring board 21 and the power module body portions 100a and 100b are fixed together. Also, the resin material 37 can restrict corrosion of the P gate metal terminal 24, the P source metal terminal 25, the P drain metal terminals 26, the P anode metal terminals 27, the N gate metal terminal 28, the N source metal terminal 29, the N drain metal terminals 30, and the N anode metal terminals 31 that connect the wiring board 21 with the power module body portions 100a and 100b. The material of the insulating resin material 37 is properly selected in accordance with temperatures of heat generated by the semiconductor elements 2 and 3. The P gate metal terminal 24, the P source metal terminal 25, the P drain metal terminals 26, the P anode metal terminals 27, the N gate metal terminal 28, the N source metal terminal 29, the N drain metal terminals 30, and the N anode metal terminals 31 each are an example of a substantially pin-like “terminal.”

In this embodiment, since the wiring board 21 that is electrically connected with the substantially flat upper end surface 4a (the upper end surface 5a, the upper end surfaces 6a, the upper end surface 7a) of the gate terminal (the source terminal 5, the drain terminals 6, the anode terminal 7) exposed from the upper surface of the resin material 10 is provided, electric power can be easily fed to the gate terminal 4 (the source terminal 5, the drain terminals 6, the anode terminal 7) through the wiring board 21.

In this embodiment, the substantially flat upper end surface 4a (the upper end surface 5a, the upper end surfaces 6a, the upper end surface 7a) of the gate terminal (the source terminal 5, the drain terminals 6, the anode terminal 7) exposed from the upper surface of the resin material 10 is electrically connected with the wiring board 21 through the substantially pin-like P gate metal terminal (the P source metal terminal 25, the P drain metal terminals 26, the P anode metal terminals 27). Also, the substantially flat upper end surface 4a (the upper end surface 5a, the upper end surfaces 6a, the upper end surface 7a) of the gate terminal 4 (the source terminal 5, the drain terminals 6, the anode terminal 7) is electrically connected with the wiring board 21 through the N gate metal terminal (the N source metal terminal 29, the N drain metal terminals 30, the N anode metal terminals 31). Thus, the substantially flat upper end surface 4a (the upper end surface 5a, the upper end surfaces 6a, the upper end surface 7a) of the gate terminal 4 (the source terminal 5, the drain terminals 6, the anode terminal 7) can be easily electrically connected with the wiring board 21.

### Sixth Embodiment

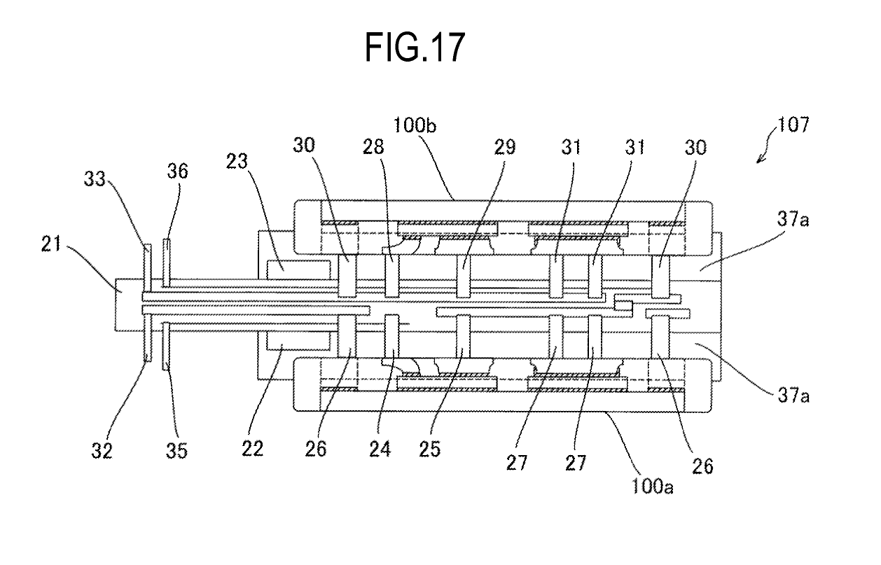

A sixth embodiment is described. Referring to FIG. 17, in a power module 107, the power module body portion 100b and the power module body portion 100a are arranged respectively at an upper surface and a lower surface of the wiring board 21. With this arrangement, the length of wiring that connects the power module body portion 100a with the power module body portion 100b is decreased and hence a wiring inductance can be decreased. Accordingly, high-frequency switching can be performed for the semiconductor elements 2 and 3.

An insulating resin material 37a is provided to seal the gap between the power module body portion 100a and the wiring board 21 and the gap between the power module body portion 100b and the wiring board 21. The resin material 37a is provided to cover an area from surfaces of the wiring board 21 to center portions of side surfaces of the power module body portions 100a and 100b. Hence, the resin material 37a can restrict corrosion of the P gate metal terminal 24, the P source metal terminal 25, the P drain metal terminals 26, the P anode metal terminals 27, the N gate metal terminal 28, the N source metal terminal 29, the N drain metal terminals 30, and the N anode metal terminals 31 that connect the wiring board 21 with the power module body portions 100a and 100b.

The other advantage of this embodiment is similar to that of the fifth embodiment.

### Seventh Embodiment

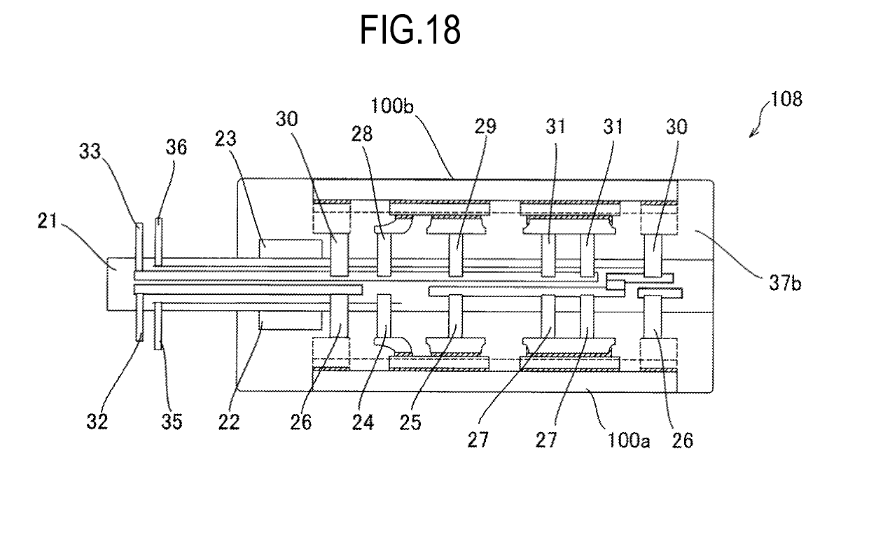

A seventh embodiment is described. Referring to FIG. 18, a power module 108 is provided such that an insulating resin material 37b having a sealing function covers side surfaces of the power module body portions 100a and 100b. Hence, upper surfaces of the resin material 37b are respectively flush with upper surfaces of the power module body portions 100a and 100b. Accordingly, coolers can be easily attached to the upper surfaces of the power module body portions 100a and 100b (drain-electrode radiator plates 1). Also, cooling effect of the power module body portions 100a and 100b is increased. The other advantage of this embodiment is similar to those of the fifth and sixth embodiments.

### Eighth Embodiment

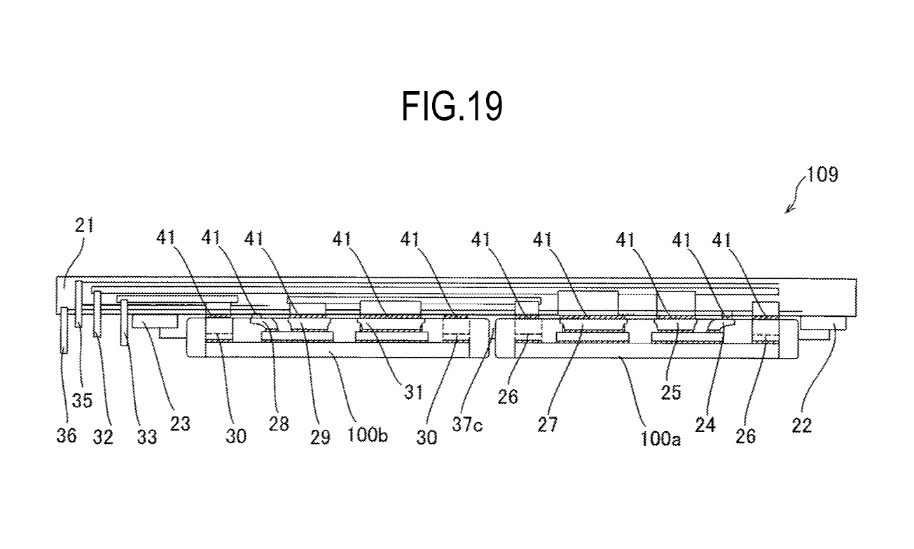

An eighth embodiment is described. Referring to FIG. 19, in a power module 109, the upper end surface 4a (the upper end surface 5a, the upper end surfaces 6a, the upper end surface 7a) (see FIG. 1) of the gate terminal 4 (the source terminal 5, the drain terminals 6, the anode terminal 7) of each of the power module body portions 100a and 100b is connected with the wiring board 21 through bump electrodes 41. A resin material 37c is provided between the power module body portions 100a and 100b and the wiring board 21.

In this embodiment, the substantially flat upper end surface 4a (the upper end surface 5a, the upper end surfaces 6a, the upper end surface 7a) of the gate terminal (the source terminal 5, the drain terminals 6, the anode terminal 7) exposed from the upper surface of the resin material 10 is electrically connected with the wiring board 21 through the bump electrode 41. Accordingly, the gap between the substantially flat upper end surface 4a (the upper end surface 5a, the upper end surfaces 6a, the upper end surface 7a) of the gate terminal 4 (the source terminal 5, the drain terminals 6, the anode terminal 7) and the wiring board 21 can be decreased. Hence the resin material 37c restricts corrosion of the gate terminal 4 (the source terminal 5, the drain terminals 6, the anode terminal 7) and the wiring board 21.

### Ninth Embodiment

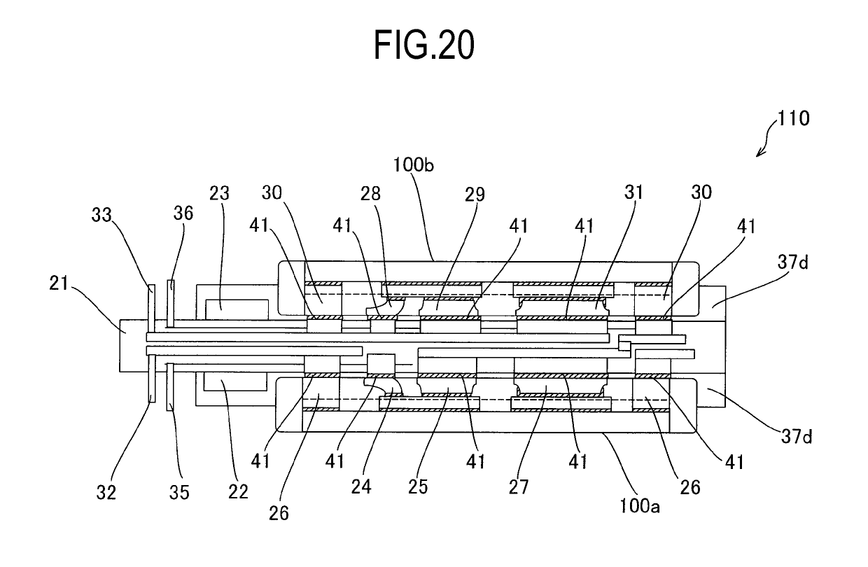

A ninth embodiment is described. Referring to FIG. 20, in a power module 110, the upper end surface 4a (the upper end surface 5a, the upper end surfaces 6a, the upper end surface 7a) of the gate terminal 4 (the source terminal 5, the drain terminals 6, the anode terminal 7) of each of the power module body portions 100a and 100b is connected with the wiring board 21 through the bump electrodes 41. A resin material 37d is provided between the power module body portion 100a and the wiring board 21 and between the power module body portion 100b and the wiring board 21. Since the power module body portions 100a and 100b are connected with the wiring board 21 through the bump electrodes 41, the gap between the power module body portion 100a and the wiring board 21 and the gap between the power module body portion 100b and the wiring board 21 are decreased. Accordingly, an advantage of restricting corrosion of terminals is obtained and hence the resin material 37d may be occasionally omitted.

### Tenth Embodiment

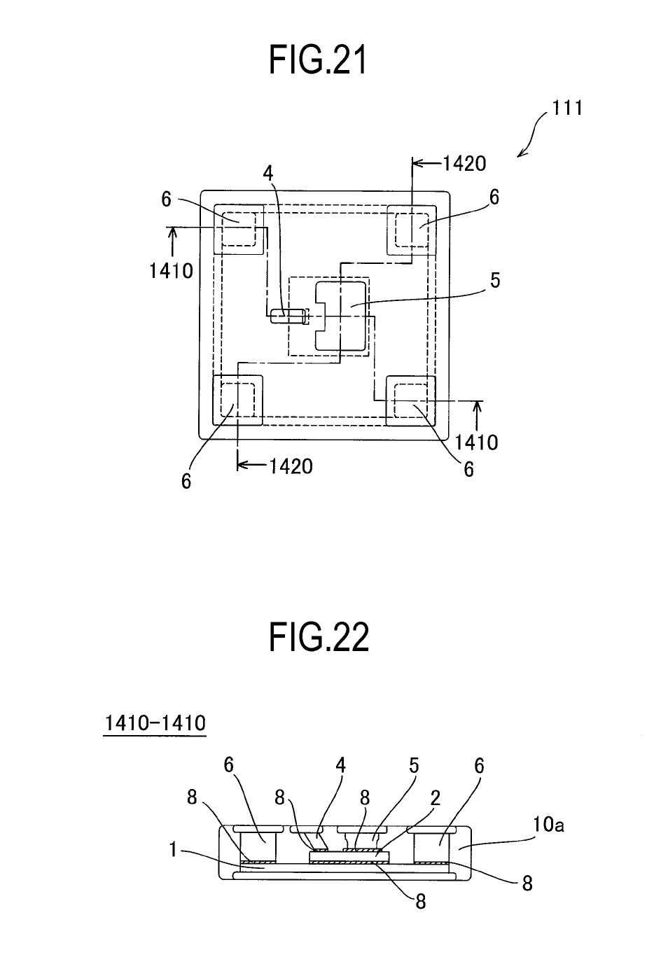

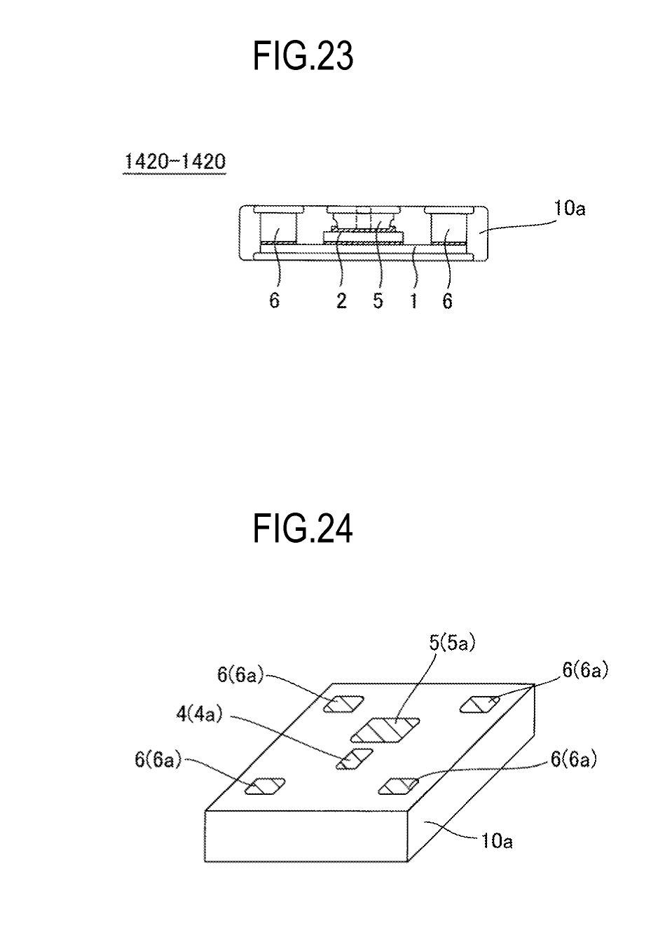

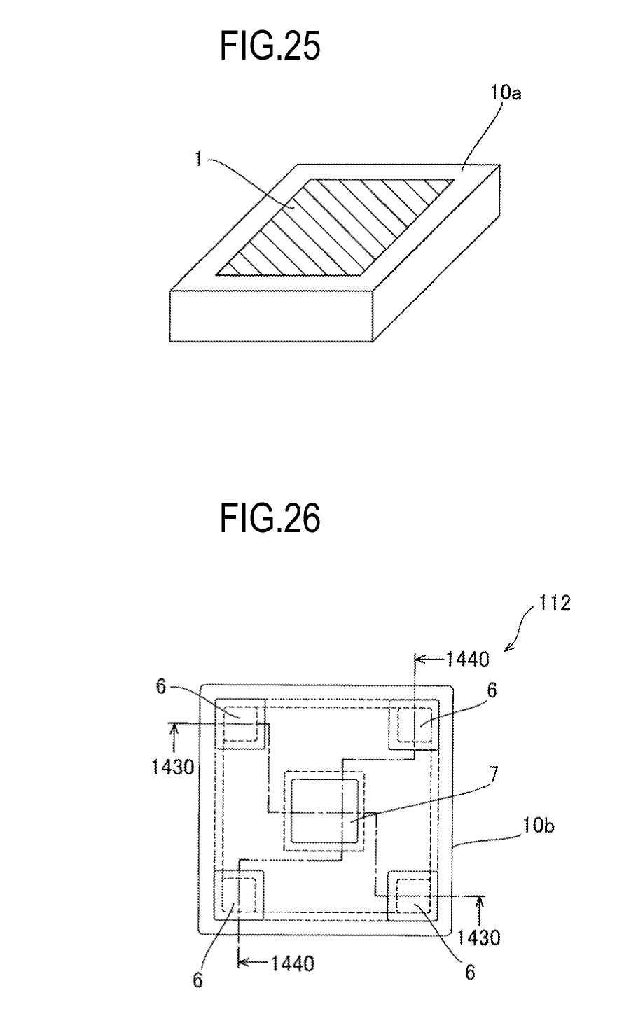

A tenth embodiment is described. Referring to FIGS. 21 to 23, a power module 111 includes only the semiconductor element 2. Referring to FIG. 24, the upper end surface 4a of the gate terminal 4, the upper end surface 5a of the source terminal 5, and the upper end surfaces 6a of the drain terminals 6 are exposed from a resin material 10a at an upper surface of the power module 111. Referring to FIG. 25, the drain-electrode radiator plate 1 is exposed from the resin material 10a at a lower surface of the power module 111.

### Eleventh Embodiment

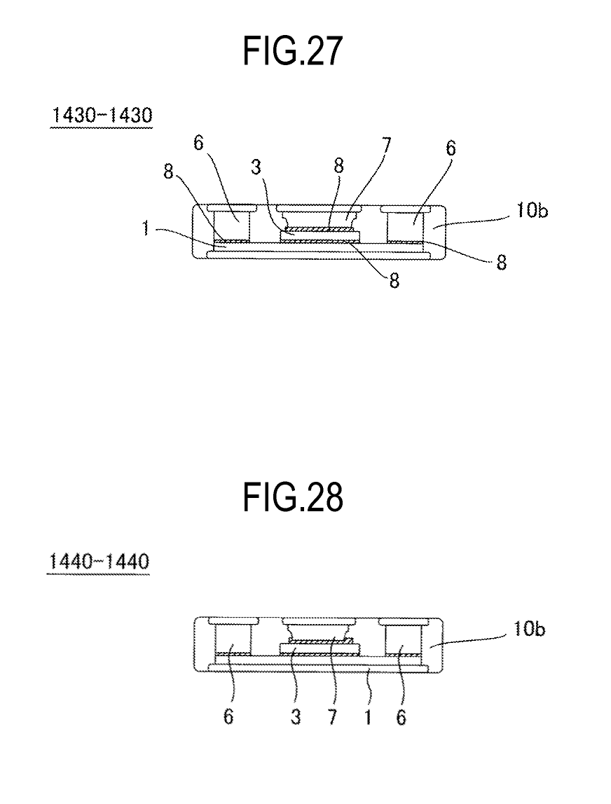

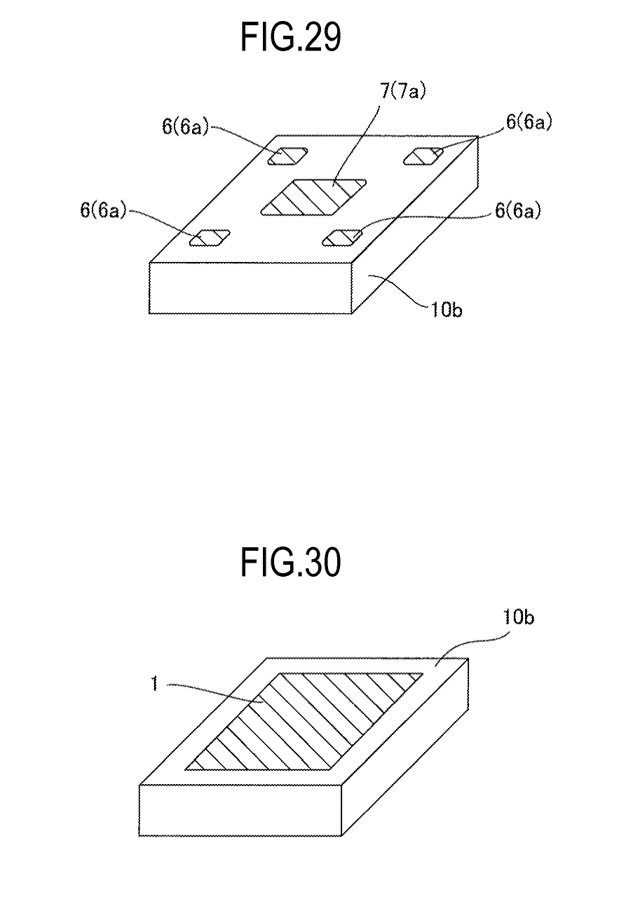

An eleventh embodiment is described. Referring to FIGS. 26 to 28, a power module 112 includes only the semiconductor element 3. Referring to FIG. 29, the upper end surface 7a of the anode terminal 7 and the upper end surfaces 6a of the drain terminals 6 are exposed from a resin material 10b at an upper surface of the power module 112. Referring to FIG. 30, the drain-electrode radiator plate 1 is exposed from the resin material 10b at a lower surface of the power module 112.

### Twelfth Embodiment

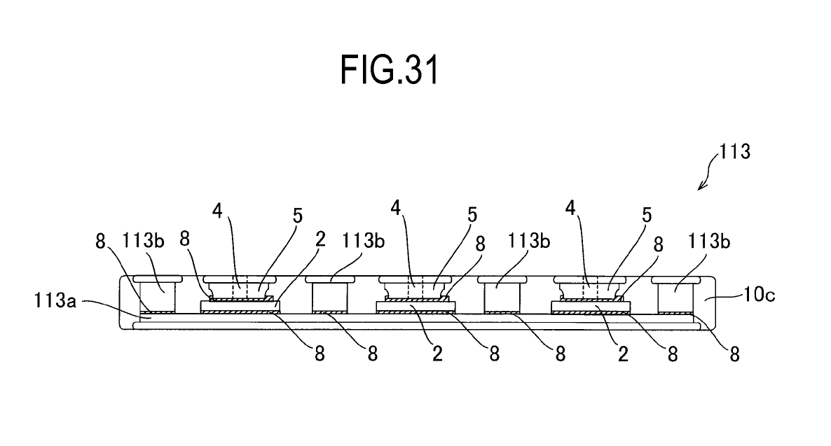

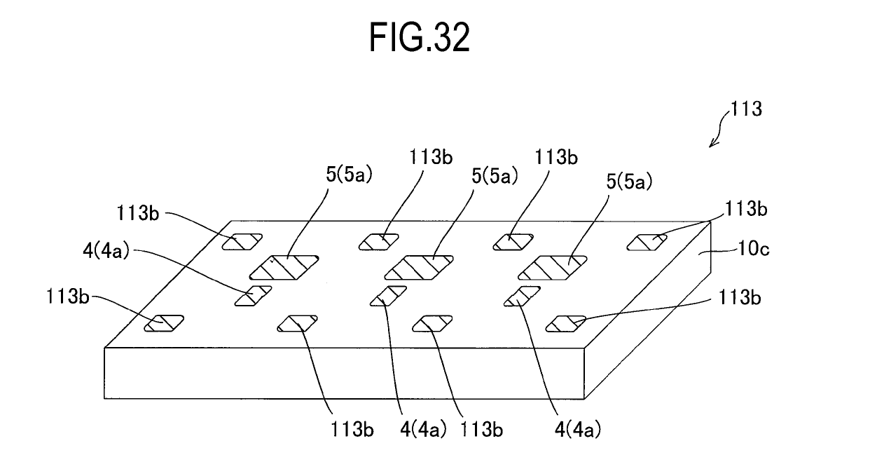

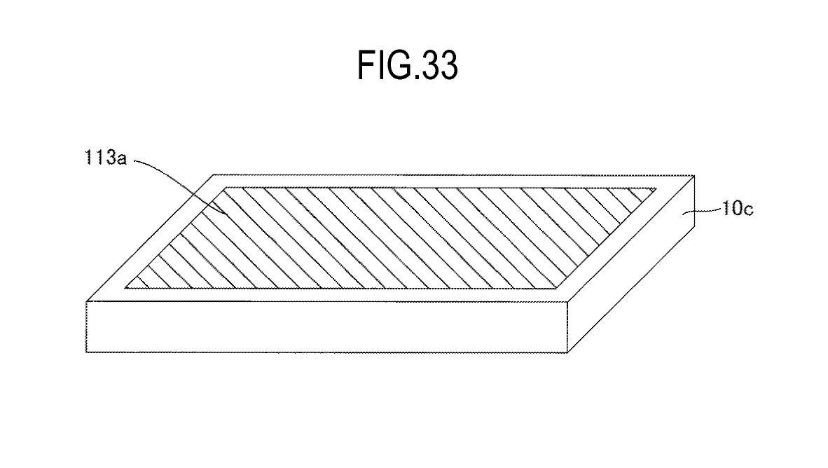

A twelfth embodiment is described. Referring to FIG. 31, a power module 113 includes three semiconductor elements 2. The power module 113 includes a P three-phase circuit. Lower surfaces of the three semiconductor elements 2 are connected with a single P potential metal radiator plate 113a through joint materials 8. Referring to FIG. 32, the upper end surface 4a of the gate terminal 4, the upper end surface 5a of the source terminal 5 of each of the three semiconductor elements 2, and upper end surfaces of P potential metal terminals 113b that also serve as drain terminals are exposed from a resin material 10c at an upper surface of the power module 113. Referring to FIG. 33, the P potential metal radiator plate 113a is exposed from the resin material 10c at a lower surface of the power module 113. The P potential metal radiator plate 113a is an example of a “radiator member” that is disclosed.

### Thirteenth Embodiment

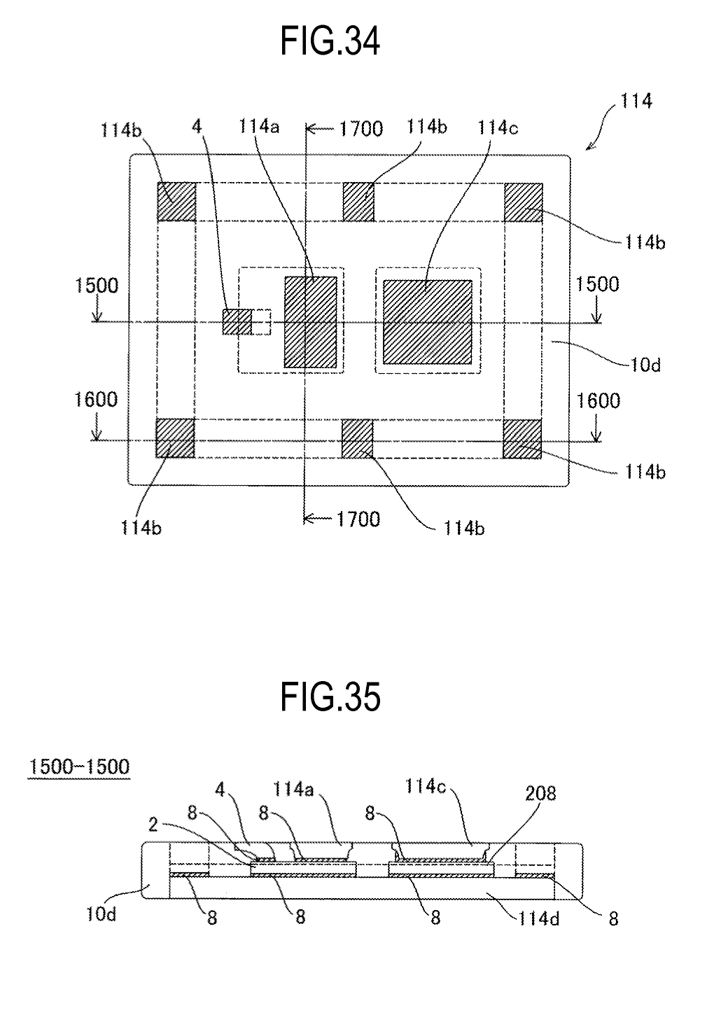

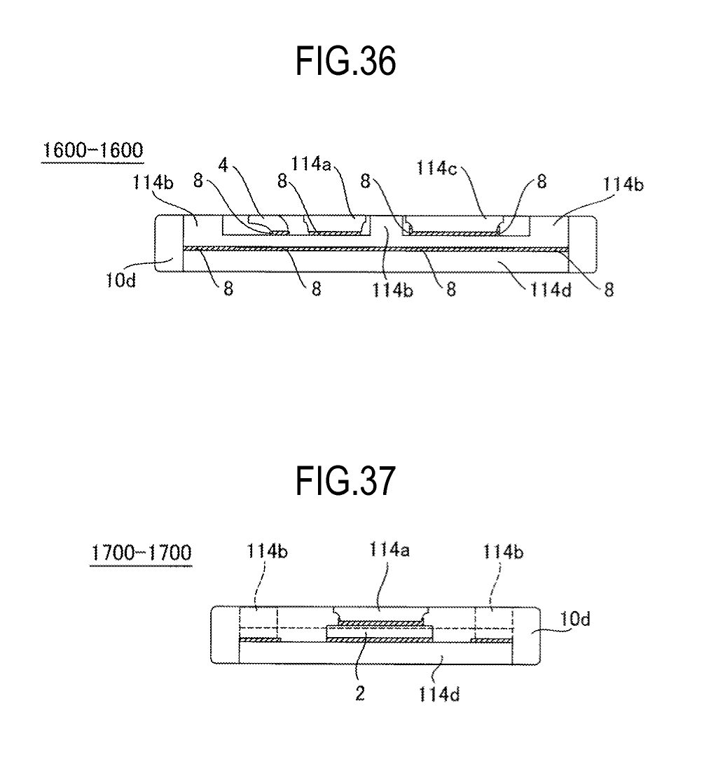

A thirteenth embodiment is described. Referring to FIGS. 34 to 37, a power module 114 includes six source terminals 114b to surround the gate terminal 4, a drain terminal 114a, and a cathode terminal 114c (described later). That is, the power module 114 has a structure in which the source terminal 5 and the drain terminals 6 of the power module 100 (see FIG. 1) according to the first embodiment are exchanged. Also, the cathode terminal 114c is provided at the surface of the semiconductor element 3 through a joint material 8. The semiconductor element 2 and the semiconductor element 3 are provided at a surface of a source-electrode radiator plate 114d respectively through joint materials 8. The source-electrode radiator plate 114d is an example of a “radiator member” that is disclosed. Upper end surfaces of the gate terminal 4, the drain terminal 114a, the source terminals 114b, and the cathode terminal 114c are exposed from an upper surface of a resin material 10d.

### Fourteenth Embodiment

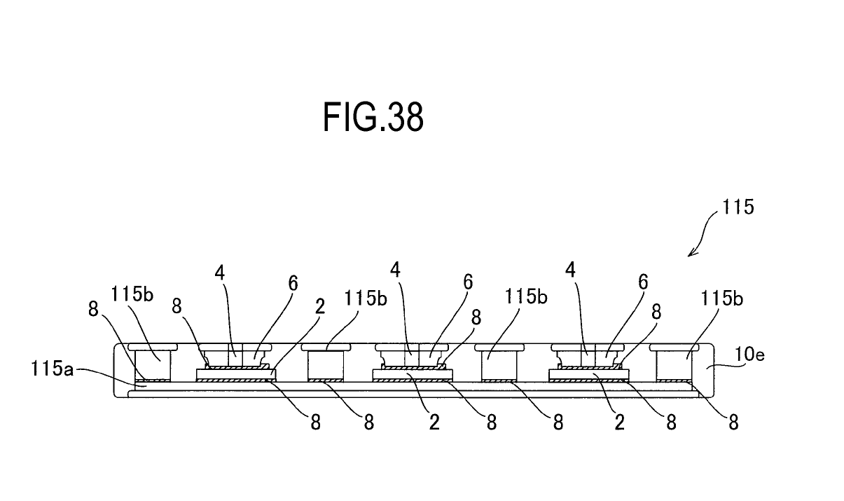

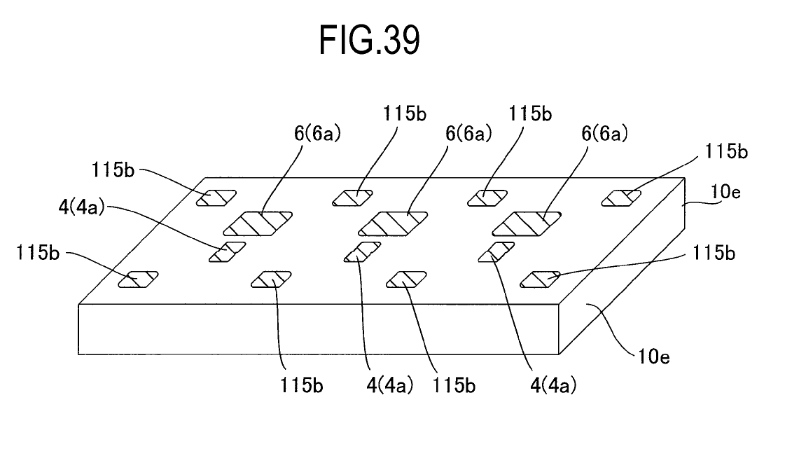

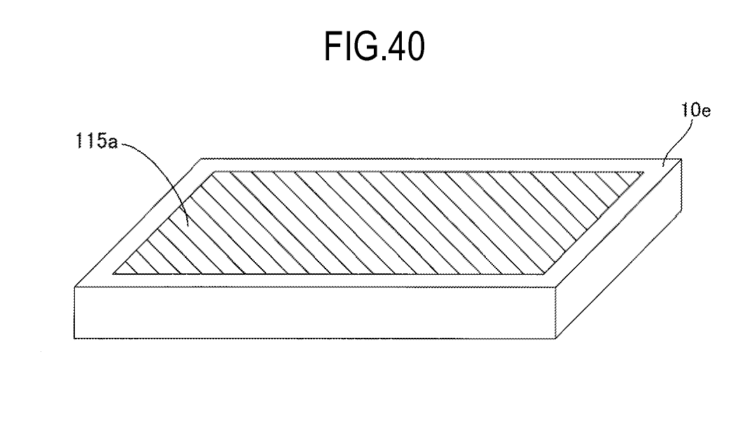

A fourteenth embodiment is described. Referring to FIG. 38, a power module 115 includes the three semiconductor elements 2. The power module 115 includes an N three-phase circuit. Lower surfaces of the three semiconductor elements 2 are connected with a single N potential metal radiator plate 115a through joint materials 8. Referring to FIG. 39, upper end surfaces 4a of gate terminals 4 that are respectively connected with the three semiconductor elements 2, and upper end surfaces of N potential metal terminals 115b that also serve as source terminals are exposed from a resin material 10e at an upper surface of the power module 115. Referring to FIG. 40, the N potential metal radiator plate 115a is exposed from the resin material 10e at a lower surface of the power module 115. The N potential metal radiator plate 115a is an example of a “radiator member” that is disclosed.

### Fifteenth Embodiment

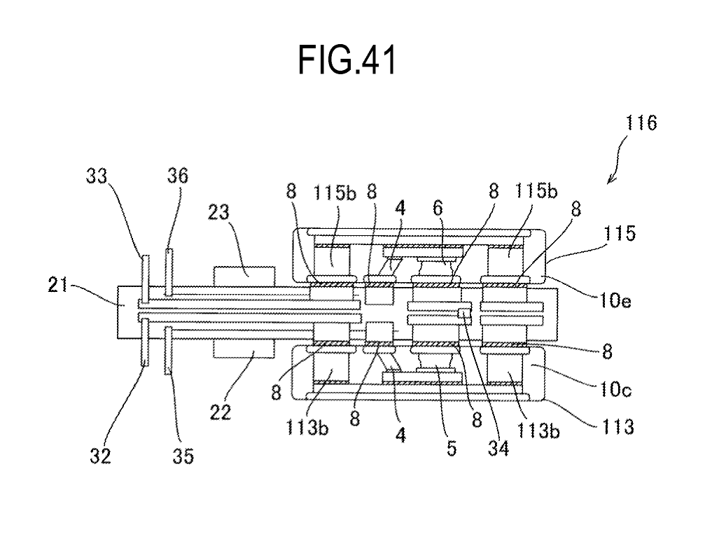

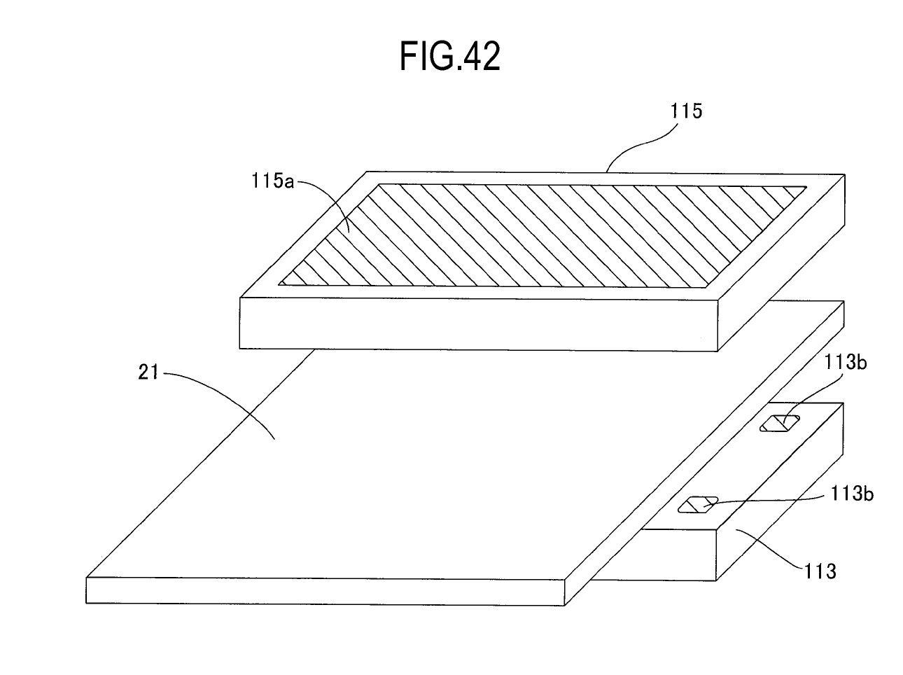

A fifteenth embodiment is described. Referring to FIGS. 41 and 42, a power module 116 includes a P three-phase power module 113 at a lower surface of the wiring board 21. Also, an N three-phase power module 115 is provided at an upper surface of the wiring board 21. The source terminal 5 of the power module 113 is connected with the drain terminal 6 of the power module 115 through wiring 34 provided in the wiring board 21. The P metal terminal 32 and the P control signal terminal 35 are provided at the lower surface of the wiring board 21. Also, the N metal terminal 33 and the N control signal terminal 36 are provided at the upper surface of the wiring board 21.

### Sixteenth Embodiment

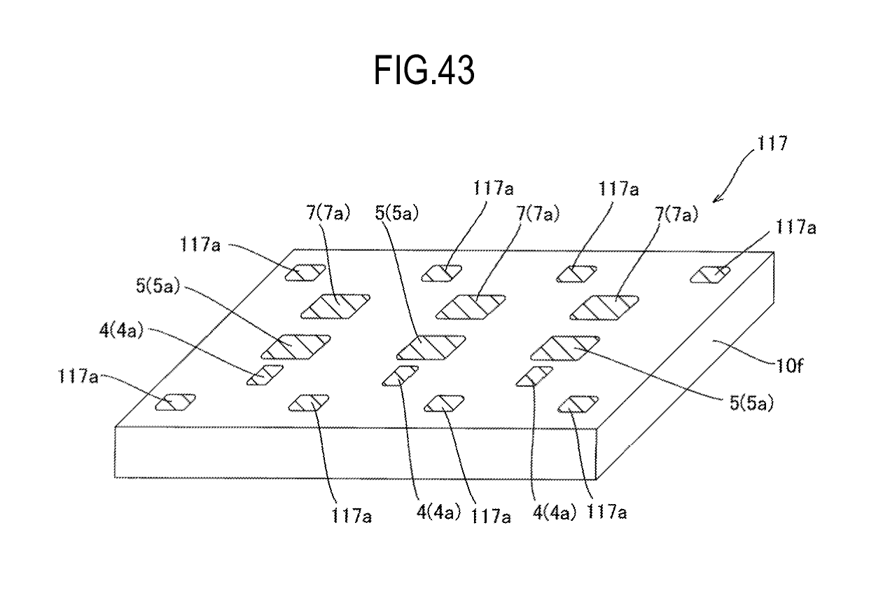

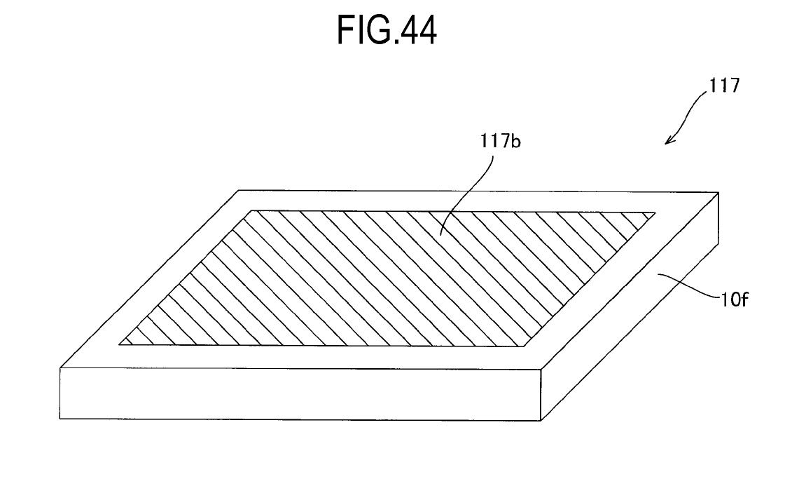

A sixteenth embodiment is described. Referring to FIG. 43, a power module 117 is provided with a free wheel diode. The upper end surfaces 4a of the gate terminals 4, the upper end surfaces 5a of the source terminals 5, the upper end surfaces 7a of the anode terminals 7 of the free wheel diode, and upper end surfaces of P potential metal terminals 117a also having functions as drain terminals and cathode terminals are exposed from a resin material 10f at an upper surface of the power module 117. Referring to FIG. 44, a P potential metal radiator plate 117b is exposed from the resin material 10f at a lower surface of the power module 117. The P potential metal radiator plate 117b is an example of a “radiator member” that is disclosed.

### Seventeenth Embodiment

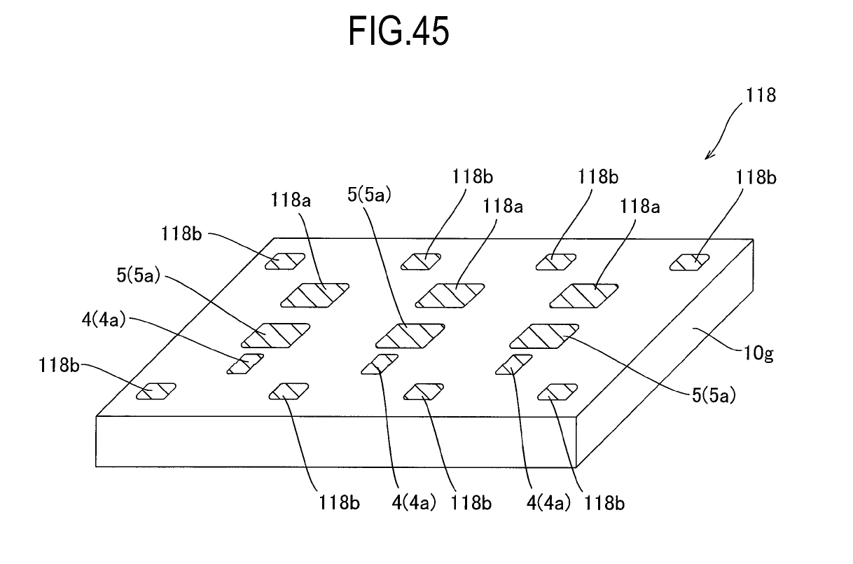

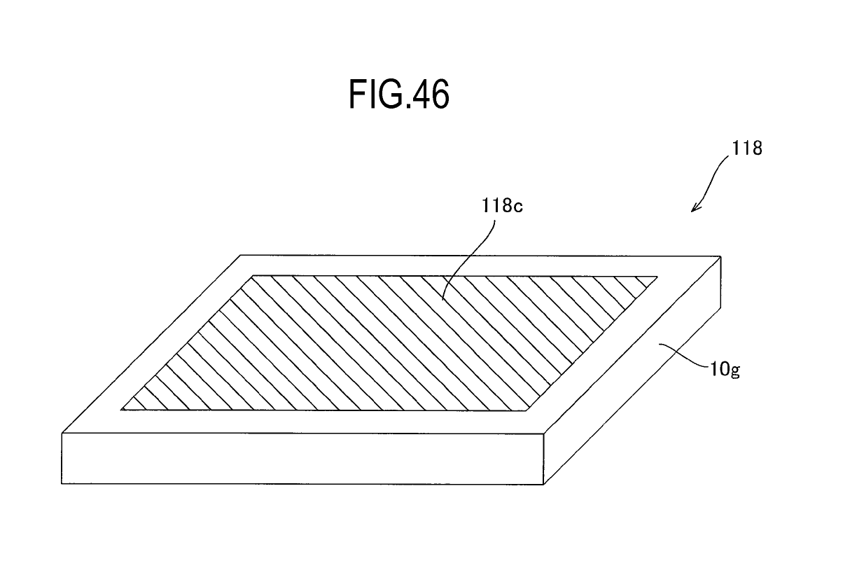

A seventeenth embodiment is described. Referring to FIG. 45, a power module 118 is provided with a free wheel diode. The upper end surfaces 4a of the gate terminals 4, the upper end surfaces 5a of the source terminals 5, cathode terminals 118a of the free wheel diode, and N potential metal terminals 118b also having functions as drain terminals and anode terminals are exposed from a resin material 10g at an upper surface of the power module 118. Referring to FIG. 46, an N potential metal radiator plate 118c is exposed from the resin material 10g at a lower surface of the power module 118. The N potential metal radiator plate 118c is an example of a “radiator member” that is disclosed.

### Eighteenth Embodiment

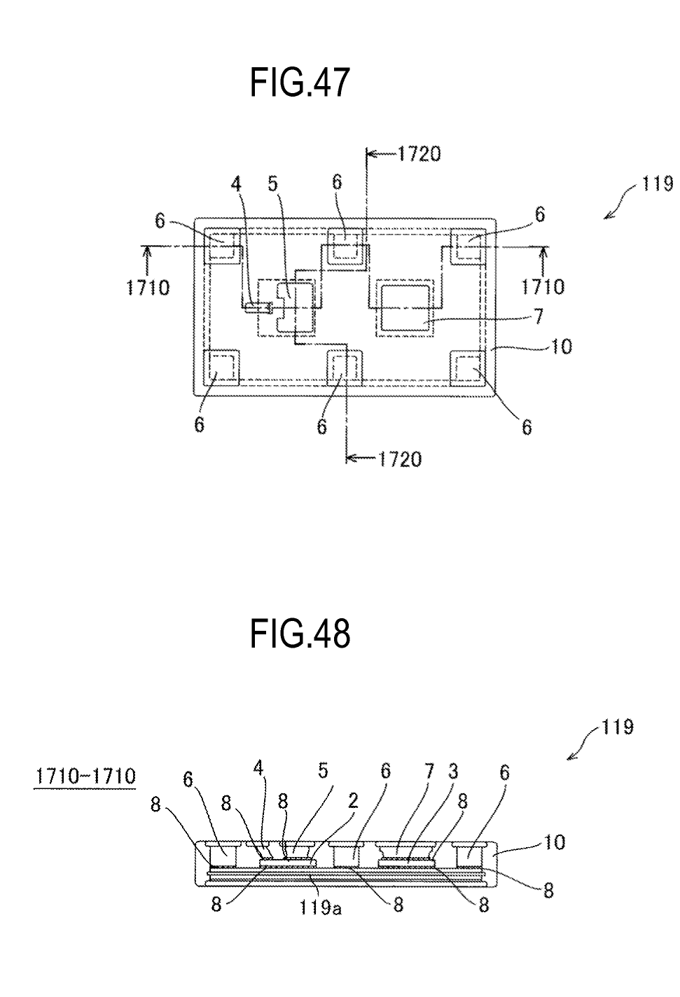

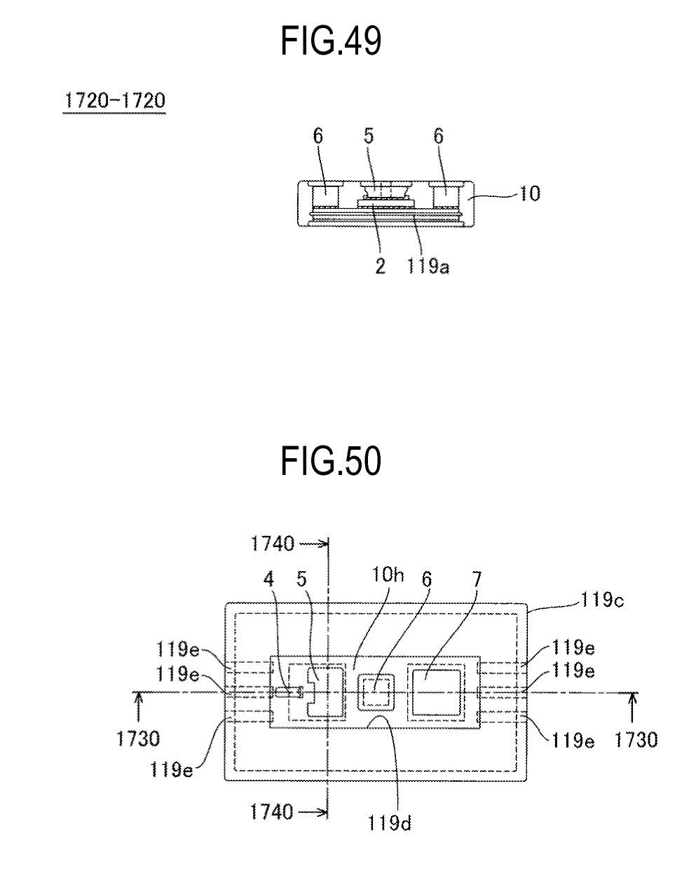

An eighteenth embodiment is described. Referring to FIGS. 47 to 49, in a power module 119, the semiconductor element 2 and the semiconductor element 3 are joined to a surface of an insulation circuit board 119a through joint materials 8. The insulation circuit board 119a has a structure in which metal plates are bonded to both surfaces of an insulator made of, for example, ceramic. With this structure, heat generated from the semiconductor elements 2 and 3 is radiated upward from the gate terminal 4, the source terminal 5, the drain terminals 6, and the anode terminal 7. Also, the heat generated from the semiconductor elements 2 and 3 is radiated from a lower side of the insulation circuit board 119a. The insulation circuit board 119a is an example of a “radiator member” that is disclosed. The other configuration of the eighteenth embodiment is similar to that of the first embodiment.

### Nineteenth Embodiment

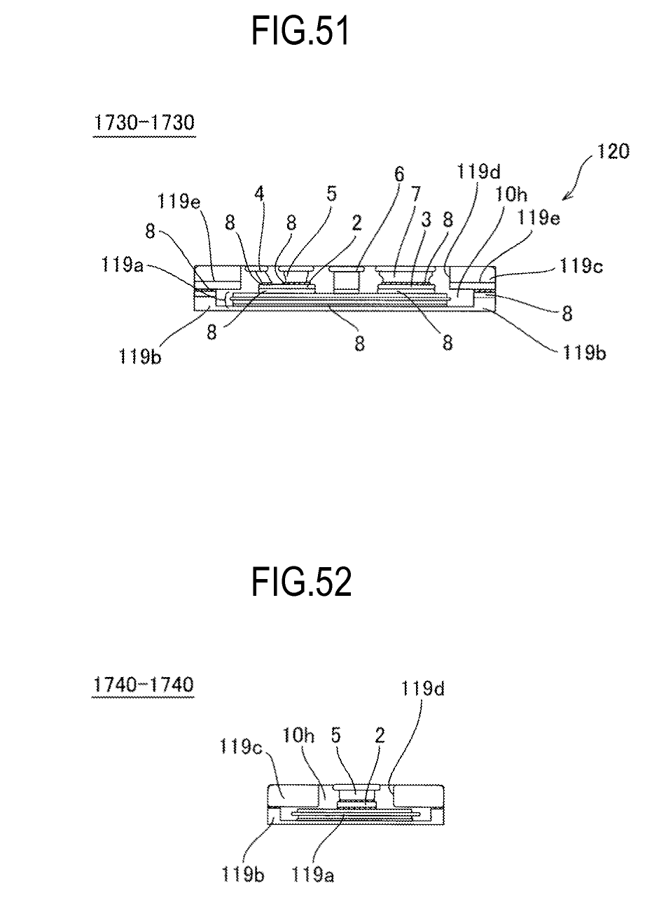

A nineteenth embodiment is described. Referring to FIGS. 50 and 51, in a power module 120, the semiconductor element 2, the semiconductor element 3, and the drain terminal 6 are joined to the surface of the insulation circuit board 119a through joint materials 8. The gate terminal 4 and the source terminal 5 are joined to the surface of the semiconductor element 2 through joint materials 8. The anode terminal 7 is joined to the surface of the semiconductor element 3 through a joint material 8.

A lower heat spreader 119b having a heat radiation function is arranged at a lower surface of the insulation circuit board 119a. The lower heat spreader 119b is formed in a substantially box-like shape (a substantially case-like shape) having a bottom surface and side surfaces. Also, an upper heat spreader 119c is arranged on the lower heat spreader 119b through a joint material 8. The upper heat spreader 119c is formed in a substantially box-like shape (a substantially case-like shape) having an upper surface and side surfaces. As shown in FIG. 52, an opening 119d is provided in the upper surface of the upper heat spreader 119c. The semiconductor elements 2 and 3 are housed in the lower heat spreader 119b and the upper heat spreader 119c. With this structure, heat generated from the semiconductor elements 2 and 3 is radiated from the lower surface and the side surfaces of the lower heat spreader 119b and from the upper surface and the side surfaces of the upper heat spreader 119c. The lower heat spreader 119b and the upper heat spreader 119c are formed of metal having electrical conductivity and thermal conductivity, and each are an example of a “case portion” that is disclosed.

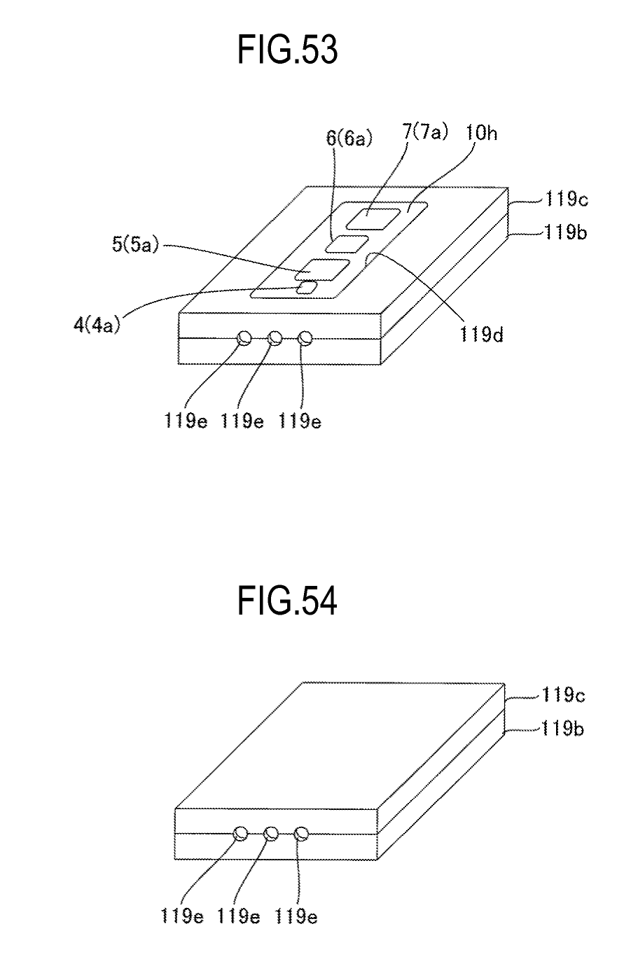

Referring to FIGS. 53 and 54, resin injection holes 119e are provided at the side surfaces of the lower heat spreader 119b and the upper heat spreader 119c. Resin is injected through the resin injection holes 119e. Thus, the space defined by the lower heat spreader 119b, the upper heat spreader 119c, the semiconductor element 2, and the semiconductor element 3 is filled with a resin material 10h. The upper end surface 4a of the gate terminal 4, the upper end surface 5a of the source terminal 5, the upper end surface 6a of the drain terminal 6, and the upper end surface 7a of the anode terminal 7 are exposed from an upper surface of the resin material 10h (the opening 119d of the upper heat spreader 119c).

In this embodiment, the inside of the lower heat spreader 119b and the upper heat spreader 119c is filled with the resin material 10h such that the semiconductor element 2 and the semiconductor element 3, and side surfaces of the gate terminal 4, the source terminal 5, the drain terminal 6, and the anode terminal 7 are covered. Also, the inside of the lower heat spreader 119b and the upper heat spreader 119c is filled with the resin material 10h such that the upper end surface 4a of the gate terminal 4, the upper end surface 5a of the source terminal 5, the upper end surface 6a of the drain terminal 6, and the upper end surface 7a of the anode terminal 7 are exposed. With this structure, the power module 120 is not broken by a shock from the outside, and reliability can be increased.

### Twentieth Embodiment

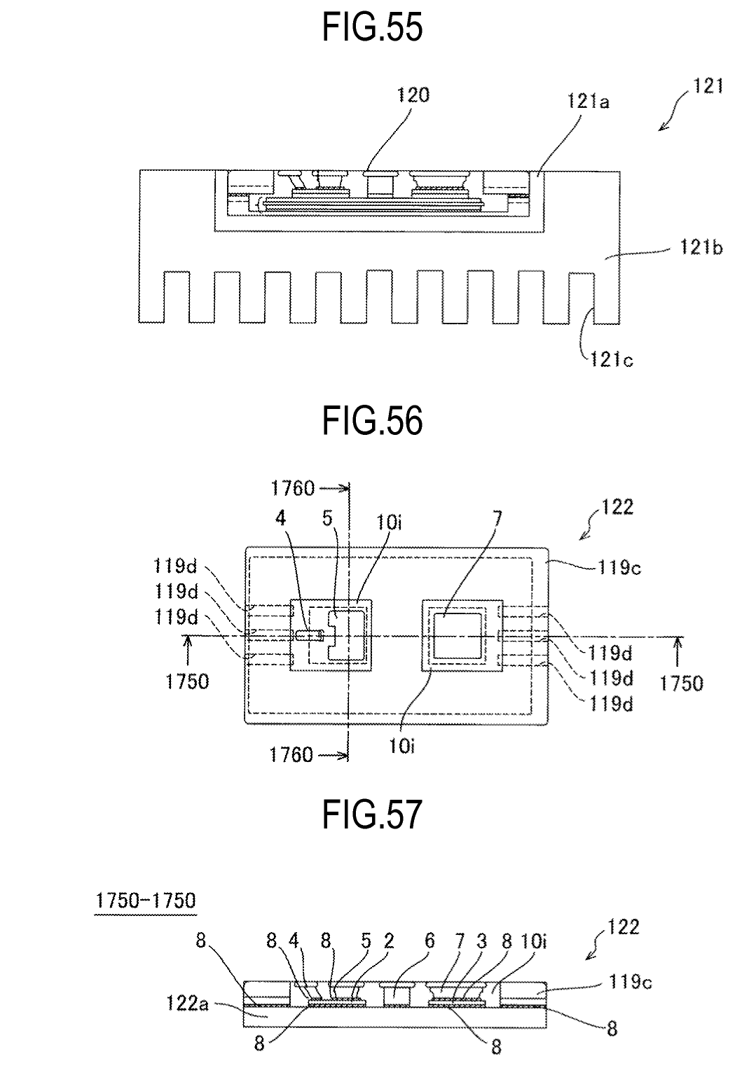

A twentieth embodiment is described. Referring to FIG. 55, in a power module 121, a heat sink 121b is connected to cover side surfaces and a lower surface of the power module 120 described in the nineteenth embodiment, through insulating thermal-conductive grease 121a. The heat sink 121b has a plurality of fins 121c. Since the heat sink 121b is provided, a thermal resistance of the power module 121 can be decreased. Further, thermal saturation by a rapid temperature increase as the result of an overload can be reduced. Accordingly, heat radiation performance can be further increased.

### Twenty-First Embodiment

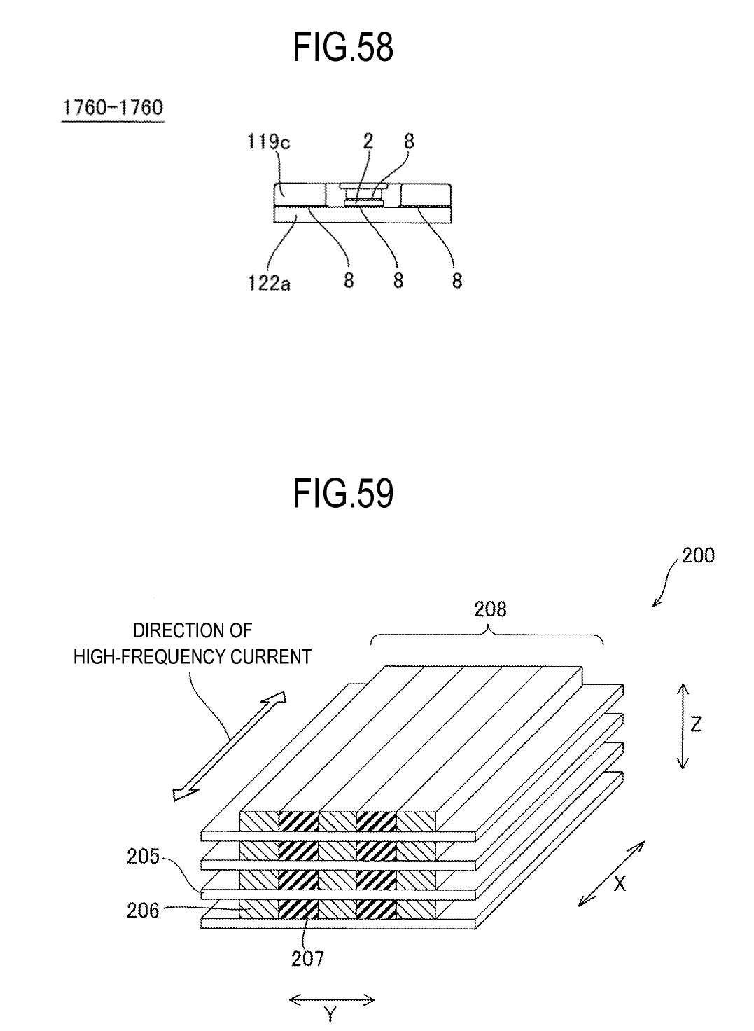

A twenty-first embodiment is described. Referring to FIGS. 56 to 58, in a power module 122, the semiconductor element 2, the semiconductor element 3, and the drain terminal 6 are joined to a surface of a metal plate 122a through joint materials 8. The gate terminal 4 and the source terminal 5 are joined to the surface of the semiconductor element 2 through joint materials 8. The anode terminal 7 is joined to the surface of the semiconductor element 3 through a joint material 8.

The upper heat spreader 119c is provided on a surface of the metal plate 122a to surround the semiconductor element 2, the semiconductor element 3, the gate terminal 4, the source terminal 5, the drain terminal 6, and the anode terminal 7. A space defined by the upper heat spreader 119c, the semiconductor element 2, the semiconductor element 3, the gate terminal 4, the source terminal 5, the drain terminal 6, and the anode terminal 7 is filled with a resin material 10i. In this embodiment, a substantially case-like lower heat spreader is not provided, and the substantially plate-like metal plate 122a forms the lower heat spreader (radiator plate). It is to be noted that the potentials of the metal plate 122a and the upper heat spreader 119c are substantially equivalent to the potential of a portion of the semiconductor element 3 near the metal plate 122a (cathode side). Accordingly, an outside circuit board (not shown) and the semiconductor element 3 can be easily electrically connected with each other.

### Twenty-Second Embodiment

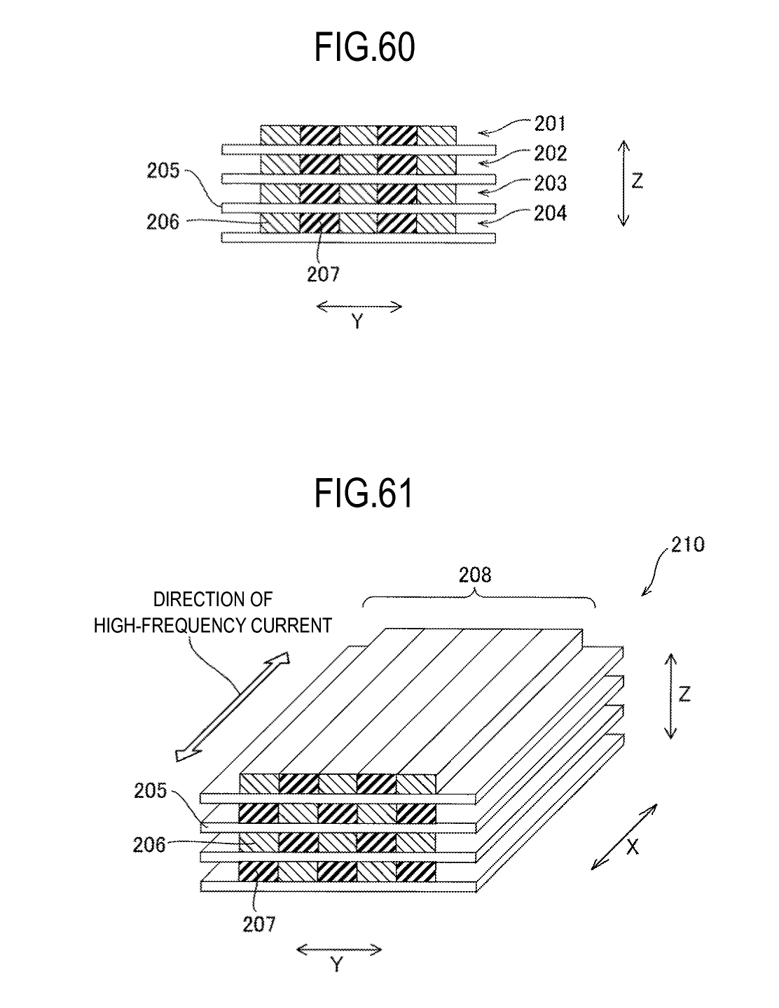

A twenty-second embodiment is described. Referring to FIGS. 59 and 60, a wiring board 200 includes a first layer 201, a second layer 202, a third layer 203, and a fourth layer 204. Each layer includes an insulating substrate 205 made of glass epoxy resin used for a typical printed board, and a plurality of (in FIG. 59, three) narrow wiring conductors 206 provided on a surface of the insulating substrate 205. The wiring conductors 206 are made of copper or the like. For example, each of the wiring conductors 206 has a width (thickness) in a range from about 100 μm to about 200 μm. The width (thickness) of the wiring conductor 206 is desirably determined in accordance with a depth from a surface, the depth which allows high-frequency current to flow and which is calculated based on the frequency of flowing high-frequency current and the material of the wiring conductor 206. Also, the number of wiring conductors 206 in a single layer and the number of layers in the wiring board 200 are desirably determined in accordance with an electric capacity. The two wiring conductors 206 stacked on each other through the insulating substrate 205 are respectively examples of a “first wiring conductor” and a “second wiring conductor” that are disclosed.

The plurality of wiring conductors 206 are arranged along the direction of the high-frequency current (an X direction) at a predetermined interval. Insulating layers 207 made of resin or the like for insulation are provided between the wiring conductors 206. The wiring conductors 206 and the insulating layers 207 are alternately arranged in a Y direction. Also, the wiring conductors 206 (the insulating layers 207) in the respective layers are arranged next to each other in a Z direction (a vertical direction) with the insulating substrates 205 interposed therebetween. The wiring conductors 206 can have electrically the same potential by through holes or vias (not shown). A fine wiring portion 208 includes the narrow wiring conductors 206 and insulating layers 207. The through holes and vias each are an example of a “connecting wiring portion” that is disclosed.

Next, a manufacturing procedure of the wiring board 200 is described.

Copper foil is bonded to a surface of the insulating substrate 205, and then the plurality of narrow wiring conductors 206 are arranged by etching or the like. Then, resin or the like is injected into spaces between the wiring conductors 206. Thus the insulating layers 207 are formed and the first layer 201 is formed. Further, the second layer 202 is formed on the first layer 201 by a press method or a buildup method. By repeating similar steps, the third layer 203 and other layers are successively formed. Thus, the wiring board 200 is manufactured.

In this embodiment, the fine wiring portion 208 is formed of a group of the plurality of narrow wiring conductors 206 arranged along the direction in which high-frequency current flows, and the insulating layers 207 interposed between the wiring conductors 206. With this configuration, the wiring through which high-frequency current flows has a larger surface area than a typical conductor that is formed of single wiring with a relatively large cross-sectional area. Heat is not concentrated at the surfaces of the wiring conductors 206. Also, since the wiring through which high-frequency current flows has the large surface area, the width (thickness) of the wiring can be decreased. Hence, the wiring board 200 can be downsized.

Also, since the plurality of fine wiring portions 208 are stacked on each other, the number of wiring conductors 206 is increased as compared with a case with a single layer. A resistance of current flowing through a single wiring conductor 206 can be decreased. Consequently, the amount of heat generated from the wiring conductors 206 can be decreased.

### Twenty-Third Embodiment

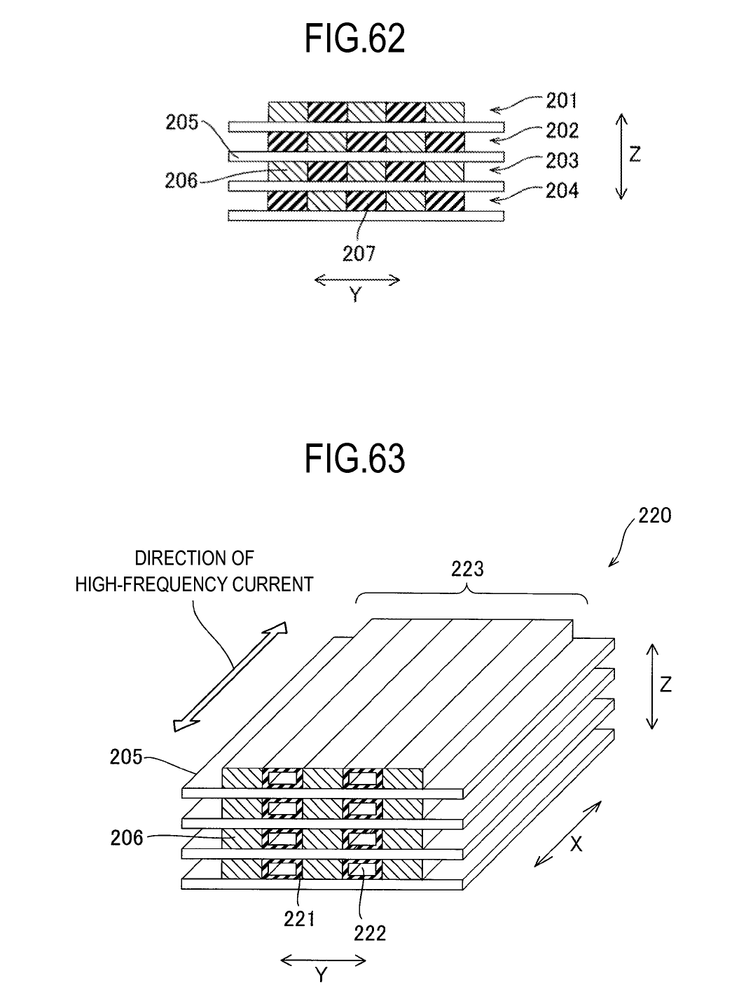

A twenty-third embodiment is described. Referring to FIGS. 61 and 62, in a wiring board 210, the wiring conductors 206 and the insulating layers 207 are alternately arranged in the Z direction. The order of arrangement of the wiring conductors 206 and the insulating layers 207 in the Z direction in an odd-numbered row differs from that in an even-numbered row. Thus, the wiring conductors 206 and the insulating layers 207 are arranged in a substantially checkerboard-like pattern. The other configuration of this embodiment is similar to that of the twenty-second embodiment.

### Twenty-Fourth Embodiment

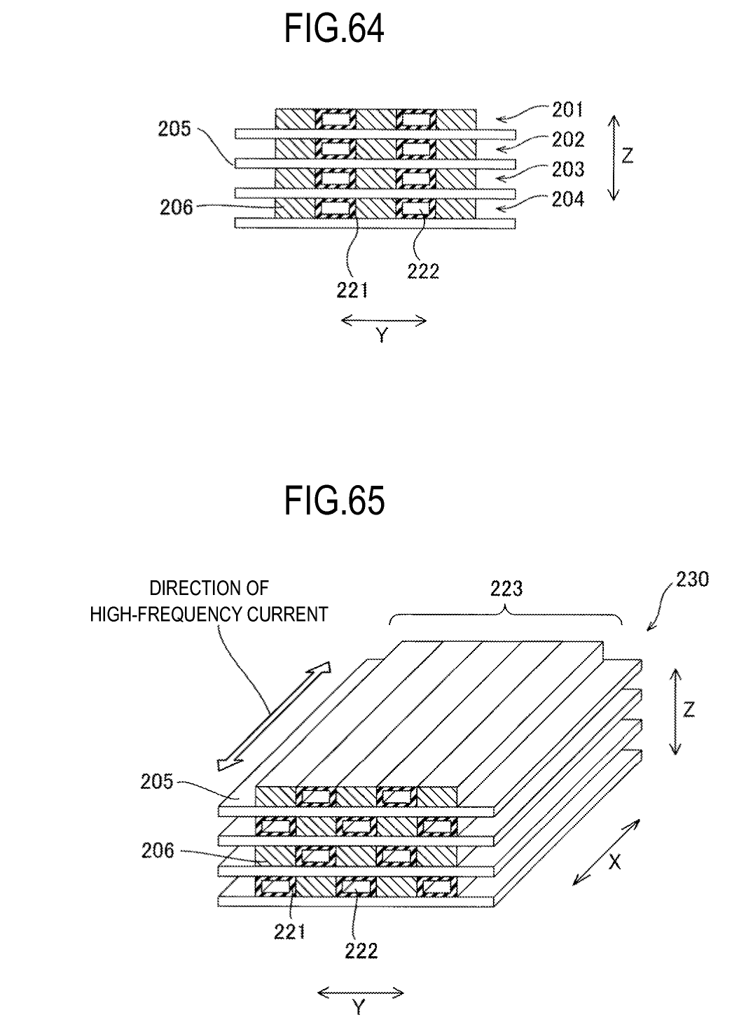

A twenty-fourth embodiment is described. Referring to FIGS. 63 and 64, in a wiring board 220, cooling pipes 222 are arranged between the wiring conductors 206. The outer peripheries of the cooling pipes 222 are covered with resin 221. Also, the wiring conductors 206 (the cooling pipes 222) are arranged next to each other in the Z direction (the vertical direction) with the insulating substrates 205 interposed therebetween. Thus, a fine wiring portion 223 includes the wiring conductors 206, the resin 221, and the cooling pipes 222. The other configuration of this embodiment is similar to that of the twenty-second embodiment.

Next, a manufacturing procedure of the wiring board 220 is described.

Copper foil is bonded to the surface of the insulating substrate 205, and then the plurality of narrow wiring conductors 206 are arranged by etching or the like. Then, the cooling pipes 222 previously molded with the resin 221 are bonded to the surface of the insulating substrate 205, at positions between the wiring conductors 206. Hence, the first layer 201 is formed. Then, the second layer 202 fabricated similarly is formed on the first layer 201. Further, by repeating similar steps, the third layer 203 and other layers are successively formed. Thus, the wiring board 220 is manufactured.

The wiring board 220 in this embodiment includes the cooling pipe 222 arranged between the adjacent wiring conductors 206. The wiring conductors 206 are stacked on each other with the insulating substrate 205 interposed therebetween. In particular, the second layer 202 and the third layer 203 arranged inside may locally generate heat by thermal interference. To avoid thermal interference, a countermeasure of expanding the gap between the wiring conductors 206 may be conceived. However, if the gap between the wiring conductors 206 is expanded, the wiring board 220 becomes large. Owing to this, the cooling pipe 222 is arranged between the adjacent wiring conductors 206 so that the wiring conductors 206 are positively cooled. Hence, the local concentration of heat can be reduced. Also, the wiring board 220 can be downsized.

### Twenty-Fifth Embodiment

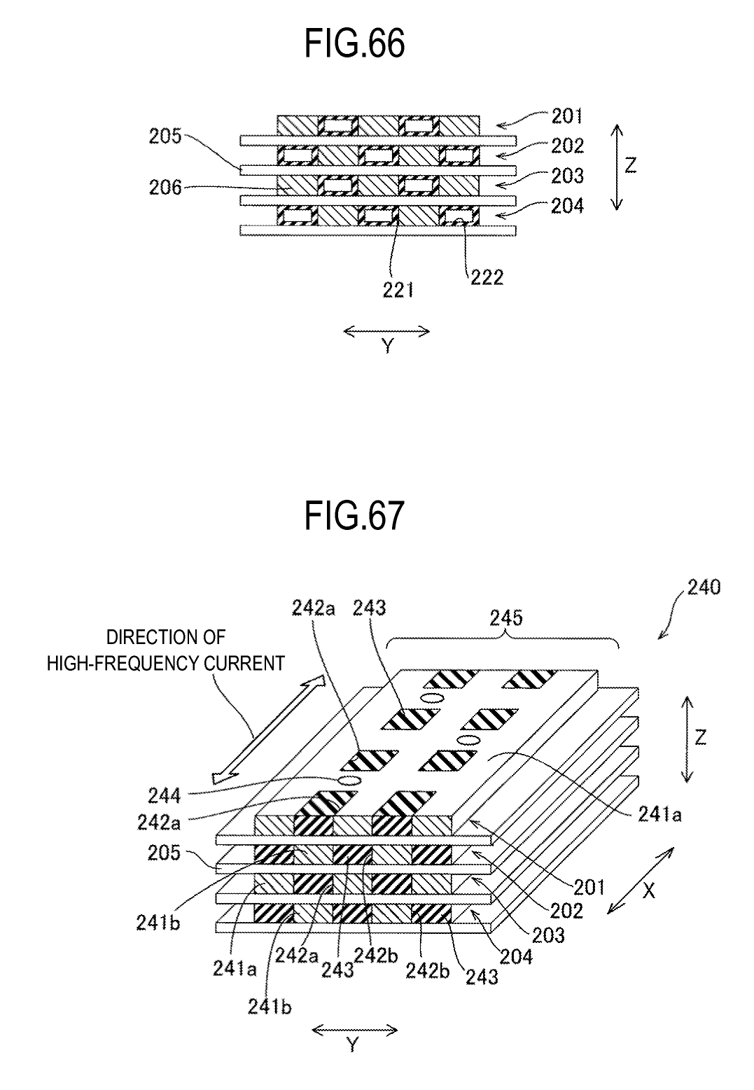

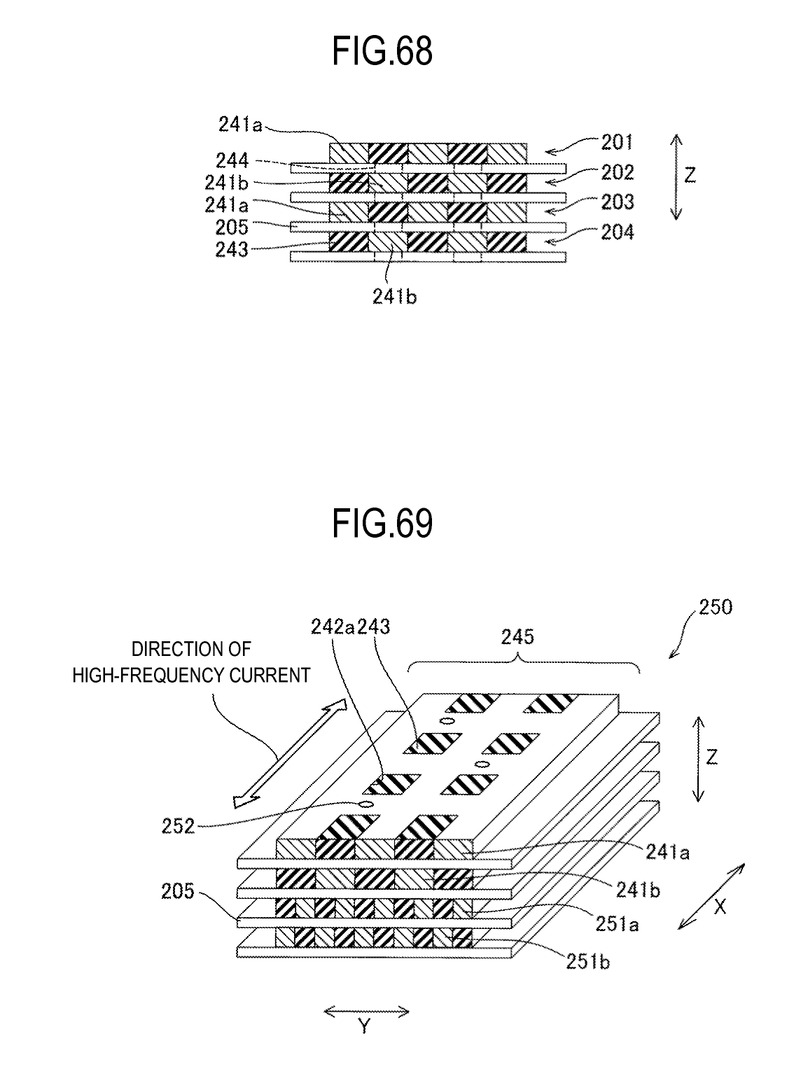

A twenty-fifth embodiment is described. Referring to FIGS. 65 and 66, in a wiring board 230, the wiring conductors 206 and the cooling pipes 222 are alternately arranged in the Z direction (the vertical direction). The order of arrangement of the wiring conductors 206 and the cooling pipes 222 in the Z direction in an odd-numbered row differs from that in an even-numbered row. Thus, the wiring conductors 206 and the cooling pipes 222 are arranged in a substantially checkerboard-like pattern in the X direction. The other configuration of this embodiment is similar to that of the twenty-fourth embodiment.

### Twenty-Sixth Embodiment

A twenty-sixth embodiment is described. Referring to FIG. 67, in a wiring board 240, wiring conductors 241a and 241b are formed in a substantially mesh-like pattern. An insulator 243 with a high dielectric constant, such as ceramic, silicon carbide, or alumina, is embedded in each of a mesh portion 242a of the wiring conductor 241a and a mesh portion 242b of the wiring conductor 241b. The first layer 201 and the third layer 203 include the wiring conductors 241a having substantially equivalent mesh patterns. The second layer 202 and the fourth layer 204 include the wiring conductors 241b having substantially mesh-like patterns that are shifted from the substantially mesh-like patterns of the first layer 201 and the third layer 203 by a half pitch in the Y direction. The wiring conductors 241a and 241b are stacked on each other with the insulating substrate 205 interposed therebetween. The first layer 201 and the third layer 203 are shifted from the second layer 202 and the fourth layer 204 by a half pitch in the Y direction.

The wiring conductors 241a and 241b are electrically connected with each other through a via 244 penetrating through the insulating substrate 205. Thus, the potentials of the four-layer wiring conductors 241a and 241b with the substantially mesh-like patterns provided in the first layer 201, the second layer 202, the third layer 203, and the fourth layer 204 are substantially equivalent to each other. The wiring conductors 241a and 241b, and the insulators 243 form a fine wiring portion 245. A wiring conductor 241 is an example of a “first wiring conductor” and a “second wiring conductor” that are disclosed.

In this embodiment, the four-layer wiring conductors 241a and 241b stacked on each other with the insulating substrates 205 interposed therebetween are electrically connected with each other through the vias 244 penetrating through the insulating substrates 205. Since the four-layer wiring conductors 241a and 241b are electrically connected with each other, the four-layer wiring conductors 241a and 241b have substantially equivalent impedances. Consequently, the impedances of the wiring conductors 241a and 241b do not become locally high and the amount of generated heat is not increased.

### Twenty-Seventh Embodiment

A twenty-seventh embodiment is described. Unlike the twenty-sixth embodiment, in which the wiring conductors 241a and 241b having the meshes with substantially the same sizes are respectively provided in the layers, in this embodiment, wiring conductors 251a and 251b having meshes with different sizes are partly provided.

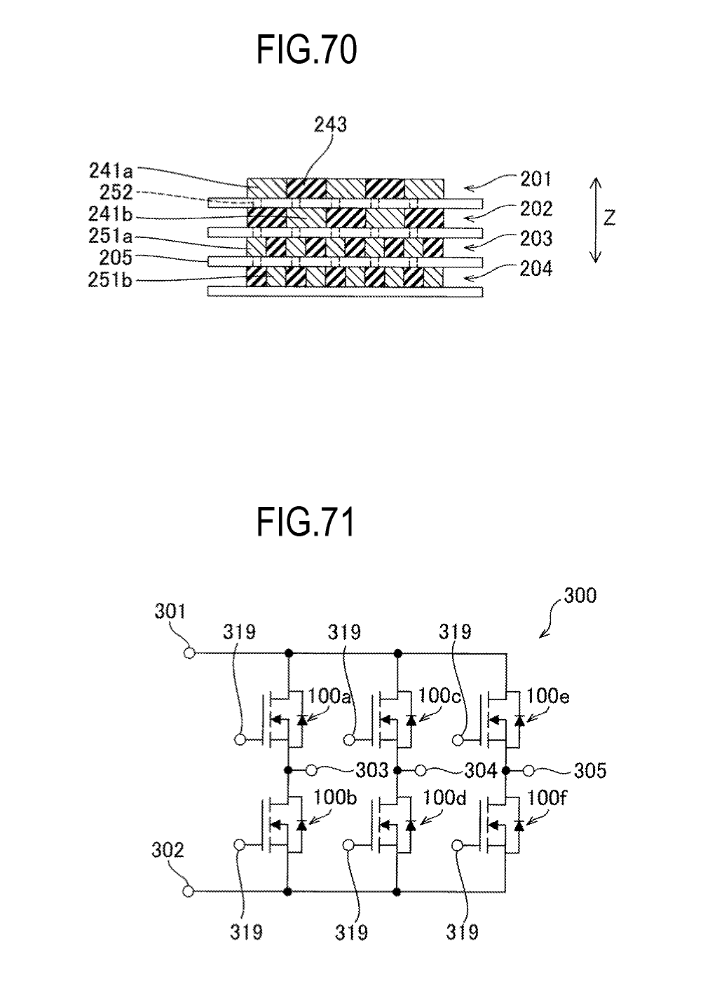

Referring to FIGS. 69 and 70, in a wiring board 250 according to the twenty-seventh embodiment, the wiring conductors 241a and 241b having substantially mesh-like shapes are respectively provided in the first layer 201 and the second layer 202. The wiring conductors 251a and 251b having substantially mesh-like shapes are respectively provided in the third layer 203 and the fourth layer 204. The wiring conductors 251a and 251b provided in the third layer 203 and the fourth layer 204 have the meshes being half the size of the meshes of the wiring conductors 241a and 241b provided in the first layer 201 and the second layer 202. The meshes of the third layer 203 are shifted by a half pitch with respect to the meshes of the fourth layer 204 in the Y direction. The wiring conductors 241a and 241b, and the wiring conductors 251a and 251b are connected with each other through vias 252 penetrating through the insulating substrate 205. Accordingly, potentials of the wiring conductors 241a and 241b, and potentials of the wiring conductors 251a and 251b are substantially equivalent to each other. The wiring conductor 251 is an example of a “first wiring conductor” and a “second wiring conductor” that are disclosed.

### Twenty-Eighth Embodiment

A twenty-eighth embodiment is described. In this embodiment, for example, the power module 100 (the power module body portion 100a) of the first embodiment is applied to a power converter circuit 300, which is employed in an inverter or the like. The power converter circuit 300 is an example of a “power converter” that is disclosed.

Referring to FIG. 71, the power converter circuit 300 includes a P terminal 301, an N terminal 302, a U terminal 303, a V terminal 304, a W terminal 305, and six power module body portions 100a to 100f. Three rows each including two of the six power module body portions 100a to 100f are connected in parallel. Thus, a three-phase full-bridge circuit is formed.

To be more specific, the power module body portion 100a and the power module body portion 100b are connected in series. The power module body portion 100c and the power module body portion 100d are connected in series. The power module body portion 100e and the power module body portion 100f are connected in series. Drains of the power module body portions 100a, 100c, and 100e are connected with the P terminal 301. Sources of the power module body portions 100a, 100c, and 100e are respectively connected with the U terminal 303, the V terminal 304, and the W terminal 305. Drains of the power module body portions 100b, 100d, and 100f are connected with the N terminal 302. Sources of the power module body portions 100b, 100d, and 100f are respectively connected with the U terminal 303, the V terminal 304, and the W terminal 305.

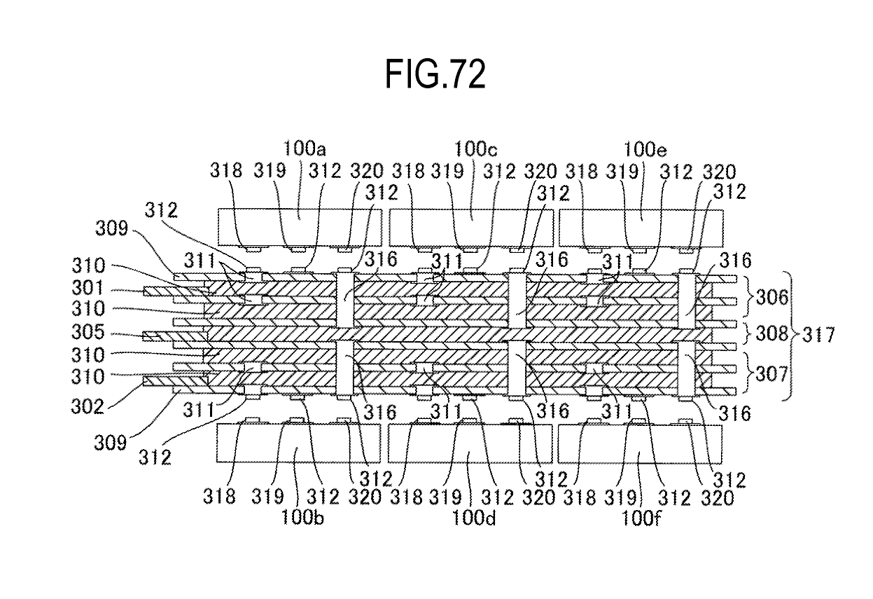

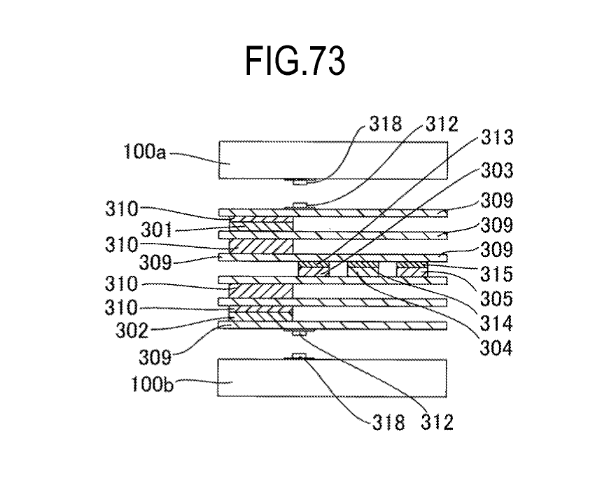

For example, as shown in FIG. 72, the three power module body portions 100a, 100c, and 100e are connected with a P potential layer 306. The three power module body portions 100b, 100d, and 100f are connected with an N potential layer 307. The P potential layer 306 and the N potential layer 307 are connected with an output potential layer 308.

The P potential layer 306 includes two insulating substrates 309 and two fine wiring portions 310. The fine wiring portions 310 employ, for example, the fine wiring portion according to any of the twenty-second to twenty-seventh embodiments. The two fine wiring portions 310 are connected with each other through vias 311, and hence have the same electric potential. Connecting terminals 312 for connection with the power module body portions 100a, 100c, and 100e are provided on an upper surface of the insulating substrate 309. The P terminal 301 is provided at one ends of the fine wiring portions 310.

The N potential layer 307 includes two insulating substrates 309 and two fine wiring portions 310. The two fine wiring portions 310 are connected with each other through vias 311, and hence have the same electric potential. Connecting terminals 312 for connection with the power module body portions 100b, 100d, and 100f are provided on a lower surface of the insulating substrate 309. The N terminal 302 is provided at one ends of the fine wiring portions 310.

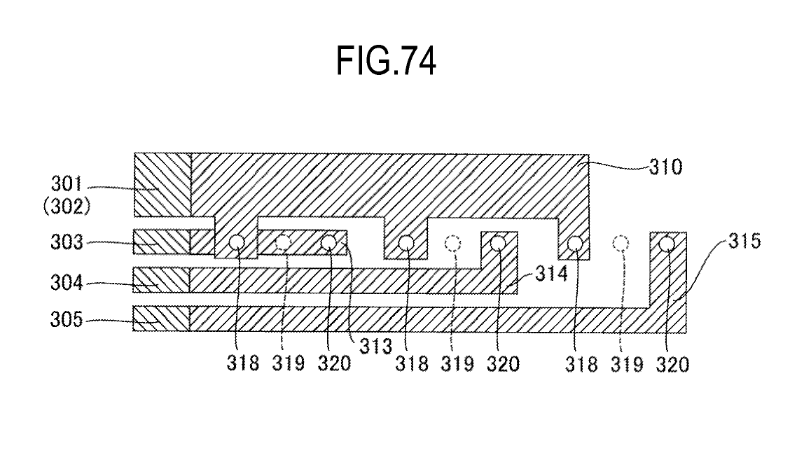

Referring to FIG. 74, the output potential layer 308 includes U-phase output wiring 313, V-phase output wiring 314, W-phase output wiring 315, and two insulating substrates 309 (see FIG. 72). The U-phase output wiring 313, the V-phase output wiring 314, and the W-phase output wiring 315 are arranged between the two insulating substrates 309. The U terminal 303, the V terminal 304, and the W terminal 305 are respectively provided at one ends of the U-phase output wiring 313, the V-phase output wiring 314, and the W-phase output wiring 315.

Referring to FIG. 72, the P potential layer 306 is stacked on an upper surface of the output potential layer 308. The connecting terminals 312 are electrically connected with the U-phase output wiring 313, the V-phase output wiring 314, and the W-phase output wiring 315 via through holes 316. Also, the N potential layer 307 is stacked on a lower surface of the output potential layer 308. The connecting terminals 312 are electrically connected with the U-phase output wiring 313, the V-phase output wiring 314, and the W-phase output wiring 315 via through holes 316. The P potential layer 306, the N potential layer 307, and the output potential layer 308 form a high-frequency high-current board 317.

By connecting drain terminals 318, gate terminals 319, and source terminals 320 of the power module body portions 100a to 100f to the connecting terminals 312 of the high-frequency high-current board 317, the three-phase full-bridge circuit shown in FIG. 71 is formed. When the three-phase full-bridge circuit is driven, rectangular-wave high-frequency current corresponding to switching frequencies of the power module body portions 100a to 100f flows through wiring lines of the P terminal 301 and the N terminal 302 (a wiring line from the P terminal 301 to the power module body portions 100a to 100f through the fine wiring portions 310, and a wiring line from the N terminal 302 to the power module body portions 100a to 100f through the fine wiring portions 310).

In recent years, development of semiconductor elements for electric power using a new material, such as SiC or GaN, is being progressed. A switching frequency when such a new material is used may be hundreds of hertz to one megahertz. Heat may be concentrated on a surface of wiring due to unevenness of impedance at the wiring. Owing to this, the fine wiring portions 310 are applied to the high-frequency high-current board 317 as described above. Accordingly, the impedance of the wiring can be equalized, and the concentration of heat on the surface of wiring can be reduced. Consequently, the power converter can be further downsized.

### Twenty-ninth Embodiment

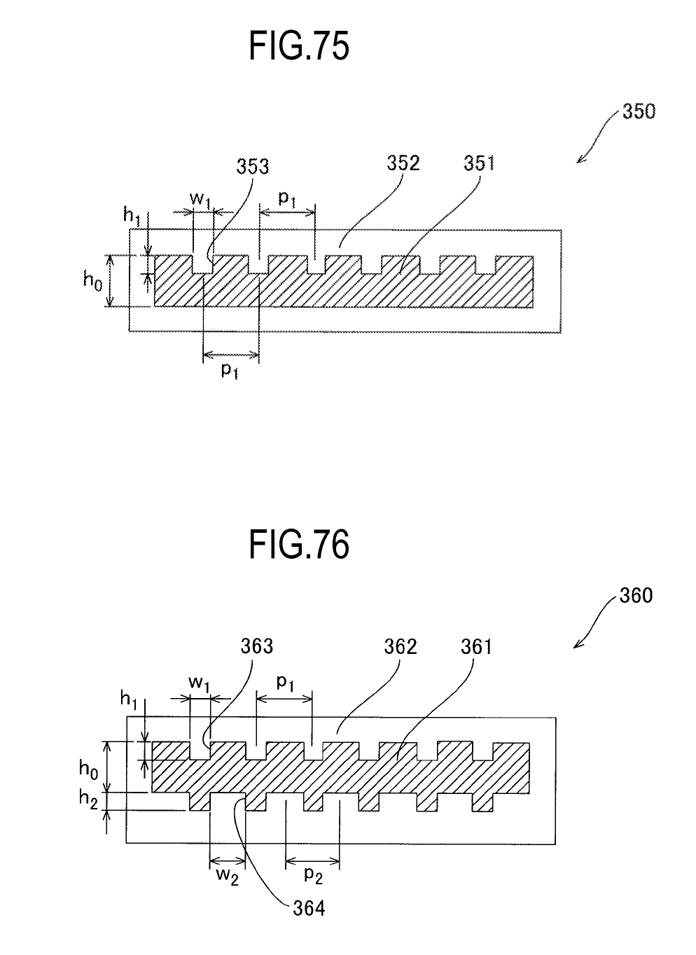

A twenty-ninth embodiment is described. Referring to FIG. 75, wiring 350 includes a conductor 351 extending in a direction in which high-frequency current flows, and an insulator 352. A plurality of upper-surface grooves 353 are provided at an upper surface of the conductor 351 and extend in the direction in which high-frequency current flows. The conductor 351 has a thickness h₀. The upper-surface grooves 353 each have a depth h₁ and a width w₁. A pitch between the upper-surface grooves 353 is p₁.

The periphery of the conductor 351 is covered with the insulator 352. The conductor 351 has the thickness h₀ of 600 p.m. If current has a drive frequency of 100 kHz, the upper-surface grooves 353 are formed such that the depth h₁ is h₀/3, the width w₁ is h₀/3, and the pitch p₁ is h₀. Thus, the conductor 351 has a shape with protrusions and recesses. Grooves may be made in the conductor 351 by using an etching solution, or by mechanical cutting. Accordingly, the plurality of upper-surface grooves 353 have substantially the same heights h₁. Even if the drive frequency of the current is 100 kHz, which is relatively high, the cross section of the conductor 351 can be entirely used as a current-application effective region. If the drive frequency is 100 kHz and the thickness h₀ of the conductor 351 is 600 μm, the cross-sectional area of the current-application effective region is increased by about 30% as compared with the shape without the protrusions and recesses (the upper-surface grooves 353). Accordingly, a resistance to conduction is decreased.

In this embodiment, the wiring 350 includes the conductor 351 having the protrusions and recesses at the outer surface and extending in the direction in which high-frequency current flows. With this structure, the surface area of the region where high-frequency current flows can be increased. As compared with a case in which a conductor has a flat outer surface, a resistance to high-frequency current can be decreased.

Also, since the periphery of the conductor 351 is surrounded by the insulator 352, current does not leak from the conductor 351.

### Thirtieth Embodiment

A thirtieth embodiment is described. Referring to FIG. 76, wiring 360 includes a conductor 361 extending in a direction in which high-frequency current flows, and an insulator 362. A plurality of upper-surface grooves 363 are provided at an upper surface of the conductor 361 and extend in the direction in which high-frequency current flows. A plurality of lower-surface grooves 364 are provided at a lower surface of the conductor 361 and extend in the direction in which high-frequency current flows. The conductor 361 has a thickness h₀. The upper-surface grooves 363 each have a depth h₁ and a width w₁. A pitch between the upper-surface grooves 363 is p₁. The lower-surface grooves 364 each have a depth h₂ and a width w₂. A pitch between the lower-surface grooves 364 is p₂.

The periphery of the conductor 361 is covered with the insulator 362. If the conductor 361 has the thickness h₀ of 600 μm and the current has a drive frequency of 100 kHz, the grooves are formed in the conductor 361 such that the upper-surface grooves 363 have the depth h₁ of h₀/3, the width w₁ of h₀/3, and the pitch p₁ of h₀. Also, the grooves are formed in the conductor 361 such that the lower-surface grooves 364 have the depth h₂ of h₀/3, the width w₂ of 2h₀/3, and the pitch p₂ of h₀/2. Thus, the conductor 361 has a shape with protrusions and recesses. Grooves may be made in the conductor 361 by using an etching solution, or by mechanical cutting. Accordingly, the plurality of upper-surface grooves 363 have substantially the same heights h₁ and the plurality of lower-surface grooves 364 have substantially the same heights h₂. Even if the drive frequency of the current is 100 kHz, which is relatively high, the cross section of the conductor 351 can be entirely used as a current-application effective region. If the drive frequency is 100 kHz and the thickness h₀ of the conductor 351 is 600 μm, the cross-sectional area of the current-application effective region is increased by about 60% as compared with the shape without the protrusions and recesses (the upper-surface grooves 363, the lower-surface grooves 364). Thus, a resistance to conduction is decreased.

### Thirty-First Embodiment

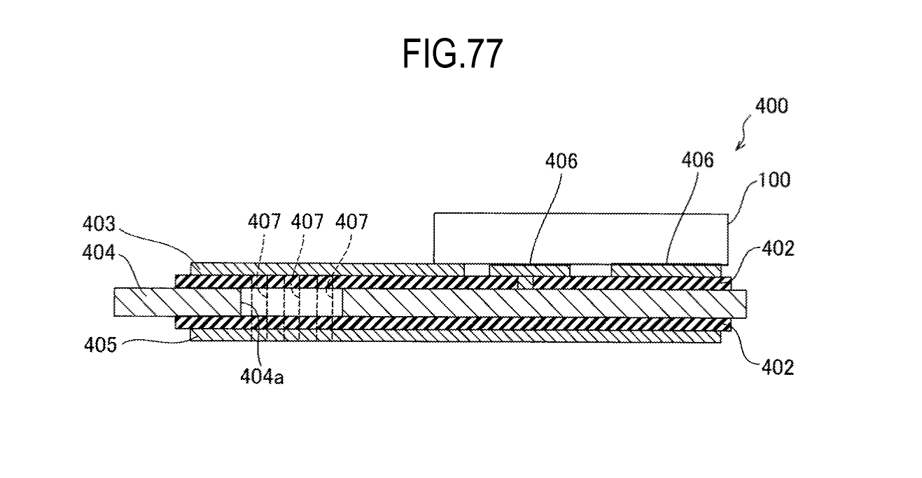

A thirty-first embodiment is described. Referring to FIG. 77, a wiring board 400 includes insulating layers 402, first-layer conductor wiring 403, second-layer conductor wiring 404, third-layer conductor wiring 405, and electrodes 406. For example, the power module 100 of the first embodiment is connected with the electrodes 406.

In the wiring board 400, the second-layer conductor wiring 404 is arranged on a surface of the third-layer conductor wiring 405 via the insulating layer 402. Also, the first-layer conductor wiring 403 is arranged on a surface of the second-layer conductor wiring 404 via the insulating layer 402. Further, cooling holes 407 penetrate through the conductor wiring 404, the insulating layers 402 provided on upper and lower surfaces of the conductor wiring 404, and the conductor wiring 405. The entire cooling holes 407 are filled with copper, silver, or nickel and hence thermal vias are formed. The cooling holes 407 each are an example of a “cooling structure” that is disclosed.

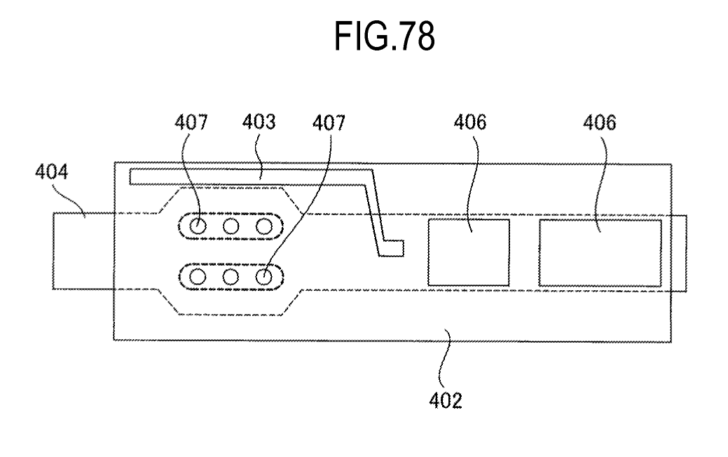

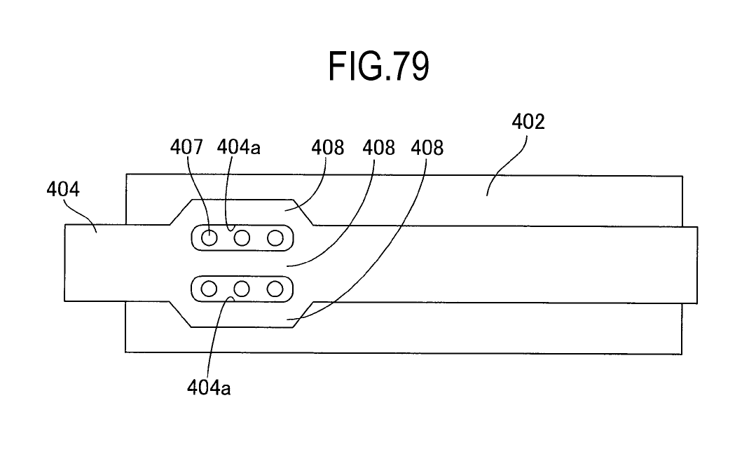

Referring to FIGS. 77 and 78, the cooling holes 407 each have a substantially circular shape. Three cooling holes 407 define a single group, and two groups of cooling holes 407 are arranged in two rows. Referring to FIG. 79, the second-layer conductor wiring 404 has branch wiring portions 408 that are equally divided into three in plan view. An opening 404a is provided between the adjacent branch wiring portions 408, in order to avoid interference with respect to the cooling holes 407. The opening 404a is filled with an insulator for insulation between the cooling holes 407 filled with copper or the like, and the branch wiring portions 408. Accordingly, the second-layer conductor wiring 404 does not come into contact with copper, silver, or nickel that fills the cooling holes 407.

In the thirty-first embodiment, since the cooling holes 407 are provided near the first-layer conductor wiring 403 and the second-layer conductor wiring 404, heat generated from the power module 100 can be radiated through the cooling holes 407.

### Thirty-Second Embodiment

A thirty-second embodiment is described. In this embodiment, an air cooler 412 is provided at the cooling holes 407 of the thirty-first embodiment.

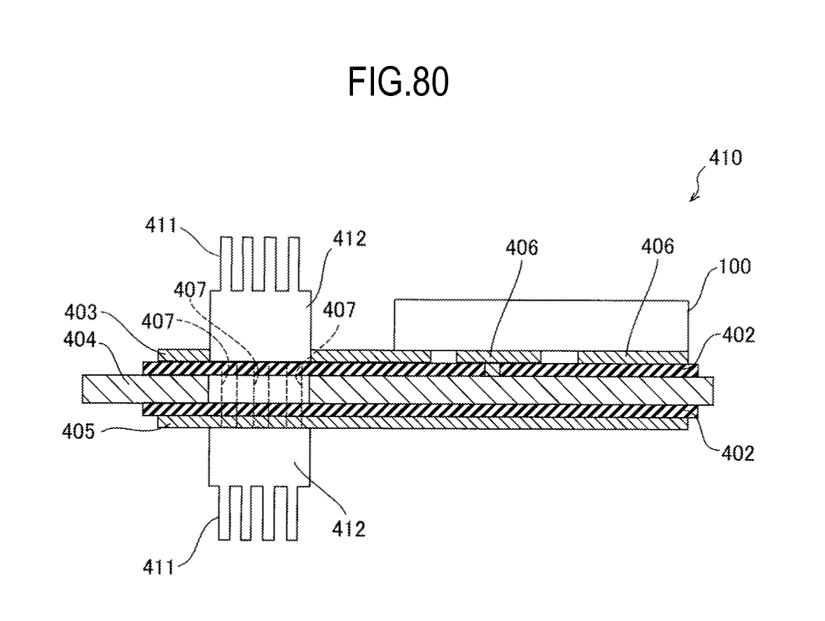

Referring to FIG. 80, the air cooler 412 having a plurality of fins 411 is provided at each of upper and lower planes of the cooling holes 407 of a wiring board 410. The air cooler 412 is an example of a “cooler” that is disclosed. The other configuration of this embodiment is similar to that of the thirty-first embodiment.

In this embodiment, the wiring board 410 includes the air coolers 412 connected with the cooling holes 407. Accordingly, heat generated from the power module 100 connected with the wiring board 410 can be radiated to the air by the air coolers 412 through the cooling holes 407. Thus, heat radiation performance is increased.

### Thirty-Third Embodiment

A thirty-third embodiment is described. In this embodiment, a liquid cooler 421 is provided at the cooling holes 407 of the thirty-first embodiment.

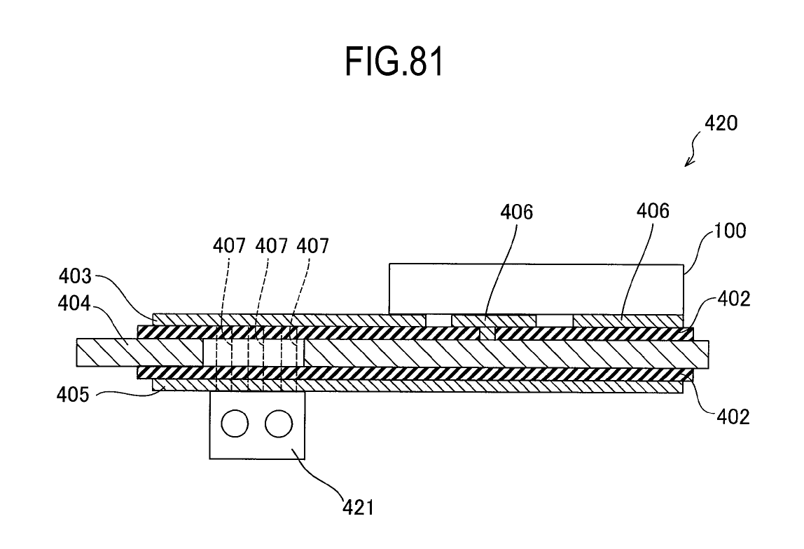

Referring to FIG. 81, the liquid cooler 421 is provided on lower planes of the cooling holes 407 of the wiring board 420 described in the thirty-first embodiment. The liquid cooler 421 is an example of a “cooler” that is disclosed. The other configuration of this embodiment is similar to that of the thirty-first embodiment.

In this embodiment, the liquid cooler 421 connected with the cooling holes 407 is provided. Accordingly, heat generated from the power module 100 connected with a wiring board 420 can be radiated to the liquid cooler 421 through the cooling holes 407. Thus, heat radiation performance is further increased.

In any of the thirty-first to thirty-third embodiments, the second-layer conductor wiring 404 has the branch wiring portions 408 evenly divided into three. Also, the two rows of cooling holes 407 are arranged near the three branch wiring portions 408 so as not to interfere with the branch wiring portions 408. Accordingly, heat can be dispersed through the branches of the conductor wiring 404 without an increase in resistance to current conduction of the conductor wiring 404. Further, since heat is transferred from the conductor wiring 404 to the cooling holes 407, the conductor wiring 404 can be efficiently cooled. Since heat can be dispersed, sufficient cooling can be provided even if cooling performance of the air cooler 412 or the liquid cooler 421 per unit area is decreased. The air cooler 412 or the liquid cooler 421 can be downsized accordingly.

### Thirty-Fourth Embodiment

A liquid cooler 500 according to a thirty-fourth embodiment is described. In this embodiment, for example, the power modules 100 described in the first embodiment are arranged on an upper surface of the liquid cooler 500. The liquid cooler 500 is an example of a “cooling structure” that is disclosed.

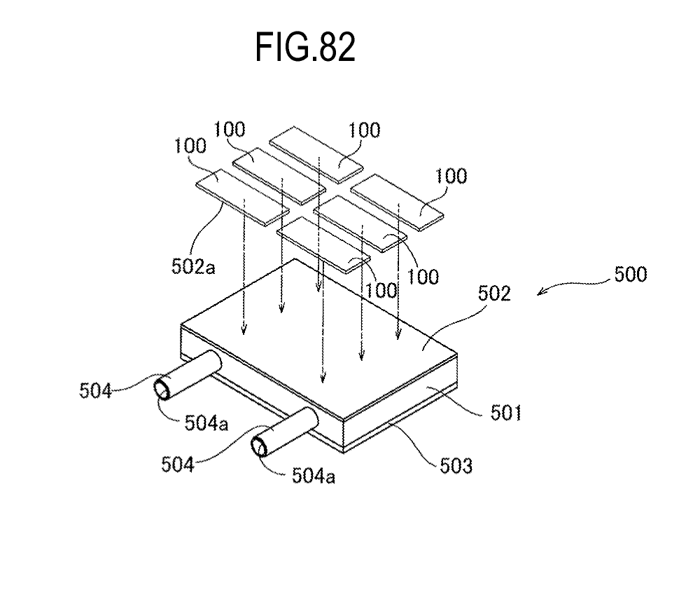

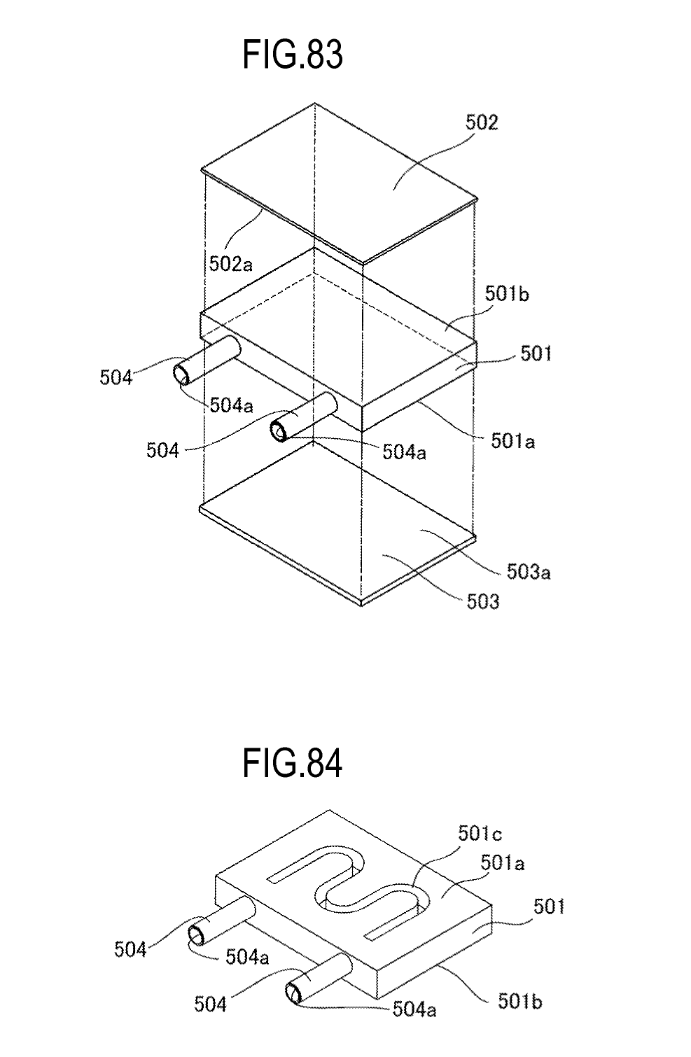

Referring to FIGS. 82 and 83, the liquid cooler 500 includes a cooling plate base 501, a cooling plate cap 502 provided on an upper surface of the cooling plate base 501, a cooling plate bottom panel 503 provided on a lower surface of the cooling plate base 501, and pipes 504 provided at a side surface of the cooling plate base 501. Alternatively, the pipes 504 may be joints. The cooling plate base 501 and the cooling plate bottom panel 503 are integrated such that a back surface 501a of the cooling plate base 501 is brazed with a brazing surface 503a of the cooling plate bottom panel 503. The cooling plate base 501 and the cooling plate cap 502 are integrated such that a surface 501b of the cooling plate base 501 is bonded to an insulating bonding surface 502a of the cooling plate cap 502 by an insulating adhesive material. The adhesive material uses, for example, a ceramic adhesive. The cooling plate base 501 is insulated from the cooling plate cap 502 by the adhesive material. Accordingly, even if the power modules 100 of the first embodiment provided on the upper surface of the liquid cooler 500 have a potential difference, the potential of the power module 100 does not cause a short circuit at the cooling plate base 501.

Referring to FIG. 84, a coolant flow path 501c is provided at the back surface of the cooling plate base 501. The coolant flow path 501c is connected with inside portions 504a of the pipes 504. Thus, a coolant flow path of the liquid cooler 500 is formed.

### Thirty-Fifth Embodiment

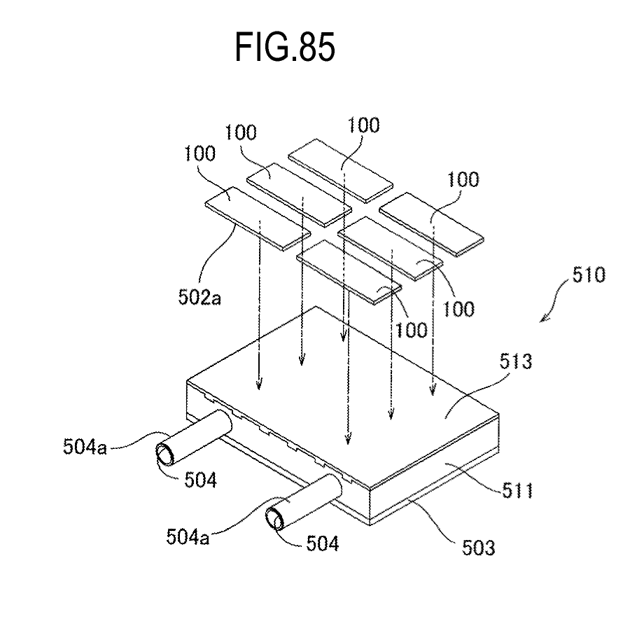

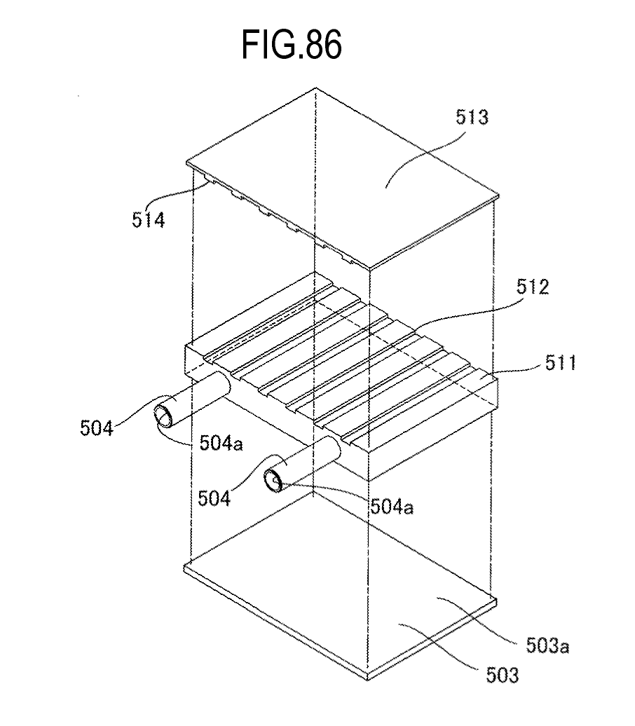

A thirty-fifth embodiment is described. Referring to FIGS. 85 and 86, a plurality of recesses 512 each having a substantially rectangular cross section are provided at an upper surface of a cooling plate base 511 of a liquid cooler 510. A plurality of protrusions 514 each having a substantially rectangular cross section are provided at a lower surface of a cooling plate cap 513 facing the cooling plate base 511. The recesses 512 of the cooling plate base 511 are fitted on the protrusions 514 of the cooling plate cap 513. Accordingly, since a contact area between the cooling plate base 511 and the cooling plate cap 513 is increased, heat radiation performance can be increased. The protrusions and recesses do not have to have the substantially rectangular cross sections and may each have a cross section of, for example, a substantially sawtooth-like shape as long as the contact area between the cooling plate base 511 and the cooling plate cap 513 is increased. The liquid cooler 510 is an example of a “cooling structure” that is disclosed. The other configuration of this embodiment is similar to that of the thirty-fourth embodiment.

### Thirty-Sixth Embodiment

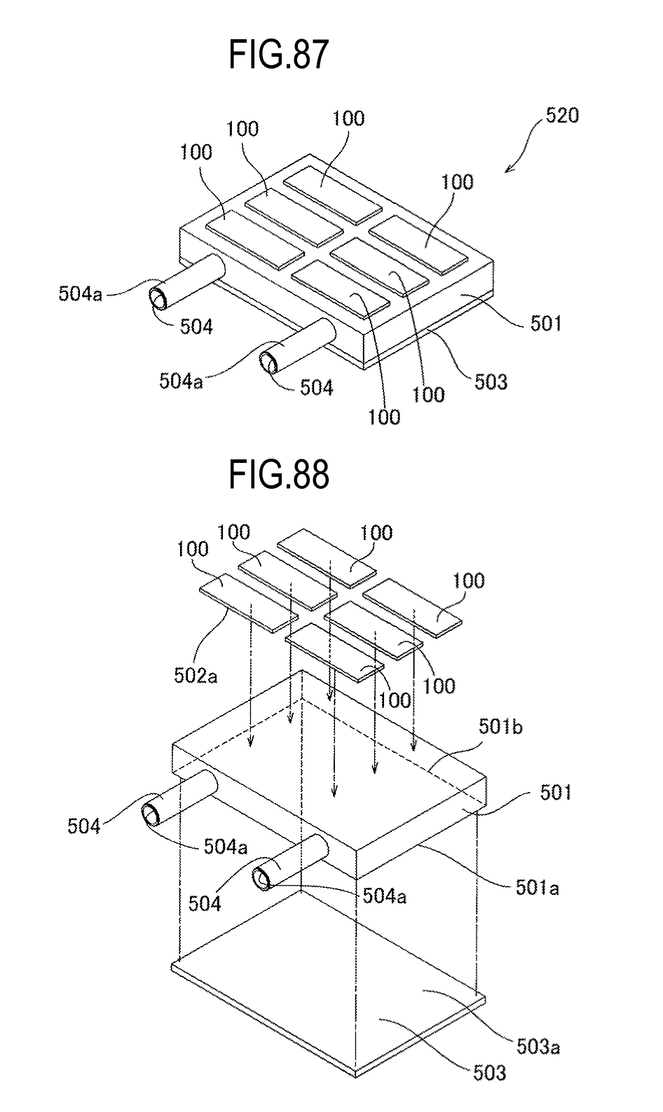

A thirty-sixth embodiment is described. In this embodiment, referring to FIGS. 87 and 88, the cooling plate cap (see FIG. 82) is not provided on the upper surface of the cooling plate base 501 of a liquid cooler 520 according to this embodiment, but the plurality of power modules 100 are directly provided on the cooling plate base 501. The cooling plate base 501 and the power modules 100 are integrated by an insulating adhesive material. The cooling plate base 501 is insulated from the power modules 100 by the adhesive material. The liquid cooler 520 is an example of a “cooling structure” that is disclosed. The other configuration of this embodiment is similar to that of the thirty-fourth embodiment.

In this embodiment, the plurality of power modules 100 are directly provided on the upper surface of the cooling plate base 501 without the cooling plate cap (see FIG. 82). Accordingly, a thermal resistance between the power modules 100 and the cooling plate base 501 can be decreased, and heat radiation performance of the liquid cooler 520 can be increased.

### Thirty-Seventh Embodiment

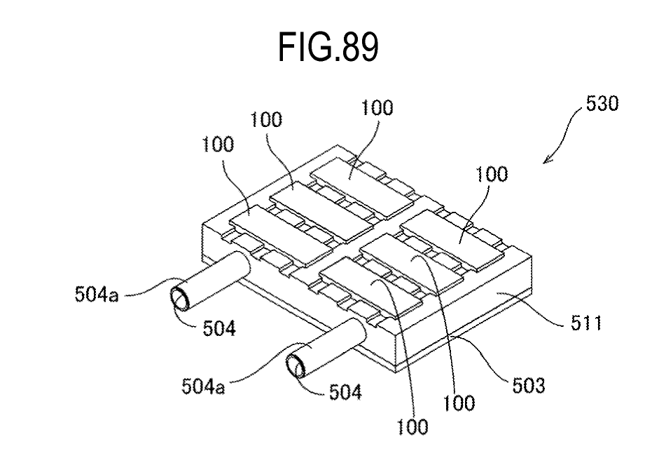

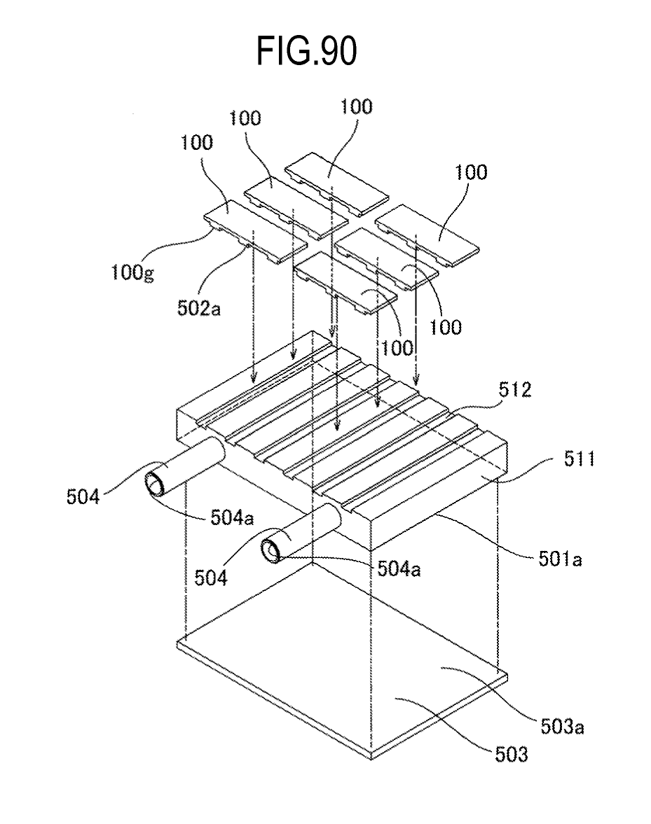

A thirty-seventh embodiment is described. Referring to FIGS. 89 and 90, in a liquid cooler 530, the recesses 512 each having a substantially rectangular cross section are provided at the upper surface of the cooling plate base 511. Also, protrusions 100g each having a substantially rectangular cross section are provided at the lower surfaces (the drain-electrode radiator plates 1) of the power modules 100. The protrusions 100g can fit to the recesses 512 of the cooling plate base 511. The protrusions and recesses do not have to have the substantially rectangular cross sections and may each have a cross section of, for example, a substantially sawtooth-like shape as long as the contact area between the cooling plate base 511 and the power modules 100 is increased. The other configuration of this embodiment is similar to that of the thirty-sixth embodiment.

The power modules 100 in this embodiment each have the protrusions 100g at the drain-electrode radiator plate 1, and the recesses 512 are formed at the upper surface of the cooling plate base 511. The recesses 512 can fit on the protrusions 100g at the drain-electrode radiator plates 1. With this structure, since the contact area between the drain-electrode radiator plates 1 of the power modules 100 and the cooling plate base 511 is increased, heat radiation performance using thermal conduction from the power modules 100 to the cooling plate base 511 can be increased.

### Thirty-Eighth Embodiment

A thirty-eighth embodiment is described. In this embodiment, a partition plate 543 is provided in a cooling plate base 541. A liquid cooler 540 is an example of a “cooling structure” that is disclosed.

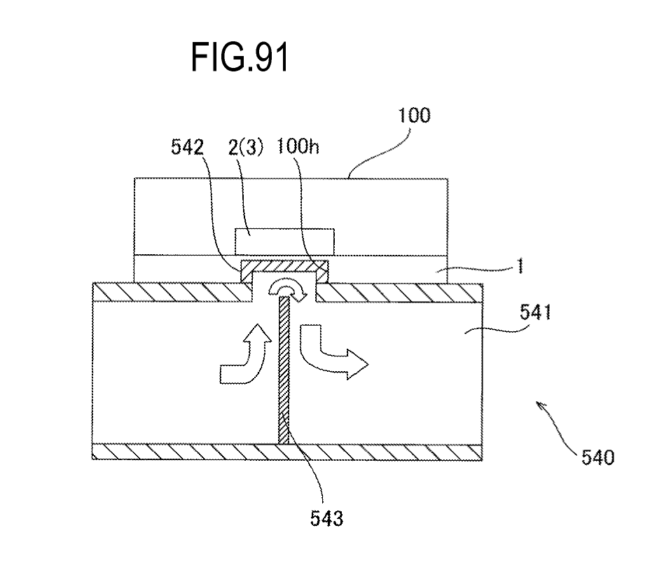

Referring to FIG. 91, the liquid cooler 540 has a protrusion 542 at an upper surface of the cooling plate base 541. Also, a recess 100h is formed at the lower surface of the drain-electrode radiator plate 1 of the power module 100. The recess 100h faces the protrusion 542 of the cooling plate base 541. The recess 100h of the drain-electrode radiator plate 1 is provided below an installation surface of the semiconductor element 2 (the semiconductor element 3). Also, in the cooling plate base 541, the partition plate 543 is provided in a region located below the installation surface of the semiconductor element 2 (the semiconductor element 3). The recess 100h narrows a flow path. The flow speed of a coolant flowing through the inside of the cooling plate base 541 is increased when the coolant passes through a gap between the recess 100h and the partition plate 543. Hence, heat radiation performance for radiating heat generated from the semiconductor element 2 (the semiconductor element 3) to the cooling plate base 541 can be increased.

### Thirty-Ninth Embodiment

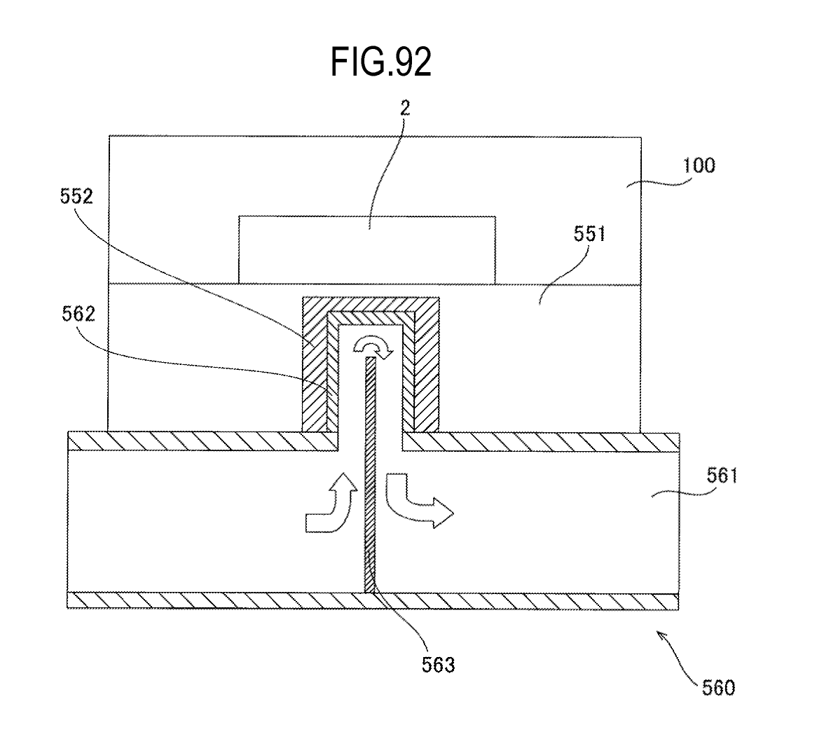

A thirty-ninth embodiment is described. Referring to FIG. 92, a via 552 is provided at a lower surface of a substrate 551 on which the semiconductor element 2 of the power module 100 is provided. An upper plane of the via 552 is sealed. The via (hole) 552 is previously provided for removing electrical connection in the substrate 551. The via 552 is fitted on a protrusion 562 provided on a cooling plate base 561. Accordingly, the power module 100 can be fitted to the cooling plate base 561 without a recess being newly provided. Also, a partition plate 563 is provided in a region of the cooling plate base 561 of a liquid cooler 560 corresponding to the semiconductor element 2 (the semiconductor element 3) for increasing the flow speed of the colorant.

### Fortieth Embodiment

A fortieth embodiment is described. Unlike the first embodiment, in which the semiconductor element 2 (the semiconductor element 3) is connected with the terminal (the gate terminal 4, the source terminal 5, the drain terminal 6, the anode terminal 7) through the joint material 8, in this embodiment, a semiconductor element 602 is connected with a terminal 604 through a granular joint material 601. The terminal 604 is, for example, any of the gate terminal 4, the source terminal 5, the drain terminal 6, and the anode terminal 7 of the first embodiment. The semiconductor element 602 is, for example, any of the semiconductor element 2 and the semiconductor element 3 of the first embodiment.

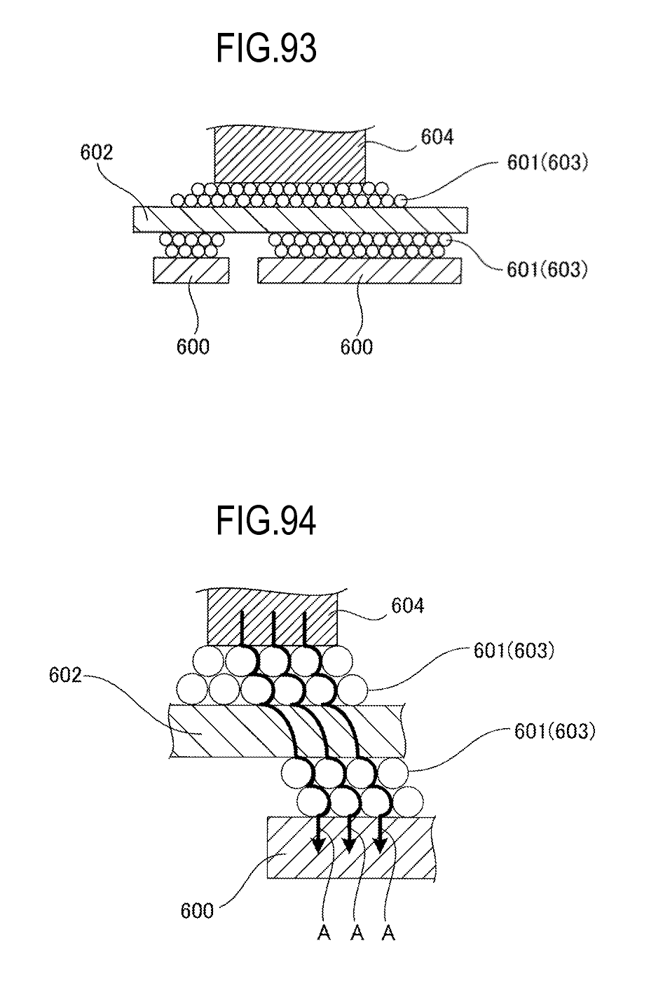

Referring to FIG. 93, the semiconductor element 602 is provided on a surface of an electrode 600 through a granular joint material 601. The granular joint material 601 contains metal particles 603 (silver particles, gold particles, copper particles, aluminum particles) with a low electrical resistance. Nickel coating or tin coating may be provided on surfaces of the metal particles 603. Also, the terminal 604 is provided on a surface of the semiconductor element 602 through a granular joint material 601. Further, current flows from the terminal 604 to the electrode 600 through the semiconductor element 602. The granular joint material 601 is an example of a “joint material” that is disclosed. The metal particles 603 are an example of “granular metal” that is disclosed.

A path A through which current flows during an operation with application of high-frequency current is described. If current with a frequency of 100 kHz or higher is applied from the terminal 604 to the electrode 600 through the semiconductor element 602, the current selectively flows on the surfaces of the metal particles 603 contained in the granular joint material 601 by skin effect. The granular joint material 601 is arranged such that the plurality of metal particles 603 are adjacent to each other. Referring to FIG. 94, the current flows from the terminal 604 to the semiconductor element 602 so as to flow on the surfaces of the metal particles 603, and flows from the semiconductor element 602 to the electrode 600.

In this embodiment, the terminal 604 and the semiconductor element 602 are joined by the granular joint material 601 in which the metal particles 603 are mixed. The high-frequency current flows along the surfaces of the metal particles 603, and hence the number of paths A through which the high-frequency current flows is increased by the plurality of metal particles 603. That is, high current can flow by the granular joint material 601 of this embodiment. Further, by adjusting the particle diameter of the metal particles 603 contained in the granular joint material 601, the current-carrying capacity of the granular joint material 601 can be adjusted.

### Forty-First Embodiment

A forty-first embodiment is described. In this embodiment, metal particles 611 are contained in a joint layer 612.

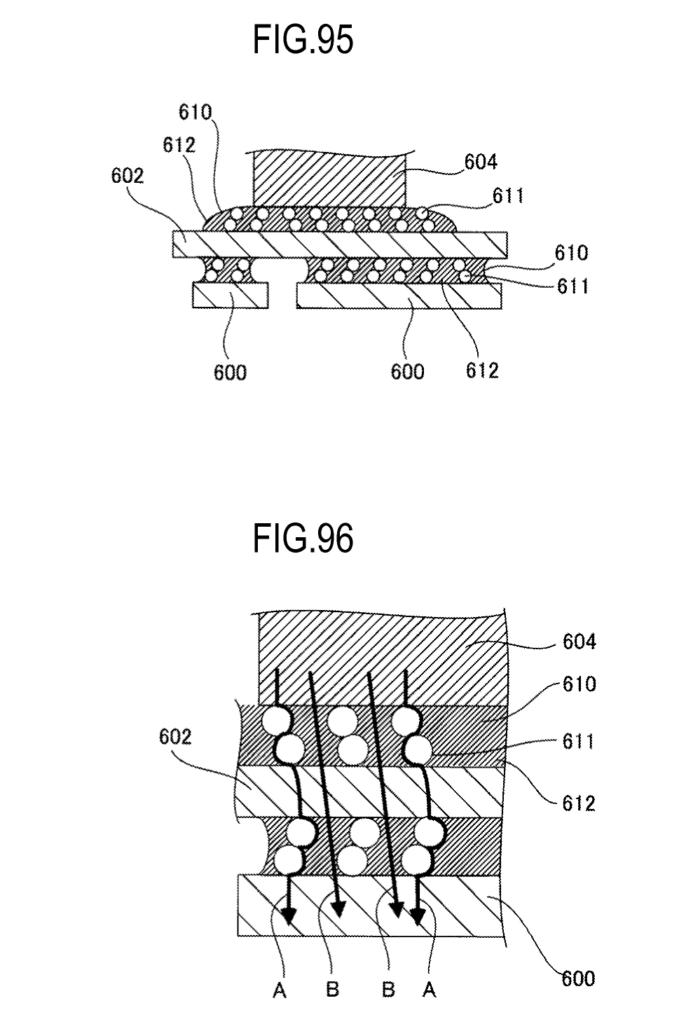

Referring to FIG. 95, the semiconductor element 602 is provided on the surface of the electrode 600 through a joint material 610. The joint material 610 includes the metal particles 611 dispersed in the joint material 610 and having a low electrical resistance, and the conductive joint layer 612. The metal particles 611 are formed of, for example, silver particles, gold particles, copper particles, or aluminum particles. Nickel coating or tin coating may be provided on surfaces of the metal particles 611. The joint layer 612 may use tin-based solder, lead-based solder, or two-dimensional or three-dimensional solder having tin or lead as the main constituent. Alternatively, the joint layer 612 may use a Au—Si brazing alloy that is available for high-temperature joint. Further alternatively, the joint material 610 may be molten at a high temperature and joined while a magnetic field is applied, so that the metal particles 611 are adjacent to each other along flux lines of the magnetic field. Also, the terminal 604 is provided on the surface of the semiconductor element 602 through a joint material 610. The joint material 610 is an example of a “joint material” that is disclosed. The metal particles 611 are an example of “granular metal” that is disclosed.

Next, referring to FIG. 96, the path A through which current flows during an operation with application of high-frequency current, and a path B through which current flows during an operation with application of low-frequency current are described.

Under the condition that the frequency is 100 kHz or higher (during application of high-frequency current), if the current flows from the terminal 604 to the electrode 600 through the semiconductor element 602, the current selectively flows on the surfaces (the path A) of the metal particles 611 contained in the joint material 610 by skin effect. In contrast, under the condition that the frequency is lower than 100 kHz (during application of low-frequency current), if the current flows from the terminal 604 to the electrode 600 through the semiconductor element 602, the influence of skin effect becomes small. Hence, the current does not pass through the metal particles 611, and passes through the shortest possible path (the path B) of the joint layer 612 of the joint material 610. As described above, in both situations of the operation with application of high-frequency current and the operation with application of low-frequency current, a path with a low resistance to current conduction can be selected. Also, by operating the mixing ratio of the metal particles 611 to the conductive joint layer 612, or the particle diameter of the metal particles 611, the current-carrying capacity with application of high-frequency current and the current-carrying capacity with application of low-frequency current can be adjusted.

### Forty-Second Embodiment

A high-current terminal block 700 according to a forty-second embodiment is described. The high-current terminal block 700 of this embodiment is used when an inverter section 710 and a converter section 720 having, for example, the power modules 100 described in the first embodiment mounted, are connected.

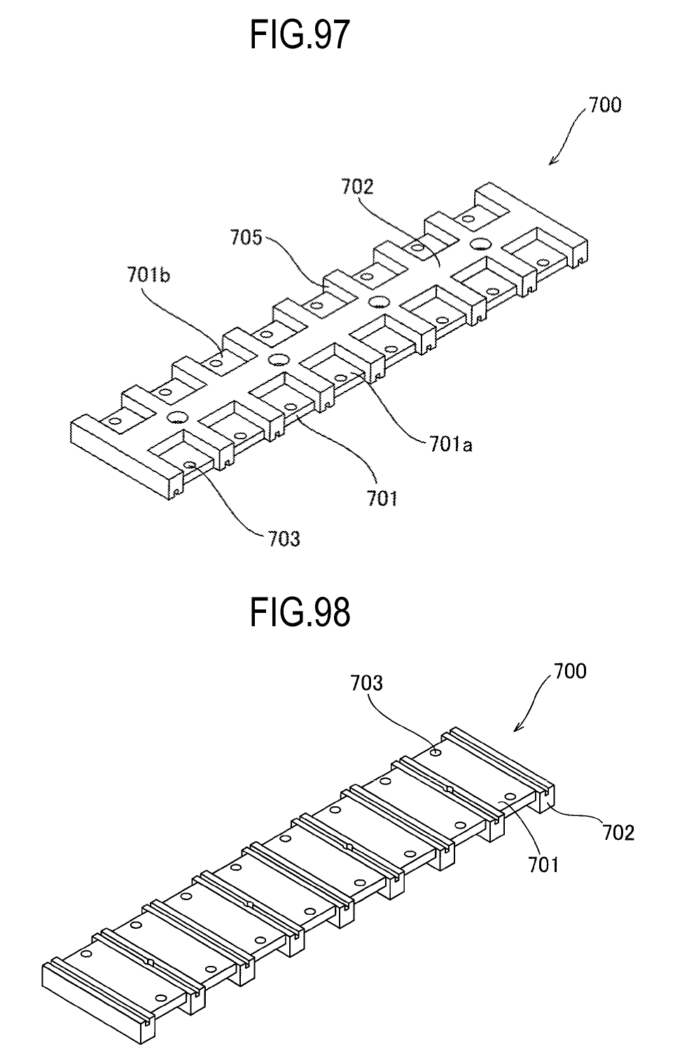

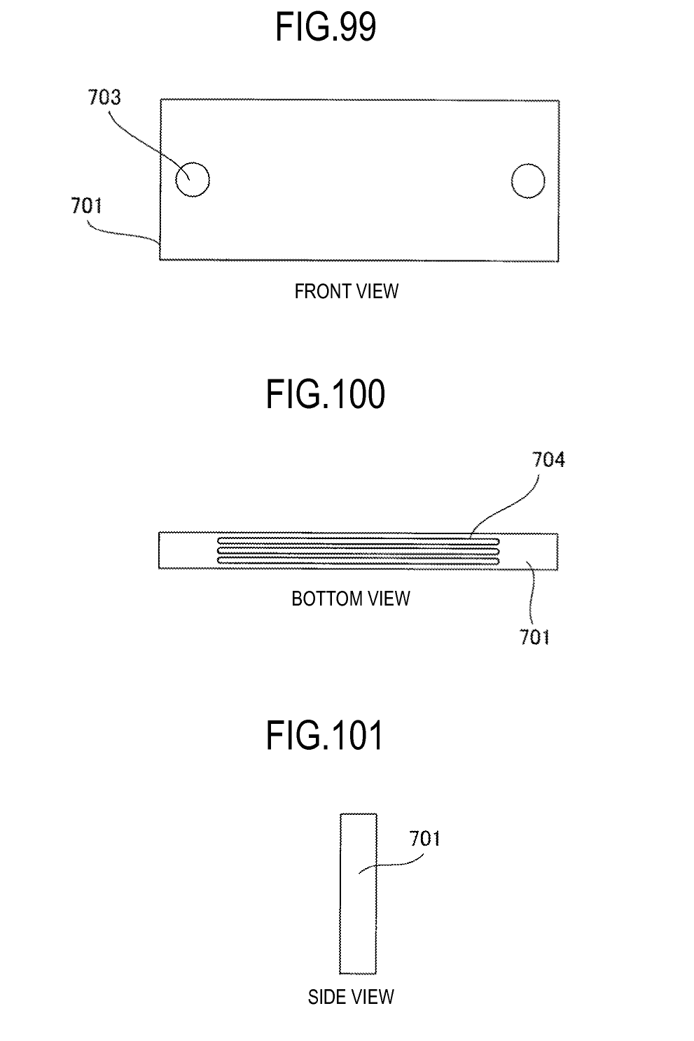

Referring to FIGS. 97 and 98, the high-current terminal block 700 includes connecting terminal portions 701 and an insulating resin portion 702. As shown in FIG. 99, the connecting terminal portions 701 each have two holes 703. Also, as shown in FIG. 100, the connecting terminal portions 701 each have a plurality of slits 704 penetrating through the connecting terminal portion 701. When the connecting terminal portions 701 and the resin portion 702 are integrated by formation with resin, the slits 704 of the connecting terminal portion 701 are filled with resin. The connecting terminal portions 701 have connecting terminal portions 701a for connection with the inverter section 710, and connecting terminal portions 701b for connection with the converter section 720. The high-current terminal block 700 is an example of a “terminal block” that is disclosed. The resin portion 702 is an example of an “insulating portion” that is disclosed. The connecting terminal portion 701a and the connecting terminal portion 701b are respectively examples of a “first connecting terminal portion” and a “second connecting terminal portion” that are disclosed.

Referring to FIG. 97, the resin portion 702 has a step part 705 for providing an insulation distance between the adjacent connecting terminal portions 701.

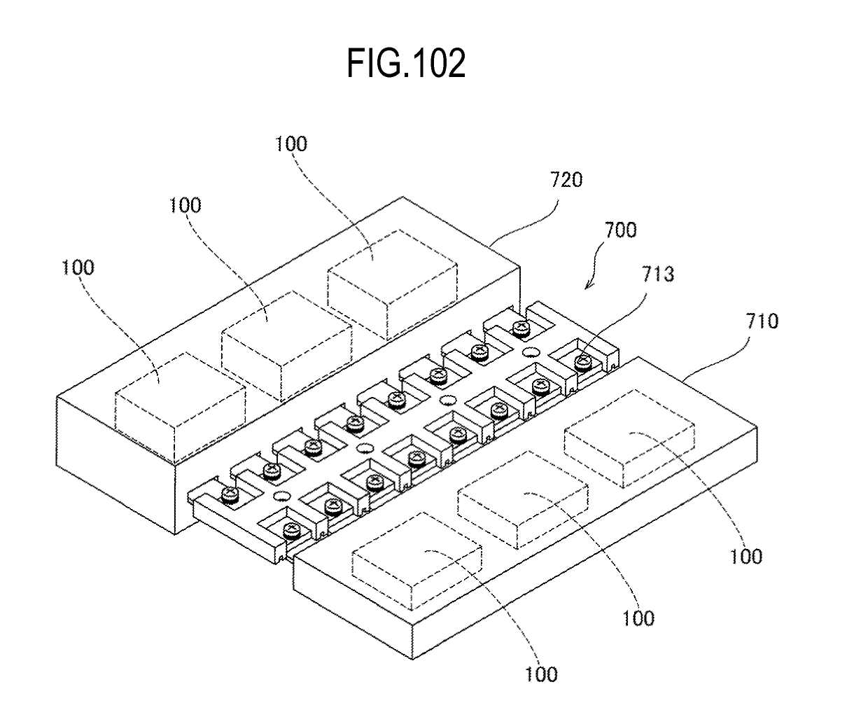

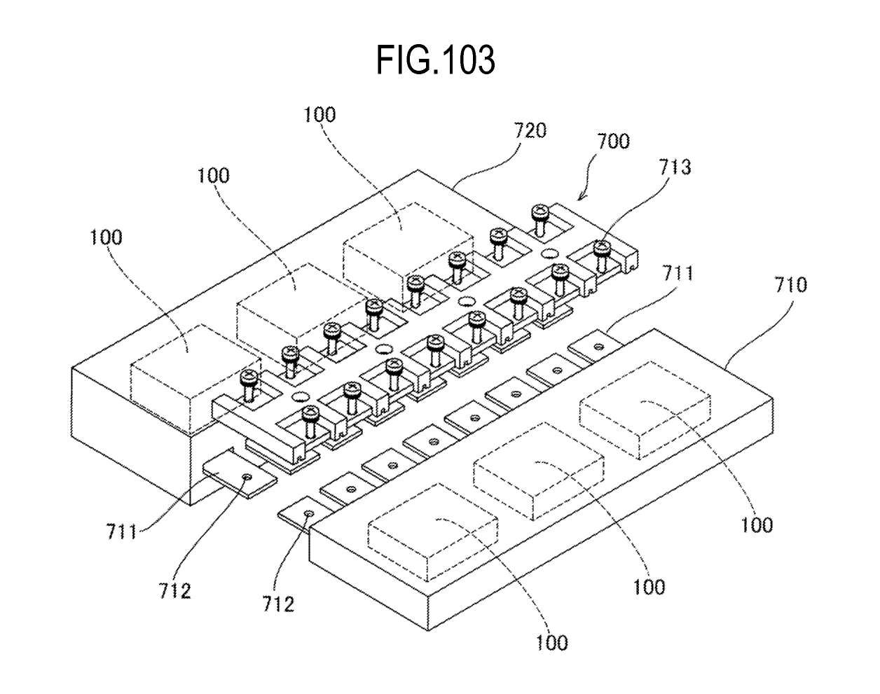

Also, referring to FIGS. 102 and 103, the high-current terminal block 700 is formed so that the inverter section 710 and the converter section 720 are connected with the high-current terminal block 700. For example, the power modules 100 described in the first embodiment are mounted in the inverter section 710 and the converter section 720. High-frequency high current can flow through the inverter section 710 and the converter section 720. The inverter section 710 and the converter section 720 have terminals 711 for connection with the high-current terminal block 700. Each terminal 711 has a hole 712 into which a screw 713 is inserted so that the terminal 711 can be fastened by the screw 713. The connecting terminal portions 701a and the connecting terminal portions 701b of the high-current terminal block 700 are connected by the terminals 711 of the inverter section 710 and the converter section 720, and the screws 713. Accordingly, the inverter section 710 and the converter section 720 are electrically and mechanically connected with the high-current terminal block 700. The screws 713 may be fastened with nuts provided on one surfaces of the terminals 711.

The high-current terminal block 700 described in this embodiment includes the plurality of connecting terminal portions 701 made of metal and the resin portion 702 made of resin for insulation between the adjacent connecting terminal portions 701. Also, the step part 705 is formed at the boundary between the connecting terminal portions 701 and the resin portion 702. With this structure, insulation between the connecting terminal portions 701 and the resin portion 702 can be reliably secured, and hence the pitch between the connecting terminal portions 701 can be decreased. Accordingly, the high-current terminal block 700 can be downsized.

The connecting terminal portions 701 of the high-current terminal block 700 described in this embodiment have the slits 704. The slits 704 are filled with resin that is the same as the resin of the resin portion 702. Accordingly, the connecting terminal portions 701 can be easily and rigidly fixed to the high-current terminal block 700.

The connecting terminal portions 701 of the high-current terminal block 700 described in this embodiment include the connecting terminal portions 701a for connection with the inverter section 710 and the connecting terminal portions 701b for connection with the converter section 720. Since the inverter section 710 and the converter section 720 are connected through the connecting terminal portions 701a and the connecting terminal portions 701b, electrical and mechanical connection can be easily made.

### Forty-Third Embodiment

A forty-third embodiment is described. In this embodiment, a connecting terminal portion 731 is provided with spring terminals 734.

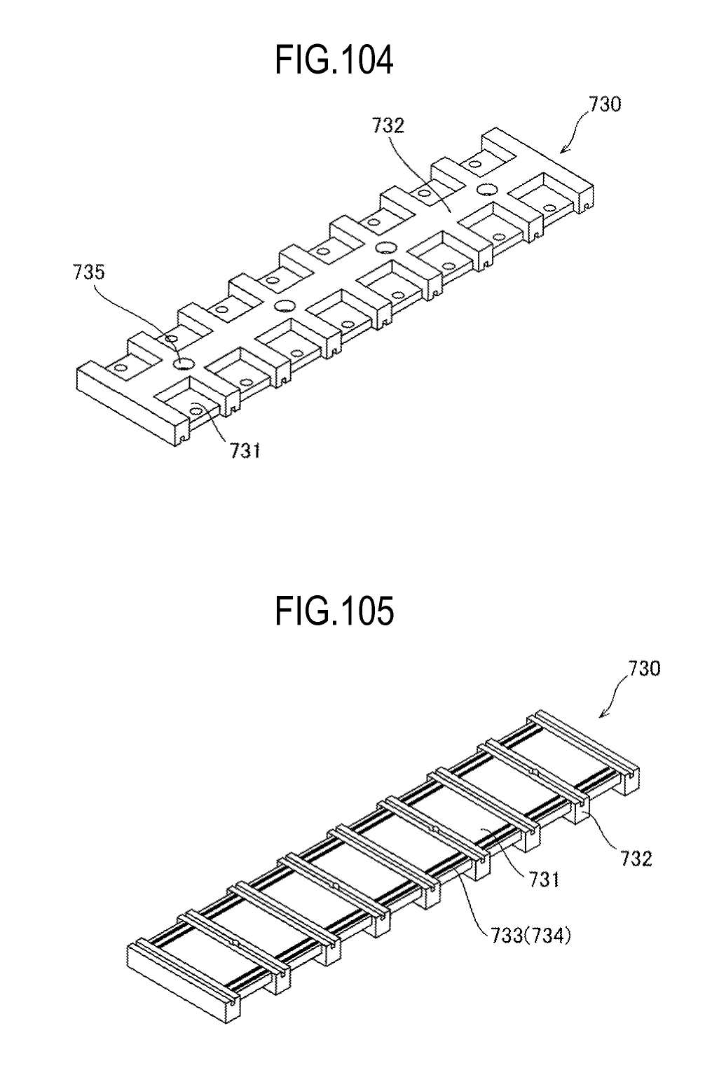

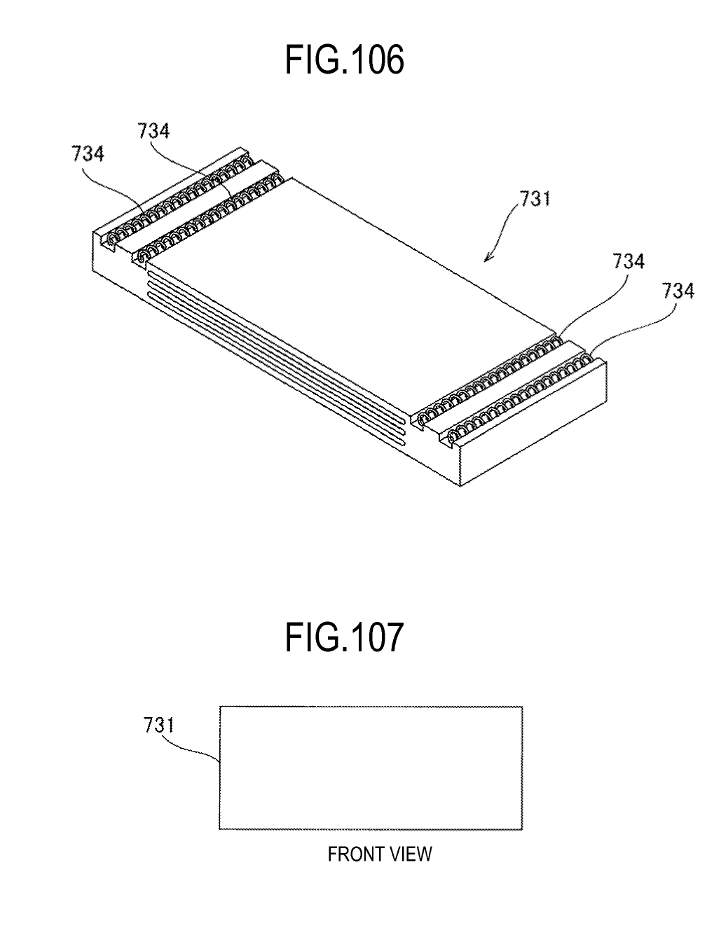

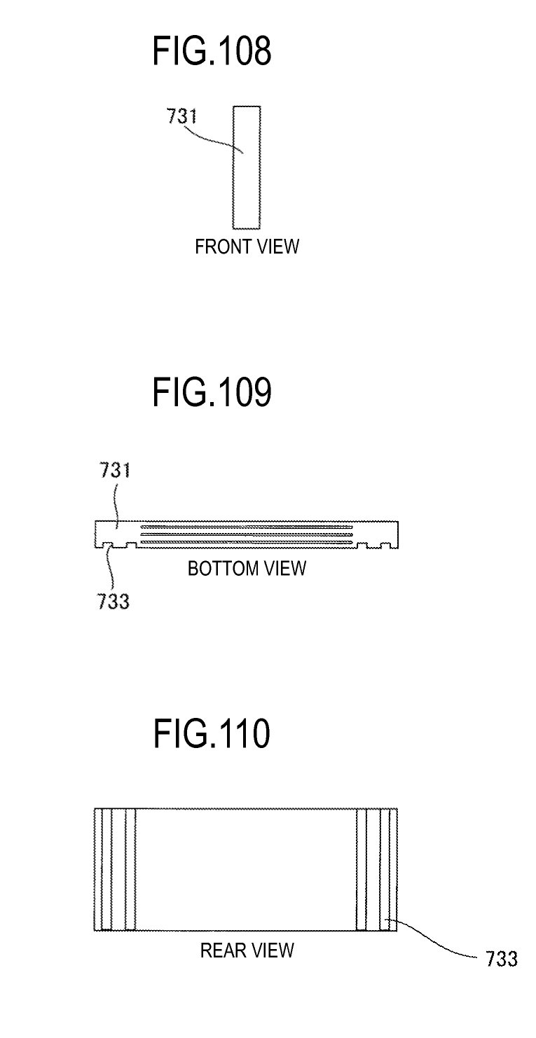

Referring to FIGS. 104 and 106, a high-current terminal block 730 includes connecting terminal portions 731 and a resin portion 732. As shown in FIGS. 109 and 110, the connecting terminal portions 731 each have four grooves 733. As shown in FIG. 106, the spring terminal 734 is attached to each groove 733. As shown in FIG. 104, the resin portion 732 has an attachment hole 735 into which a screw 736 can be inserted. The high-current terminal block 730 is an example of a “terminal block” that is disclosed. The resin portion 732 is an example of an “insulating portion” that is disclosed.

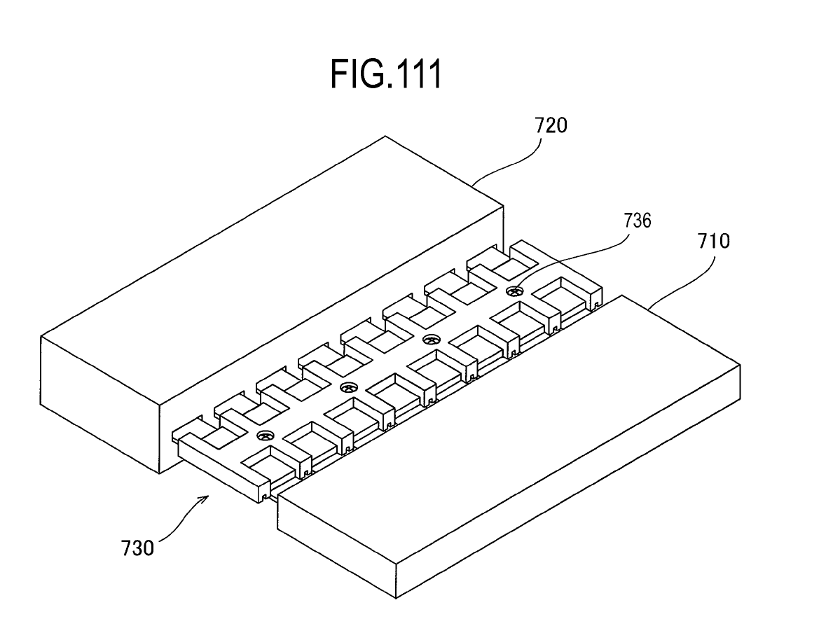

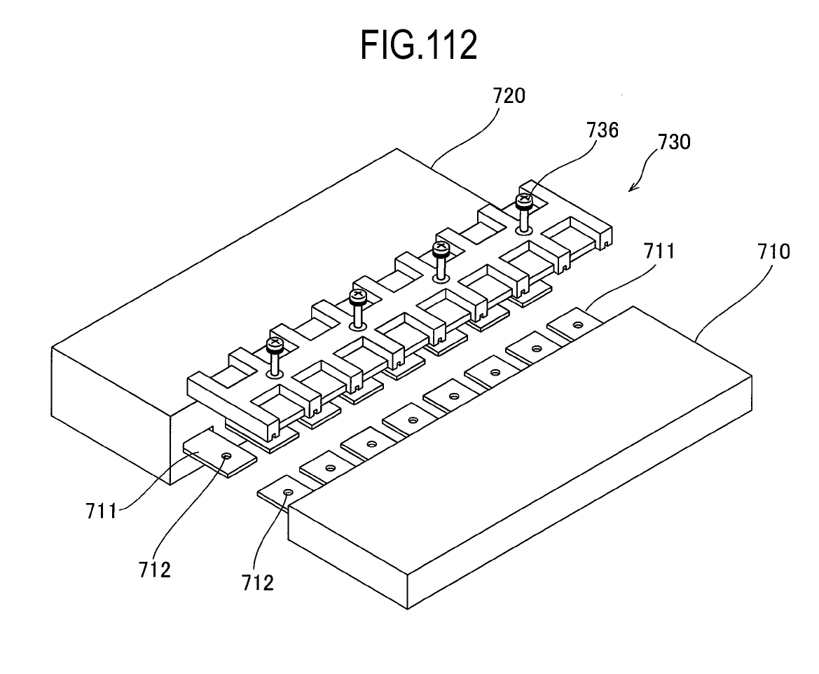

Referring to FIGS. 111 and 112, the high-current terminal block 730 is attached to a housing, such as a case that covers the inverter section 710 and the converter section 720 or a cooler (not shown) by the screw 736. Each connecting terminal portion 731 of the high-current terminal block 730 is fixed so as to be pressed to the terminals 711 of the inverter section 710 and the converter section 720 through the spring terminals 734. With this structure, screws for connecting the high-current terminal block 730 with the terminals 711 of the inverter section 710 and the converter section 720 are no longer used. Even if a contact pressure between the high-current terminal block 730 and the terminals 711 varies, a spiral structure of the spring terminal 734 can keep a certain contact area. As described above, electrical connection between the high-current terminal block 730 and the terminals 711 can be stabilized.

The disclosed embodiments are merely examples and are not limited thereto.

For example, in each of the first to forty-third embodiments, the substantially flat upper end surfaces of the gate terminal, the source terminal, the drain terminal, and the anode terminal (the cathode terminal) are exposed from the resin material. However, it is not limited thereto. For example, a substantially flat upper end surface of at least one of the gate terminal, the source terminal, the drain terminal, and the anode terminal (the cathode terminal) may be exposed.

In each of the first to forty-third embodiments, the substantially flat upper end surfaces of the gate terminal, the source terminal, the drain terminal, and the anode terminal (the cathode terminal) have the substantially equivalent heights. However, it is not limited thereto. For example, the substantially flat upper end surfaces of the gate terminal, the source terminal, the drain terminal, and the anode terminal (the cathode terminal) may have different heights.

In each of the first to forty-third embodiments, the gate terminal, the source terminal, the drain terminal, and the anode terminal (the cathode terminal) have substantially columnar shapes. However, it is not limited thereto. For example, the gate terminal, the source terminal, the drain terminal, and the anode terminal (the cathode terminal) may have shapes other than the substantially columnar shapes.

In each of the first to forty-third embodiments, the substantially flat upper end surfaces of the gate terminal, the source terminal, the drain terminal, and the anode terminal (the cathode terminal) have heights substantially equivalent to the height of the resin material. However, it is not limited thereto. For example, the substantially flat upper end surfaces of the gate terminal, the source terminal, the drain terminal, and the anode terminal (the cathode terminal) may protrude from the upper surface of the resin material.

Also, in each of the first to forty-third embodiments, the drain terminal is separated from the gate terminal, the source terminal, and the anode terminal. However, it is not limited thereto. For example, the gate terminal, the source terminal, the drain terminal, and the anode terminal may be adjacent to each other.

Also, in each of the first to forty-third embodiments, the semiconductor element exemplarily employs the FET that is formed on the SiC substrate having silicon carbide (SiC) as the main constituent and is available for high-frequency switching. However, it is not limited thereto. For example, the semiconductor element may employ a FET that is formed on a GaN substrate having gallium nitride (GaN) as the main constituent and is available for high-frequency switching. Alternatively, the semiconductor element may employ a metal oxide semiconductor field-effect transistor (MOSFET) formed on a Si substrate having silicon (Si) as the main constituent. Still alternatively, the semiconductor element may employ an insulated-gate bipolar transistor (IGBT).

Also, in each of the first to forty-third embodiments, the free wheel diode exemplarily employs the fast recovery diode (FRD). However, it is not limited thereto. For example, the semiconductor element may employ a Schottky barrier diode (SBD). Alternatively, any diode may be used as long as the diode is a free wheel diode.

In each of the first to thirty-ninth embodiments, the joint material exemplarily employs Au-20Sn, Zn-30Sn, or Pb-5Sn, or Ag nanoparticle paste. However, it is not limited thereto. For example, the joint material may employ solder foil or solder paste.

Also, in each of the thirty-first to thirty-third embodiments, the cooling hole is filled with copper, silver, or nickel. However, it is not limited thereto. For example, the cooling hole does not have to be filled with copper, silver, or nickel.

Also, in each of the forty-second and forty-third embodiments, the power modules as the power converters are provided in the inverter section and the converter section. However, it is not limited thereto. For example, the disclosed power module may be provided in an electronic device other than the inverter section or the converter section.

Obviously, numerous modifications and variations of the present invention are possible in light of the above teachings. It is therefore to be understood that within the scope of the appended claims, the invention may be practiced otherwise than as specifically described herein.

What is claimed is:

1. A power converter comprising:
a power-converter body portion including
a power-conversion semiconductor element having an electrode,
an electrode conductor electrically connected with the electrode of the power-conversion semiconductor element, and having side surfaces and a substantially flat upper end surface, and
a sealant made of resin and covering the power-conversion semiconductor element and the side surfaces of the electrode conductor,
wherein the sealant allows the substantially flat upper end surface of the electrode conductor to be exposed at an upper surface of the sealant and provides electrical connection with an external device at the substantially flat upper end surface of the exposed electrode conductor; and
a wiring board electrically connected with the substantially flat upper end surface of the electrode conductor exposed from the upper surface of the sealant.

2. The power converter according to claim 1,
wherein a plurality of the electrode conductors are provided, and
wherein a plurality of the substantially flat upper end surfaces of the plurality of electrode conductors exposed from the upper surface of the sealant have substantially equivalent heights.

3. The power converter according to claim 2, wherein the electrode conductor has a columnar shape extending upward, and the columnar shape has a substantially flat upper end surface.

4. The power converter according to claim 1, wherein the substantially flat upper end surface of the electrode conductor exposed from the upper surface of the sealant has a height substantially equivalent to a height of the upper surface of the sealant.

5. The power converter according to claim 1,
wherein the electrode of the power-conversion semiconductor element includes
a front-surface electrode provided on a principal surface of the power-conversion semiconductor element, and
a back-surface electrode provided on a back surface of the power-conversion semiconductor element, and
wherein the electrode conductor includes
a first electrode conductor connected with the front-surface electrode through a joint material at the principal surface of the power-conversion semiconductor element, extending upward, and having a substantially flat upper end surface exposed from the upper surface of the sealant, and
a second electrode conductor electrically connected with the back-surface electrode at the back surface of the power-conversion semiconductor element, extending upward from a position separated from the power-conversion semiconductor element, and having a substantially flat upper end surface exposed from the upper surface of the sealant.

6. The power converter according to claim 5, wherein the sealant forms an outer surface of the power-converter body portion.

7. The power converter according to claim 5, further comprising:
a case portion surrounding the power-conversion semiconductor element and the electrode conductor,
wherein the sealant covers the power-conversion semiconductor element and the side surfaces of the electrode conductor, and the case portion is filled with the sealant such that the substantially flat upper end surface of the electrode conductor is exposed.

8. The power converter according to claim 7, further comprising a radiator member arranged at the back surface of the power-conversion semiconductor element.

9. The power converter according to claim 8, wherein the power-conversion semiconductor element is formed of a semiconductor made of silicon carbide or gallium nitride.

10. The power converter according to claim 1, wherein the substantially flat upper end surface of the electrode conductor exposed from the upper surface of the sealant is electrically connected with the wiring board through a bump electrode.

11. The power converter according to claim 1, wherein the substantially flat upper end surface of the electrode conductor exposed from the upper surface of the sealant is electrically connected with the wiring board through a pin-like terminal.

12. The power converter according to claim 11, wherein the wiring board includes wiring having a cooling structure.

13. The power converter according to claim 12, wherein the cooling structure has a cooling hole formed near the wiring of the wiring board.

14. The power converter according to claim 13, wherein the wiring board includes a wiring portion having a fine wiring portion that is formed of a fine wiring conductor extending in a direction in which high-frequency current flows.

15. The power converter according to claim 14,
wherein the wiring conductor includes a plurality of wiring conductors adjacent to each other in a plane at an interval, and
wherein the wiring board further includes a cooling pipe arranged between the adjacent wiring conductors.

16. The power converter according to claim 15, wherein the fine wiring portion formed of the fine wiring conductor includes a first wiring conductor and a second wiring conductor stacked on each other through an insulating substrate.

17. The power converter according to claim 16, wherein the wiring board further includes a connecting wiring portion that penetrates through the insulating substrate and electrically connects the first wiring conductor and the second wiring conductor stacked on each other through the insulating substrate.

18. The power converter according to claim 17, wherein the wiring board includes a wiring conductor having a protrusion and a recess at an outer surface, the protrusion and recess extending in the direction in which the high-frequency current flows.

19. The power converter according to claim 18, wherein the wiring board further includes an insulator surrounding the periphery of the wiring conductor having the protrusion and the recess.

20. A power converter comprising:
a plurality of power-conversion semiconductor elements including a plurality of electrodes;
a plurality of electrode conductors electrically connected with the plurality of electrodes of the plurality of power-conversion semiconductor elements, having columnar shapes extending upward, and having substantially flat upper end surfaces;
a radiator member arranged at back surfaces of the power-conversion semiconductor elements; and
a sealant made of resin and covering the power-conversion semiconductor elements and side surfaces of the electrode conductors,
wherein the sealant allows the substantially flat upper end surfaces of the plurality of electrode conductors having the columnar shapes to be exposed at an upper surface of the sealant and provides electrical connection with an external device at the upper end surfaces of the exposed electrode conductors, and
wherein heat generated by the power-conversion semiconductor elements can be radiated from both the substantially flat upper end surfaces of the plurality of electrode conductors arranged at principal surfaces of the power-conversion semiconductor elements and the radiator member arranged at the back surfaces of the power-conversion semiconductor elements.
